(19) United States
(12) Patent Application Publication
(10) Pub. No.: US 2025/0324682 A1
(43) Pub. Date: Oct. 16, 2025

(54) SIC SEMICONDUCTOR DEVICE

(71) Applicant: ROHM CO., LTD., Kyoto-shi (JP)

(72) Inventors: Seigo MORI, Kyoto-shi (JP); Yuki NAKANO, Kyoto-shi (JP)

(73) Assignee: ROHM CO., LTD., Kyoto-shi (JP)

(21) Appl. No.: 19/252,687

(22) Filed: Jun. 27, 2025

Related U.S. Application Data
(63) Continuation of application No. PCT/JP2023/046705, filed on Dec. 26, 2023.

(30) Foreign Application Priority Data
Dec. 28, 2022 (JP) 2022-212617

(51) Int. Cl. H10D 62/10; H10D 30/01; H10D 30/66; H10D 62/00; H10D 62/832

(52) U.S. Cl. CPC H10D 62/111; H10D 30/0297; H10D 30/668; H10D 62/054; H10D 62/8325

(57) ABSTRACT

An SiC semiconductor device includes an SiC layer that includes a main surface and has an axis channel in a lamination direction, an impurity region of a p-type formed in the SiC layer, a trench that is formed shallower than the impurity region in the main surface and defines a lower region including a part of the impurity region between a bottom portion of the SiC layer and the trench, and an inversion column of an n-type that is formed in the lower region such as to extend along the axis channel and that inverts a conductivity type of the impurity region.

### CROSS-REFERENCE TO RELATED APPLICATIONS

The present application is a bypass continuation of International Patent Application No. PCT/JP2023/046705 filed on Dec. 26, 2023, which claims priority to Japanese Patent Application No. 2022-212617 filed on Dec. 28, 2022 and the entire contents of this application are hereby incorporated herein by reference.

### BACKGROUND

### 1. Field of the Disclosure

The present disclosure relates to an SiC semiconductor device.

### 2. Description of the Related Art

US2015/0028351A1 discloses an electronic device having an impurity region introduced into a silicon carbide layer by a channeling implantation method.

### BRIEF DESCRIPTION OF DRAWINGS

FIG. 1 is a plan view showing an SiC semiconductor device according to a specific embodiment.

FIG. 2 is a cross-sectional view taken along line II-II shown in FIG. 1.

FIG. 3 is a plan view showing a layout example of a chip.

FIG. 4 is a perspective view showing the layout example of the chip.

FIG. 5 is a plan view showing an active region and a trench structure according to a first configuration example.

FIG. 6 is a cross-sectional perspective view showing the active region and the trench structure according to the first configuration example.

FIG. 7 is an enlarged cross-sectional view showing the trench structure according to the first configuration example.

FIG. 8 is a graph showing an example of a p-type concentration gradient of an impurity region.

FIG. 9 is a graph showing a comparative example of the p-type concentration gradient of the impurity region.

FIG. 10 is a graph showing an example of an n-type concentration gradient of a column region.

FIG. 11 is a perspective view showing a configuration of an outer peripheral region.

FIG. 12 is a cross-sectional view showing a main portion of the outer peripheral region.

FIG. 13 is a cross-sectional view showing the main portion of the outer peripheral region.

FIG. 14 is a schematic view showing a wafer used in manufacturing an SiC semiconductor device.

FIG. 15 is a flowchart showing a manufacturing method example of the SiC semiconductor device.

FIGS. 16A to 16O are cross-sectional perspective views showing the manufacturing method example of the SiC semiconductor device.

FIG. 17A is a schematic view for illustrating a measurement step of a crystal orientation.

FIG. 17B is a schematic view for illustrating the measurement step of the crystal orientation.

FIG. 18A is a schematic view for illustrating an ion implantation step.

FIG. 18B is a schematic view for illustrating the ion implantation step.

FIG. 19 is a cross-sectional perspective view showing a trench structure according to a second configuration example.

FIG. 20 is a cross-sectional perspective view showing the trench structure according to a third configuration example.

FIG. 21 is a cross-sectional perspective view showing the trench structure according to the fourth configuration example.

FIG. 22 is a cross-sectional perspective view showing an SiC semiconductor device according to a first modification example.

FIG. 23 is a cross-sectional perspective view showing an SiC semiconductor device according to a second modification example.

FIG. 24 is a cross-sectional perspective view showing an SiC semiconductor device according to a third modification example.

### DETAILED DESCRIPTION OF THE PREFERRED EMBODIMENTS

Hereinafter, specific embodiments will be described in detail with reference to the accompanying drawings. All of the accompanying drawings are schematic views and thus are not precisely drawn and are not always matched in relative positional relationships, reduced scales, ratios, angles, etc. Identical reference signs are assigned to corresponding structures in the accompanying drawings, and redundant descriptions thereof will be omitted or simplified. Descriptions provided before the omission or simplification will be applied to the structures described in an omitted or simplified manner.

When the wording “substantially” is used in this Description, the wording includes a numerical value (shape) equal to a numerical value (shape) of the comparison target and also includes numerical errors (shape errors) in a range of ±10% on a basis of the numerical value (shape) of the comparison target. Although the wordings “first,” “second,” “third,” etc., are used in the following description, these are symbols attached to names of respective structures in order to clarify the order of description and are not attached with an intention of restricting the names of the respective structures.

In the following descriptions, a “p-type” or an “n-type” is used to indicate a conductivity type of a semiconductor (impurities), however, the “p-type” may be referred to as a “first conductivity type,” and the “n-type” may be referred to as a “second conductivity type.” As a matter of course, the “n-type” may be referred to as a “first conductivity type,” and the “p-type” may be referred to as a “second conductivity type.” The “p-type” is a conductivity type due to a trivalent element, and the “n-type” is a conductivity type due to a pentavalent element. The trivalent element may be at least one type among boron, aluminum, gallium, and indium, unless otherwise specified. The pentavalent element is at least one type among nitrogen, phosphorus, arsenic, antimony, and bismuth, unless otherwise specified.

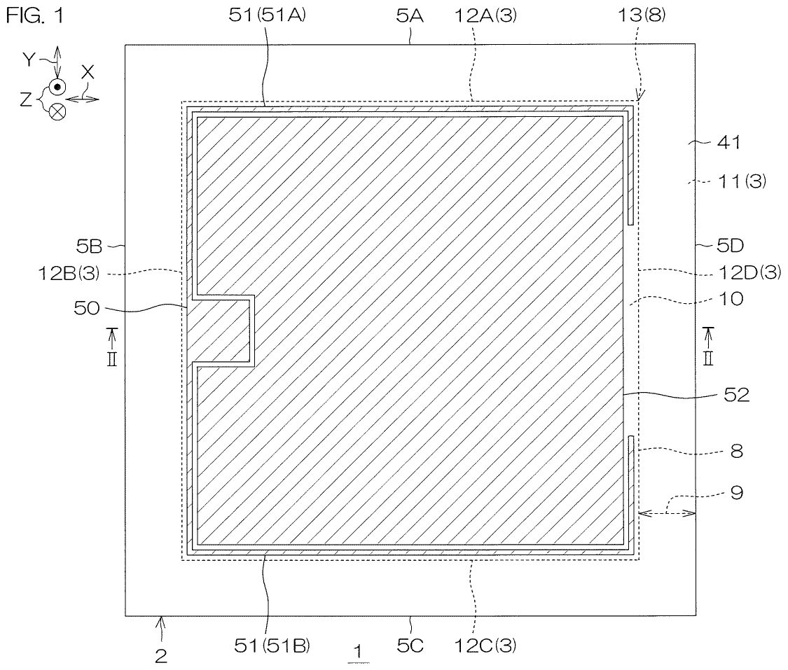

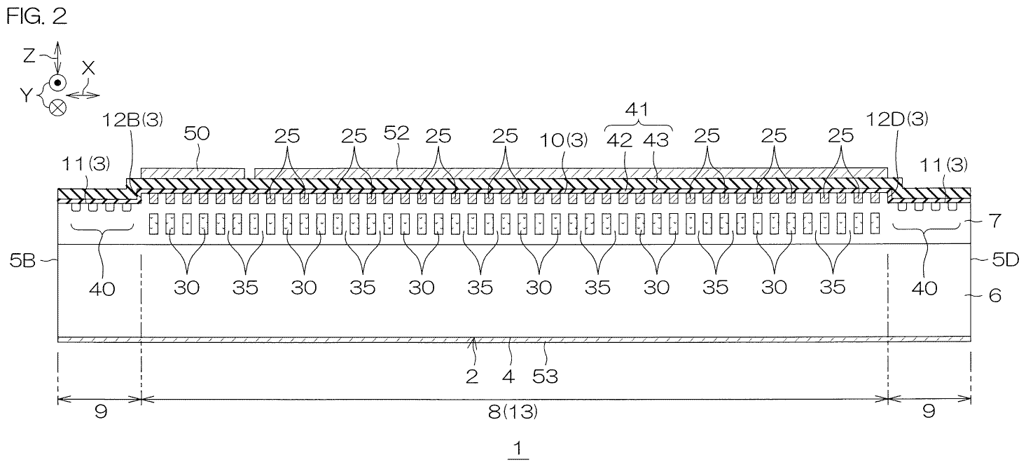

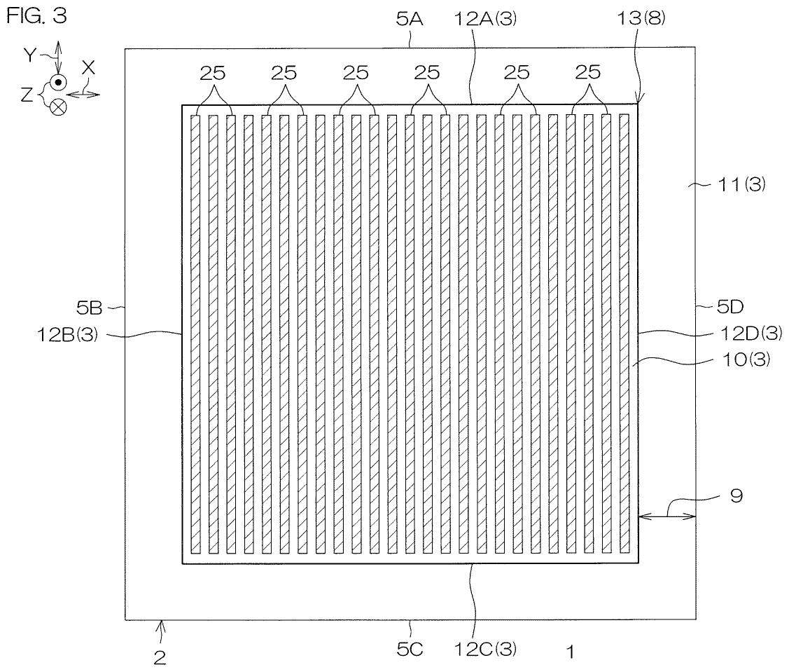

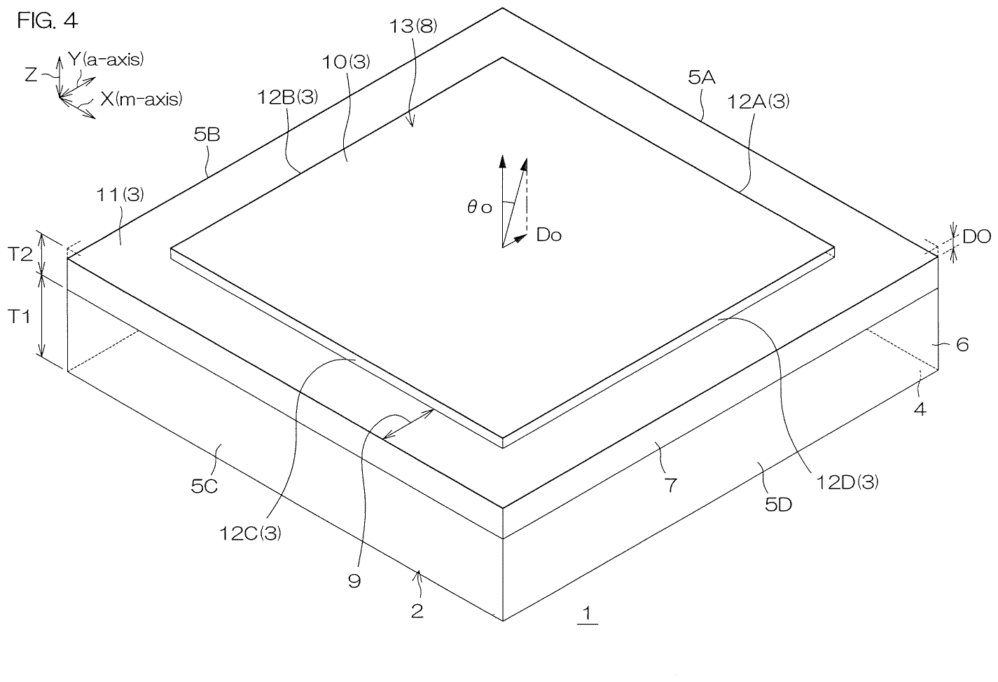

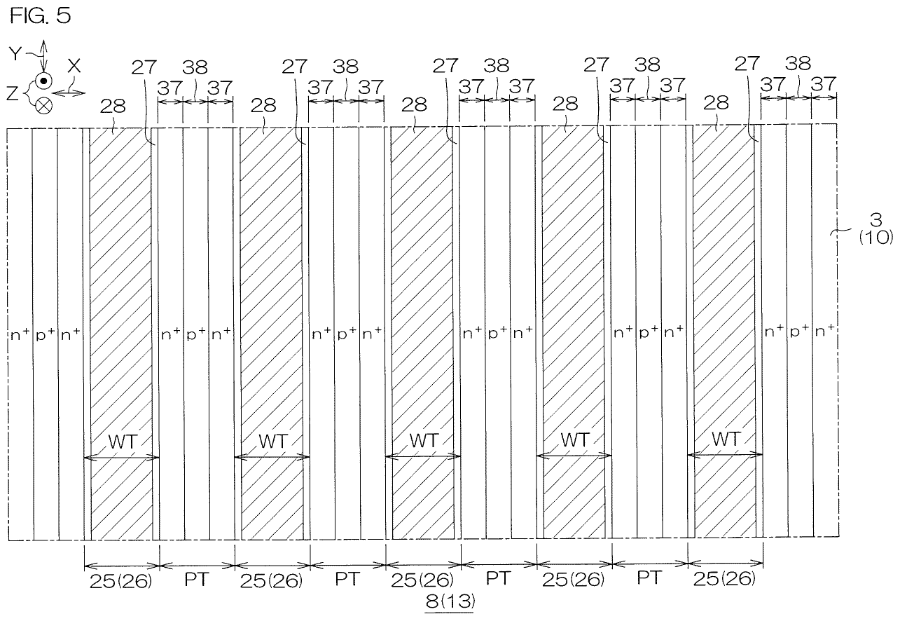

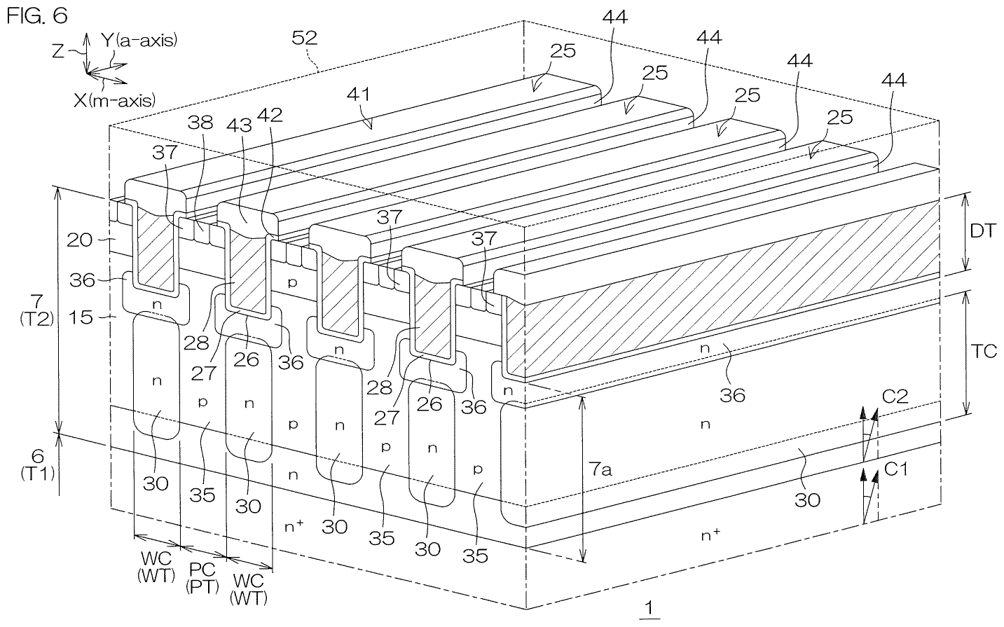

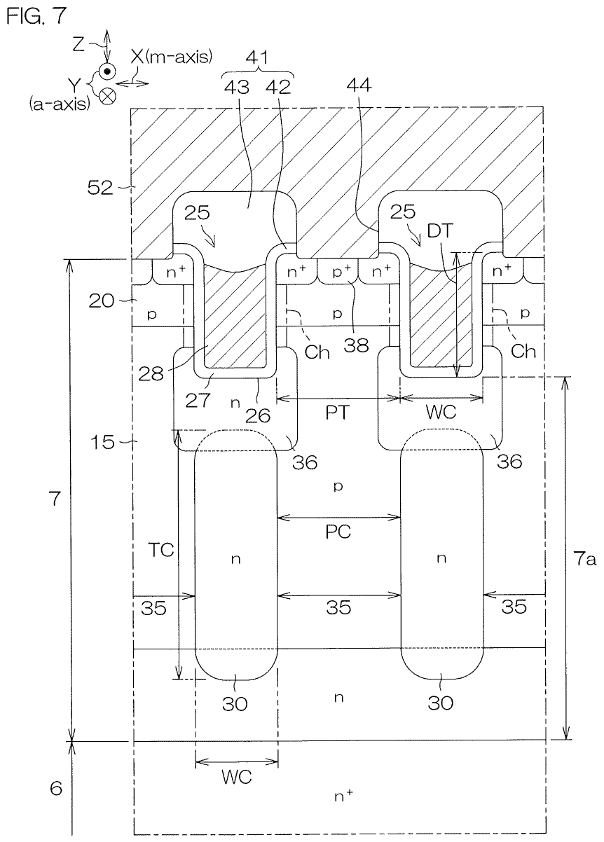

FIG. 1 is a plan view showing an SiC semiconductor device 1 according to a specific embodiment. FIG. 2 is a cross-sectional view taken along line II-II shown in FIG. 1. FIG. 3 is a plan view showing a layout example of a chip 2. FIG. 4 is a perspective view showing a layout example of the chip 2. FIG. 5 is a plan view showing an active region 8 and a trench structure 25 according to a first configuration example. FIG. 6 is a cross-sectional perspective view showing the active region 8 and the trench structure 25 according to the first configuration example. FIG. 7 is an enlarged cross-sectional view showing the trench structure 25 according to the first configuration example.

With reference to FIGS. 1 to 7, the SiC semiconductor device 1 includes the chip 2 including an SiC monocrystal. The chip 2 may be referred to as an “SiC chip” or as a “semiconductor chip.” In this embodiment, the chip 2 is constituted of a hexagonal SiC monocrystal and is formed in a rectangular parallelepiped shape. The hexagonal SiC monocrystal has a plurality of polytypes including a 2H (hexagonal)-SiC monocrystal, a 4H-SiC monocrystal, a 6H-SiC monocrystal, etc. In this embodiment, an example in which the chip 2 is constituted of the 4H-SiC monocrystal is described, but the chip 2 may be constituted of another polytype.

The chip 2 has a first main surface 3 on one side, a second main surface 4 on the other side, and first to fourth side surfaces 5A to 5D connecting the first main surface 3 and the second main surface 4. The first main surface 3 and the second main surface 4 are each formed in a quadrangular shape in plan view in a vertical direction Z (hereinafter, simply referred to as “plan view”). The vertical direction Z is also a thickness direction of the chip 2 or a normal direction to the first main surface 3 (the second main surface 4). The first main surface 3 and the second main surface 4 may each be formed in a square shape or a rectangular shape in plan view.

The first main surface 3 and the second main surface 4 are preferably formed of respective c-planes of the SiC monocrystal. In this case, preferably, the first main surface 3 is formed of a silicon surface (a (0001) surface) of the SiC monocrystal, and the second main surface 4 is formed of a carbon surface (a (000-1) surface) of the SiC monocrystal.

With regard to a circumferential direction (a counterclockwise direction in FIG. 1) of the chip 2 with the first side surface 5A as a starting point, the second side surface 5B is connected to the first side surface 5A, the third side surface 5C is connected to the second side surface 5B, and the fourth side surface 5D is connected to the first side surface 5A and the third side surface 5C. The first side surface 5A and the third side surface 5C extend in a first direction X along the first main surface 3 and oppose each other in a second direction Y that intersects (specifically, is orthogonal to) the first direction X. The second side surface 5B and the fourth side surface 5D extend in the second direction Y and oppose each other in the first direction X.

In this embodiment, the first direction X is an m-axis direction (a [1-100] direction) of the SiC monocrystal, and the second direction Y is an a-axis direction (a [11-20] direction) of the SiC monocrystal. As a matter of course, the first direction X may be the a-axis direction of the SiC monocrystal, and the second direction Y may be the m-axis direction of the SiC monocrystal.

An XY plane including the first direction X and the second direction Y forms a horizontal plane orthogonal to the vertical direction Z. Hereinafter, an axis extending in the vertical direction Z may be referred to as a “vertical axis.” Also, the first direction X and the second direction Y may be hereinafter referred to as a “horizontal direction.” The horizontal direction may also be a direction extending along the first main surface 3.

With reference to FIG. 4, the chip 2 (the first main surface 3 and the second main surface 4) has an off angle θo inclined at a predetermined angle in a predetermined off direction Do with respect to the c-plane of the SiC monocrystal. That is, a c-axis (a (0001) axis) of the SiC monocrystal is inclined by the off angle θo from the vertical axis toward the off direction Do. Also, the c-plane of the SiC monocrystal is inclined by the off angle θo with respect to the horizontal plane.

The off direction Do is preferably the a-axis direction (that is, the second direction Y) of the SiC monocrystal. The off angle θo may exceed 0° and be not more than 10°. The off angle θo may have a value falling within any one of ranges of exceeding 0° and not more than 10, not less than 10 and not more than 2.5°, not less than 2.5° and not more than 5°, not less than 5° and not more than 7.5°, and not less than 7.5° and not more than 10°.

The off angle θo is preferably not more than 5°. The off angle θo is particularly preferably not less than 2° and not more than 4.5°. The off angle θo is typically set in a range of 4°±0.1°. As a matter of course, this Description does not exclude a form in which the off angle θo is 0° (that is, a form in which the first main surface 3 is a just surface with respect to the c-plane).

The chip 2 includes a base layer 6 of an n-type constituted of an SiC monocrystal. The base layer 6 may be referred to as a “base SiC layer,” a “base region,” etc. The base layer 6 extends in a layer shape in the horizontal direction and forms the second main surface 4 and a part of each of the first to fourth side surfaces 5A to 5D. In this embodiment, the base layer 6 is constituted of a substrate made of the SiC monocrystal (that is, an SiC substrate). The base layer 6 has the off direction Do and the off angle θo described above.

The base layer 6 has a first axis channel C1 oriented along a lamination direction. The first axis channel C1 is constituted of regions (channels) that are of comparatively wide interatomic distance (atomic interval) in the SiC monocrystal constituting the base layer 6 and are surrounded by atomic rows constituting a crystal axis extending in the lamination direction (crystal growth direction).

That is, the first axis channel C1 is constituted of the regions that are sparse in atomic rows and extend in the lamination direction and are the regions in which atomic rows (interatomic distance/atomic density) in the horizontal direction are sparse in plan view. The first axis channel C1 is preferably constituted of the regions surrounded by atomic rows oriented along a low index crystal axis among crystal axes. A low index crystal axis is, in terms of Miller indices (a1, a2, a3, and c), a crystal axis expressed by absolute values of “a1,” “a2,” “a3,” and “c” all being not more than 2 (preferably not more than 1) (the same applies hereinafter in this Description).

In this embodiment, the first axis channel C1 is constituted of regions surrounded by atomic rows along the c-axis (the (0001) axis) of the SiC monocrystal. That is, the first axis channel C1 extends along the c-axis and has the off direction Do and the off angle θo described above. In other words, the first axis channel C1 is inclined by the off angle θo from the vertical axis toward the off direction Do.

The base layer 6 may have an n-type impurity concentration of not less than 1×10¹⁸ cm⁻³ and not more than 1×10²¹ cm⁻³ as a peak value. The base layer 6 preferably has a substantially constant n-type impurity concentration in the thickness direction. The n-type impurity concentration of the base layer 6 is preferably adjusted by a single type of pentavalent element. The n-type impurity concentration of the base layer 6 is particularly preferably adjusted by a pentavalent element other than phosphorus. In this embodiment, the n-type impurity concentration of the base layer 6 is adjusted by nitrogen.

The base layer 6 has a first thickness T1. The first thickness T1 may be not less than 5 μm and not more than 300 μm. The first thickness T1 may have a value falling within any one of ranges of not less than 5 μm and not more than 50 μm, not less than 50 μm and not more than 100 μm, not less than 100 μm and not more than 150 μm, not less than 150 μm and not more than 200 μm, not less than 200 μm and not more than 250 μm, and not less than 250 μm and not more than 300 μm. The first thickness T1 is preferably not less than 50 μm and not more than 250 μm.

The chip 2 includes a semiconductor layer 7 made of the SiC monocrystal laminated on the base layer 6. The semiconductor layer 7 may be referred to as an “SiC layer,” a “semiconductor region,” etc. The semiconductor layer 7 extends in a layer shape in the horizontal direction and forms the first main surface 3 and a part of each of the first to fourth side surfaces 5A to 5D. The semiconductor layer 7 is constituted of an epitaxial layer (that is, an SiC epitaxial layer) that is crystal-grown with the base layer 6 as a starting point.

The semiconductor layer 7 has a lower end and an upper end. The lower end of the semiconductor layer 7 is a crystal growth starting point, and the upper end of the semiconductor layer 7 is a crystal growth end point. The lower end of the semiconductor layer 7 is also a bottom portion of the semiconductor layer 7. Since the semiconductor layer 7 is continuously crystal-grown from the base layer 6, the lower end of the semiconductor layer 7 is matched with an upper end of the base layer 6.

A boundary portion between the base layer 6 and the semiconductor layer 7 is not necessarily visible and can be indirectly evaluated and/or determined from other configurations or elements. The semiconductor layer 7 has the off direction Do and the off angle θo that are substantially matched with the off direction Do and the off angle θo of the base layer 6.

The semiconductor layer 7 has a second axis channel C2 oriented along the lamination direction. The second axis channel C2 is constituted of regions (channels) that are of comparatively wide interatomic distance (atomic interval) in the SiC monocrystal constituting the semiconductor layer 7 and are surrounded by atomic rows constituting a crystal axis extending in the lamination direction (crystal growth direction).

That is, the second axis channel C2 is constituted of the regions that are sparse in atomic rows and extend in the lamination direction and are the regions in which atomic rows (interatomic distance/atomic density) in the horizontal direction are sparse in plan view. The second axis channel C2 is preferably constituted of the regions surrounded by atomic rows oriented along a low index crystal axis among crystal axes.

In this embodiment, the second axis channel C2 is constituted of the regions surrounded by atomic rows along the c-axis of the SiC monocrystal. That is, the second axis channel C2 extends along the c-axis and has the off direction Do and the off angle θo. In other words, the second axis channel C2 is inclined by the off angle θo from the vertical axis toward the off direction Do. Also, the second axis channel C2 is substantially matched with the first axis channel C1.

An n-type impurity concentration of the semiconductor layer 7 is preferably less than the n-type impurity concentration of the base layer 6. The semiconductor layer 7 may have an n-type impurity concentration of not less than 1×10¹⁵ cm⁻³ and not more than 1×10¹⁸ cm⁻³ as a peak value. The n-type impurity concentration of the semiconductor layer 7 may be substantially constant in the thickness direction. As a matter of course, the n-type impurity concentration of the semiconductor layer 7 may have a concentration gradient that gradually increases and/or gradually decreases in the lamination direction (the crystal growth direction).

In this embodiment, the n-type impurity concentration of the semiconductor layer 7 is adjusted by nitrogen. The semiconductor layer 7 may have an n-type impurity concentration adjusted by at least one type of pentavalent element. For example, the n-type impurity concentration of the semiconductor layer 7 may be adjusted by at least one type among nitrogen, phosphorus, arsenic, antimony, and bismuth. The semiconductor layer 7 preferably includes a pentavalent element other than phosphorus.

The n-type impurity concentration of the semiconductor layer 7 is preferably adjusted by at least nitrogen. In a case where the semiconductor layer 7 includes two or more types of pentavalent elements, the semiconductor layer 7 preferably includes nitrogen and a pentavalent element other than nitrogen. In this case, the semiconductor layer 7 preferably includes one or both of arsenic and antimony as a pentavalent element other than phosphorus and nitrogen.

The semiconductor layer 7 has a second thickness T2 less than the first thickness T1. The second thickness T2 may be not less than 1 μm and not more than 10 μm. The second thickness T2 may have a value belonging to any one of ranges of not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The second thickness T2 is preferably not less than 2 μm and not more than 8 μm.

The SiC semiconductor device 1 includes the active region 8 set in the chip 2. The active region 8 is set in an inner portion of the chip 2 with an interval from a peripheral edge (the first to fourth side surfaces 5A to 5D) of the chip 2 in plan view. The active region 8 is formed in a polygonal shape (in this embodiment, a quadrangular shape) having four sides parallel to the peripheral edge of the chip 2 in plan view. The plane area of the active region 8 is preferably not less than 50% and not more than 90% of the plane area of the first main surface 3.

The SiC semiconductor device 1 includes an outer peripheral region 9 set outside the active region 8 in the chip 2. The outer peripheral region 9 is provided in a region between the peripheral edges of the chip 2 and the active region 8 in plan view. The outer peripheral region 9 extends as a band along the active region 8 and is set in a polygonal annular shape (in this embodiment, a quadrangular annular shape) surrounding the active region 8 in plan view.

The SiC semiconductor device 1 includes an active surface 10, an outer surface 11, and first to fourth connecting surfaces 12A to 12D that are formed in the first main surface 3. The active surface 10, the outer surface 11, and the first to fourth connecting surfaces 12A to 12D define an active mesa 13 in the first main surface 3.

The active surface 10 may be referred to as a “first surface portion,” the outer surface 11 may be referred to as a “second surface portion,” the first to fourth connecting surfaces 12A to 12D may be referred to as “connecting surface portions,” and the active mesa 13 may be referred to as a “mesa portion.” The active surface 10, the outer surface 11, and the first to fourth connecting surfaces 12A to 12D (that is, the active mesa 13) may be considered as components of the chip 2 (the first main surface 3).

The active surface 10 is formed in the active region 8. That is, the active surface 10 is formed at intervals inward from the peripheral edges (the first to fourth side surfaces 5A to 5D) of the first main surface 3. The active surface 10 has a flat surface extending in the first direction X and the second direction Y. In this embodiment, the active surface 10 is formed of the c-plane (an Si surface). In this embodiment, the active surface 10 is formed in a quadrangular shape having four sides parallel to the first to fourth side surfaces 5A to 5D in plan view.

The outer surface 11 is formed in the outer peripheral region 9. That is, the outer surface 11 is formed outside the active surface 10. The outer surface 11 is recessed in the thickness direction (toward the second main surface 4 side) of the chip 2 with respect to the active surface 10. Specifically, in this embodiment, the outer surface 11 is recessed at a depth less than the thickness of the semiconductor layer 7 such as to expose the semiconductor layer 7. That is, the outer surface 11 opposes the base layer 6 across a part of the semiconductor layer 7 and exposes the semiconductor layer 7.

The outer surface 11 extends as a band along the active surface 10 in plan view and is formed in a annular shape (specifically, a quadrangular annular shape) surrounding the active surface 10. The outer surface 11 has a flat surface extending in the first direction X and the second direction Y and is formed substantially parallel to the active surface 10. In this embodiment, the outer surface 11 is formed of the c-plane (the Si surface). The outer surface 11 is continuous to the first to fourth side surfaces 5A to 5D.

The outer surface 11 has an outer depth DO. The outer depth DO may be not less than 0.1 μm and not more than 2 μm. The outer depth DO may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, and not less than 1.5 μm and not more than 2 μm. The outer depth DO is preferably not less than 0.1 μm and not more than 1.5 μm.

The first to fourth connecting surfaces 12A to 12D extend in the vertical direction Z and connect the active surface 10 and the outer surface 11. The first connecting surface 12A is positioned on the first side surface 5A side, the second connecting surface 12B is positioned on the second side surface 5B side, the third connecting surface 12C is positioned on the third side surface 5C side, and the fourth connecting surface 12D is positioned on the fourth side surface 5D side. The first connecting surface 12A and the third connecting surface 12C extend in the first direction X and oppose each other in the second direction Y. The second connecting surface 12B and the fourth connecting surface 12D extend in the second direction Y and oppose each other in the first direction X.

The first to fourth connecting surfaces 12A to 12D may extend substantially vertically between the active surface 10 and the outer surface 11 such as to define the active mesa 13 having a quadrangular column shape. The first to fourth connecting surfaces 12A to 12D may be inclined obliquely downward from the active surface 10 toward the outer surface 11 such as to define the active mesa 13 having a quadrangular pyramid shape. In this manner, the active mesa 13 is defined in a projecting shape on the semiconductor layer 7 in the first main surface 3. The active mesa 13 is formed only on the semiconductor layer 7 and is not formed on the base layer 6.

With reference to FIGS. 6 and 7, the SiC semiconductor device 1 includes an impurity region 15 of the p-type formed at least in a portion in the semiconductor layer 7 which is positioned in the active region 8. The impurity region 15 has an n-type impurity concentration higher than the n-type impurity concentration of the semiconductor layer 7 and inverts the conductivity type of the semiconductor layer 7 from the n-type to the p-type.

That is, the impurity region 15 includes a trivalent element in addition to the pentavalent element establishing the conductivity type of the semiconductor layer 7. The impurity region 15 may have a p-type impurity concentration of not less than 1×10¹⁵ cm⁻³ and not more than 1×10¹⁸ cm⁻³ as a peak value. The p-type impurity concentration of the impurity region 15 is preferably adjusted by at least one type of trivalent element.

The p-type impurity concentration of the impurity region 15 is particularly preferably adjusted by a trivalent element belonging to heavy elements heavier than carbon. That is, the impurity region 15 preferably includes a trivalent element other than boron (at least one type among aluminum, gallium, and indium). In this embodiment, the p-type impurity concentration of the impurity region 15 is adjusted by aluminum.

In this embodiment, the impurity region 15 is formed in the semiconductor layer 7 at an interval inward from peripheral edges of the active region 8 and has peripheral edge portions positioned in the active region 8. As a matter of course, the impurity region 15 may be led out from the active region 8 to the outer peripheral region 9. In this case, the impurity region 15 may be led out from a portion of the semiconductor layer 7 positioned in the active region 8 to a portion of the semiconductor layer 7 positioned in the outer peripheral region 9.

The impurity region 15 may extend from the outer peripheral region 9 toward the first to fourth side surfaces 5A to 5D and may be exposed from the first to fourth side surfaces 5A to 5D. As a matter of course, the impurity region 15 may be formed in the semiconductor layer 7 at an interval inward from the first to fourth side surfaces 5A to 5D. In this case, the peripheral edge portions of the impurity region 15 may be positioned in the outer peripheral region 9.

The impurity region 15 has an upper end portion positioned on an upper end side of the semiconductor layer 7 and a lower end portion positioned on a lower end side of the semiconductor layer 7. In this embodiment, the upper end portion of the impurity region 15 is positioned in a region on the lower end side of the semiconductor layer 7 with respect to a thickness range intermediate portion of the semiconductor layer 7, and the lower end portion of the impurity region 15 is positioned in a region on the lower end side of the semiconductor layer 7 with respect to the thickness range intermediate portion of the semiconductor layer 7.

Although not specifically shown, the upper end of the impurity region 15 may be exposed from the first main surface 3. As a matter of course, the upper end portion of the impurity region 15 may be formed at an interval from the upper end (that is, the semiconductor layer 7) toward the lower end side of the semiconductor layer 7 and may oppose the first main surface 3 across a part (the upper end portion) of the semiconductor layer 7. Such a structure is identified by analyzing the p-type impurity concentration (a concentration gradient) of the impurity region 15.

A distance between the first main surface 3 and the upper end portion of the impurity region 15 may be not less than 0 μm and not more than 1 μm. The distance between the first main surface 3 and the upper end portion of the impurity region 15 may have a value falling within any one of ranges of not less than 0 μm and not more than 0.25 μm, not less than 0.25 μm and not more than 0.5 μm, not less than 0.5 μm and not more than 0.75 μm, and not less than 0.75 μm and not more than 1 μm.

The lower end portion of the impurity region 15 may be formed at an interval from the lower end (that is, the base layer 6) toward the upper end side of the semiconductor layer 7 and may oppose the base layer 6 across a part (the lower end portion) of the semiconductor layer 7. A distance between the lower end of the semiconductor layer 7 and the lower end portion of the impurity region 15 may exceed 0 μm and be not more than 5 μm. The distance between the lower end of the semiconductor layer 7 and the lower end portion of the impurity region 15 may have a value falling within any one of ranges of exceeding 0 μm and not more than 1 μm, not less than 1 μm and not more than 2 μm, not less than 2 μm and not more than 3 μm, not less than 3 μm and not more than 4 μm, and not less than 4 μm and not more than 5 μm.

The impurity region 15 has a thickness less than the second thickness T2 of the semiconductor layer 7. The thickness of the impurity region 15 may be not less than 1 μm and less than 10 μm. The thickness of the impurity region 15 may have a value falling within any one of ranges of not less than 1 μm and not more than 2 μm, not less than 2 μm and not more than 4 μm, not less than 4 μm and not more than 6 μm, not less than 6 μm and not more than 8 μm, and not less than 8 μm and less than 10 μm. The thickness of the impurity region 15 is preferably not less than 2 μm and not more than 8 μm. As a matter of course, the lower end portion of the impurity region 15 may cross the boundary portion between the base layer 6 and the semiconductor layer 7 and may be positioned in the base layer 6.

The impurity region 15 is constituted of a channeling region of the p-type extending along the second axis channel C2 in the semiconductor layer 7 in cross-sectional view. That is, the impurity region 15 is constituted of an impurity region introduced parallel to or substantially parallel to regions (the second axis channel C2) surrounded by atomic rows along the low-index crystal axis in the semiconductor layer 7 and inclinedly extends with respect to the first main surface 3.

Therefore, the impurity region 15 has the off direction Do and the off angle θo that are substantially matched with the off direction Do and the off angle θo of the second axis channel C2. In other words, the impurity region 15 is inclined by the off angle θo from the vertical axis toward the off direction Do. The impurity region 15 is constituted of a single impurity region having a thickness (a depth) that crosses the intermediate portion of the semiconductor layer 7 along the second axis channel C2.

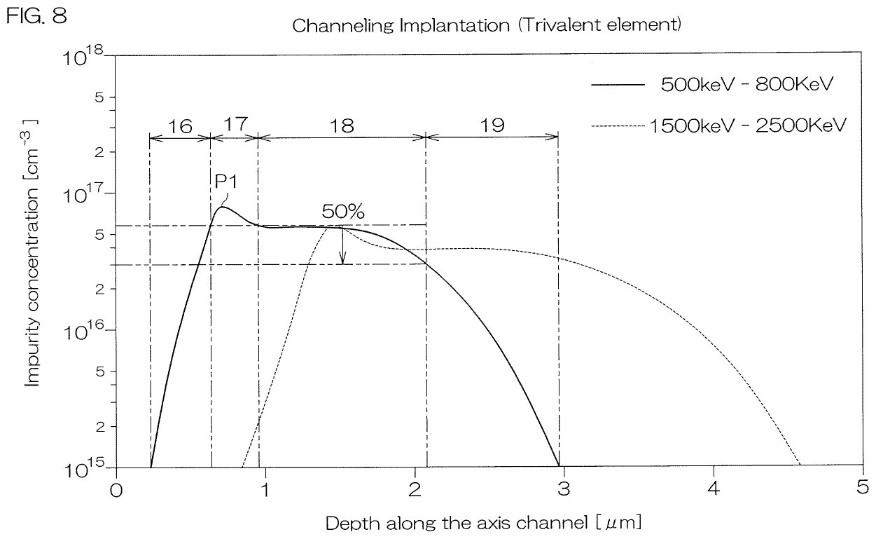

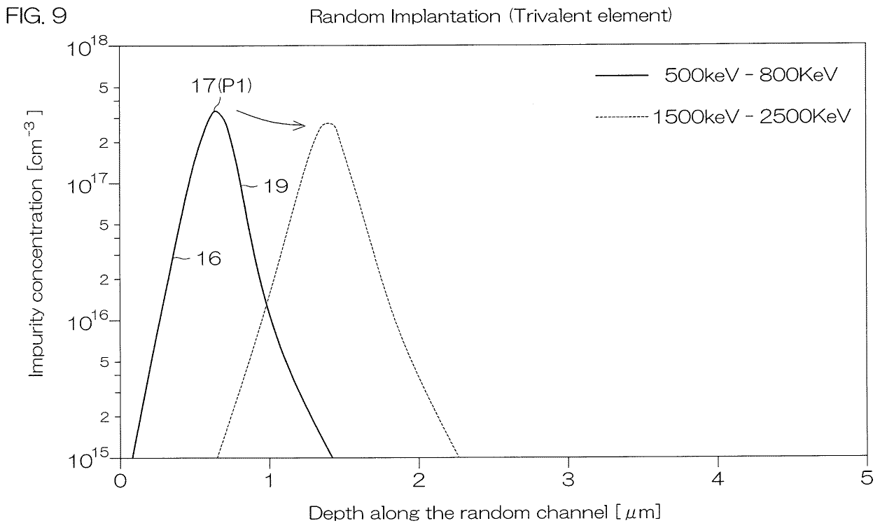

Hereinafter, an n-type concentration gradient of the impurity region 15 will be specifically described. FIG. 8 is a graph (a simulation) showing an example of a p-type concentration gradient of the impurity region 15. FIG. 9 is a graph (a simulation) showing a comparative example of the p-type concentration gradient of the impurity region 15. In FIGS. 8 and 9, the ordinate axis represents the p-type impurity concentration of the impurity region 15, and the abscissa represents a depth along the second axis channel C2 on the basis of the first main surface 3 (a zero point).

In FIGS. 8 and 9, a region having a p-type impurity concentration of not less than 1×10¹⁵ cm⁻³ is defined as the impurity region 15 and is shown as a graph. Numerical values of the impurity concentration, the thickness, etc., provided hereinafter are an example for describing a basic configuration of the impurity region 15 on the basis of the concentration gradient and are not provided with an intention of uniquely limiting the configuration of the impurity region 15. The impurity concentration, the thickness, etc., are adjusted to various values in accordance with an implantation condition (a dose amount, an implantation temperature, implantation energy, etc.) of a trivalent element, etc.

FIG. 8 is a graph in a case where the impurity region 15 is formed by a channeling implantation method. FIG. 8 shows a concentration gradient of the impurity region 15 when a predetermined trivalent element (here, aluminum) is introduced, into the semiconductor layer 7, parallel to or substantially parallel to the second axis channel C2 with an implantation energy of not less than 500 KeV and not more than 800 KeV.

The dose amount of the trivalent element is 1×10¹³ cm⁻². The thickness of the semiconductor layer 7 is approximately 5 μm. In FIG. 8, a concentration gradient in a case where the impurity region 15 is formed with the implantation energy of not less than 1500 KeV and not more than 2500 KeV is represented by a broken line.

Meanwhile, FIG. 9 is a graph in a case where the impurity region 15 is formed by a random implantation method. FIG. 9 shows a concentration gradient of the impurity region 15 when the predetermined trivalent element (here, aluminum) is introduced into the semiconductor layer 7 in a random direction with the implantation energy of not less than 500 KeV and not more than 800 KeV.

The random direction is a direction that is not parallel (substantially parallel) to the second axis channel C2 (for example, the vertical direction Z). The dose amount of the trivalent element is 1×10¹³ cm⁻². The thickness of the semiconductor layer 7 is approximately 5 μm. In FIG. 9, the concentration gradient in the case where the impurity region 15 is formed with the implantation energy of not less than 1500 KeV and not more than 2500 KeV is represented by a broken line.

With reference to FIG. 8, the impurity region 15 has a thickness of not less than 2.5 μm and not more than 2.8 μm and has the upper end portion separated from the first main surface 3 toward the lower end side of the semiconductor layer 7 and the lower end portion separated from the lower end toward the upper end side of the semiconductor layer 7. The impurity region 15 has a concentration gradient that gradually decreases from the upper end portion side toward the lower end portion side.

Specifically, the p-type impurity concentration of the impurity region 15 has a concentration gradient including a first gradual increase portion 16, a first peak portion 17, a first gentle gradient portion 18, and a first gradual decrease portion 19 from the upper end portion side toward the lower end portion side. The first gradual increase portion 16 is a portion forming the upper end portion of the impurity region 15 and has a p-type impurity concentration gradually increasing from the upper end portion toward the lower end portion side up to the first peak portion 17 at a relatively steep increase rate.

The first peak portion 17 is a portion having a first peak value P1 (a maximum value) of the p-type impurity concentration. The first peak portion 17 may also be a main concentration transition portion having a projecting shape which includes a series of concentration changes (inflection points) in which the p-type impurity concentration turns from an increase (an increasing tendency) to a decrease (a decreasing tendency).

The first gentle gradient portion 18 is formed in a region closer to the lower end portion than the first peak portion 17 and is a portion where the impurity concentration gently decreases at a relatively gentle decrease rate. That is, the first gentle gradient portion 18 is a portion, where a constant p-type impurity concentration is maintained in a constant depth range, and forms a main body portion of the impurity region 15. The p-type impurity concentration of the first gentle gradient portion 18 gently decreases in a concentration range less than the p-type impurity concentration of the first peak portion 17.

The first gentle gradient portion 18 is defined by a portion having a concentration decrease rate of not more than 50% in a thickness range of at least 0.5 μm. In the example in FIG. 8, the first gentle gradient portion 18 has a thickness of not less than 1 μm and not more than 1.3 μm and has the concentration decrease rate of not more than 50% in this thickness range.

The first gentle gradient portion 18 accounts for a thickness range of not less than 1/4 of the impurity region 15. Specifically, a ratio of the first gentle gradient portion 18 to the impurity region 15 is not less than 1/3. The ratio of the first gentle gradient portion 18 to the impurity region 15 is typically not more than 1/2 (less than 1/2). As a matter of course, the ratio of the first gentle gradient portion 18 to the impurity region 15 may be not less than 1/2.

The first gradual decrease portion 19 is a portion forming the lower end portion of the impurity region 15. The first gradual decrease portion 19 has a concentration decrease rate larger than the concentration decrease rate in the first gentle gradient portion 18 and is a portion where the p-type impurity concentration gradually decreases from the first gentle gradient portion 18 toward the lower end portion. The concentration decrease rate per unit thickness of the first gradual decrease portion 19 is larger than the concentration decrease rate per unit thickness of the first gentle gradient portion 18.

In the case of the channeling implantation method, the thickness (the depth) of the impurity region 15 increases as the implantation energy increases. A depth position of the upper end portion of the impurity region 15 with respect to the first main surface 3 increases as the implantation energy increases. A thickness of the first gradual increase portion 16, a thickness of the first peak portion 17, the thickness of the first gentle gradient portion 18, and a thickness of the first gradual decrease portion 19 all increase as the implantation energy increases. Meanwhile, the first peak value P1 of the impurity region 15 decreases as the implantation energy increases. This is because the trivalent element is introduced into a deeper region as the implantation energy increases, and the p-type impurity concentration of this deeper region increases.

Oppositely, the depth position of the upper end portion of the impurity region 15 with respect to the first main surface 3 decreases as the implantation energy decreases. The thickness of the first gradual increase portion 16, the thickness of the first peak portion 17, the thickness of the first gentle gradient portion 18, and the thickness of the first gradual decrease portion 19 all decrease as the implantation energy decreases. Meanwhile, the first peak value P1 of the impurity region 15 increases as the implantation energy decreases. This is because the trivalent element is captured in a shallow region as the injection energy decreases.

Meanwhile, with reference to FIG. 9, in the case of the random implantation method, the impurity region 15 has the first gradual increase portion 16, the first peak portion 17 (the first peak value P1), and the first gradual decrease portion 19 in a range of 0.5 μm, but does not have the first gentle gradient portion 18 having the thickness of not less than 0.5 μm. Also, in the case of the random implantation method, a depth position of the first peak portion 17 (the first peak value P1) with respect to the first main surface 3 increased as the implantation energy increased, but the thickness of the impurity region 15 was less than 2 μm. That is, even when the implantation energy was increased, the thickness did not significantly vary.

This leads to an understanding that the SiC monocrystal has physical properties that make it difficult for impurities to diffuse, thus making it difficult for the impurity region 15 having a relatively large thickness (for example, the thickness of not less than 1 μm and not more than 5 μm) which is constituted of a single region to be formed with respect to the semiconductor layer 7 having the relatively large second thickness T2 (for example, not less than 1 μm), in the case of the random implantation method.

With reference to FIGS. 6 and 7, the SiC semiconductor device 1 includes a body region 20 of the p-type formed in a surface layer portion of the first main surface 3 (active surface 10). In this embodiment, the body region 20 is formed in a layer shape extending along the active surface 10. The body region 20 may be formed in the entire region of the active surface 10 and may be exposed from the first to fourth connecting surfaces 12A to 12D. The body region 20 is formed at an interval from the lower end of the semiconductor layer 7 toward the active surface 10 side.

It is preferable that the body region 20 is formed at an interval from a depth position of the outer surface 11 toward the active surface 10 side and is exposed from the active surface 10. In a case where the impurity region 15 is formed at an interval from the first main surface 3, the body region 20 is formed in a region between the first main surface 3 and the impurity region 15 and is connected to the impurity region 15. In a case where the impurity region 15 is exposed from the first main surface 3, the body region 20 is formed in a surface layer portion of the impurity region 15 and is connected to the impurity region 15.

The body region 20 is constituted of a random region introduced in a surface layer portion of the semiconductor layer 7 by the random implantation method with respect to the semiconductor layer 7. Therefore, unlike the impurity region 15, the body region 20 does not have a gentle gradient portion similar to the first gentle gradient portion 18. The body region 20 has a thickness less than the thickness of the impurity region 15 in a direction along the second axis channel C2.

The body region 20 may have a p-type impurity concentration of not less than 1×10¹⁵ cm⁻³ and not more than 1×10¹⁸ cm⁻³ as a peak value. The p-type impurity concentration of the body region 20 is preferably adjusted by at least one type of trivalent element. The trivalent element of the body region 20 may be at least one type among boron, aluminum, gallium, and indium.

The body region 20 does not necessarily have to be formed. For example, in a case where a part (the surface layer portion) of the impurity region 15 can function as a part of the body region 20, the part (the surface layer portion) of the impurity region 15 may be formed as the body region 20, and the body region 20 may be omitted. In other words, the surface layer portion of the impurity region 15 may also serve as the body region 20, and the body region 20 may be formed using the surface layer portion of the impurity region 15. Such a configuration is applicable to both a case where the impurity region 15 is formed at an interval from the first main surface 3 toward the lower end side of the semiconductor layer 7 and a case where the impurity region 15 is exposed from the first main surface 3.

The SiC semiconductor device 1 includes a plurality of the trench structures 25 of a trench electrode type formed in the first main surface 3 (the active surface 10) in the active region 8. The trench structure 25 may be referred to as a “gate structure,” a “trench gate structure,” etc. A gate potential as a control potential is applied to the plurality of trench structures 25. The plurality of trench structures 25 control inversion and non-inversion of channels Ch (see FIG. 7) as current paths in the body region 20 in response to the gate potential.

The plurality of trench structures 25 are arranged at intervals inward from the peripheral edges (the first to fourth connecting surfaces 12A to 12D) of the active surface 10 in the active region 8. In this embodiment, the plurality of trench structures 25 are arrayed at intervals in the first direction X and are each formed as a band extending in the second direction Y.

That is, the plurality of trench structures 25 are arrayed at intervals in the m-axis direction and each extend in the a-axis direction. Also, in this embodiment, the plurality of trench structures 25 are arrayed as stripes extending in the a-axis direction (the second direction Y). An extension direction of the plurality of trench structures 25 is matched with the off direction Do of the semiconductor layer 7.

The plurality of trench structures 25 are formed at intervals from the lower end (the base layer 6) of the semiconductor layer 7 toward the first main surface 3 (the active surface 10) side and oppose the base layer 6 across a part of the semiconductor layer 7. The plurality of trench structures 25 define a lower region 7a in a region between the lower end (the base layer 6) of the semiconductor layer 7 and bottom walls of the plurality of trench structures 25.

In this embodiment, the plurality of trench structures 25 are formed at intervals from the bottom portion of the impurity region 15 toward the first main surface 3 (the active surface 10) side and oppose a part (the lower end portion) of the semiconductor layer 7 across a part (the lower end portion) of the impurity region 15. That is, the plurality of trench structures 25 are formed shallower than the impurity region 15 and define the lower region 7a including a part (the lower end portion) of the impurity region 15. In this embodiment, the lower region 7a includes a part (the lower end portion) of the semiconductor layer 7 and a part (the lower end portion) of the impurity region 15.

The plurality of trench structures 25 are preferably formed at intervals from a thickness range intermediate portion of the impurity region 15 toward the active surface 10 side. As a matter of course, the plurality of trench structures 25 may be formed at a depth position crossing the thickness range intermediate portion of the impurity region 15.

Each of the trench structures 25 has a trench width WT in an array direction and a trench depth DT in the vertical direction Z. The trench width WT is preferably less than the second thickness T2 of the semiconductor layer 7. The trench width WT is preferably less than the thickness of the impurity region 15. The trench width WT may be not less than 0.1 μm and not more than 5 μm.

The trench width WT may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The trench depth DT is preferably less than the second thickness T2 of the semiconductor layer 7. The trench depth DT is preferably less than the thickness of the impurity region 15. Particularly preferably, the trench depth DT is substantially equal to the outer depth DO described above. As a matter of course, the trench depth DT may be not less than the outer depth DO or may be less than the outer depth DO.

The trench depth DT is preferably larger than the trench width WT. That is, each of the plurality of trench structures 25 preferably has an aspect ratio DT/WT extending in a vertically long columnar shape. The aspect ratio DT/WT is a ratio of the trench depth DT to the trench width WT. The trench depth DT may be not less than 0.1 μm and not more than 5 μm.

The trench depth DT may have a value falling within any one of ranges of not less than 0.1 μm and not more than 0.25 μm, not less than 0.25 μm and not more than 0.5 μm, not less than 0.5 μm and not more than 1 μm, not less than 1 μm and not more than 1.5 μm, not less than 1.5 μm and not more than 2 μm, not less than 2 μm and not more than 3 μm, not less than 3 μm and not more than 4 μm, and not less than 4 μm and not more than 5 μm. The trench depth DT is preferably not less than 0.1 μm and not more than 1.5 μm.

The plurality of trench structures 25 are arrayed at intervals of a trench pitch PT in the first direction X. The trench pitch PT is preferably less than the second thickness T2 of the semiconductor layer 7. The trench pitch PT is preferably less than the thickness of the impurity region 15. The trench pitch PT is preferably less than the trench depth DT. The trench pitch PT may be not less than 0.1 μm and not more than 5 μm.

The trench pitch PT may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The trench pitch PT is preferably not less than 0.5 μm and not more than 1.5 μm.

Each of the trench structures 25 includes a trench 26, an insulating film 27, and an embedded electrode 28. The trench 26 is formed in the active surface 10 and defines wall surfaces (side walls and a bottom wall) of the trench structure 25. The bottom wall of the trench 26 preferably has a portion that extends flatly.

It is particularly preferable that a flat portion of the bottom wall extends substantially parallel to the first main surface 3. That is, it is preferable that the bottom wall of the trench 26 has the off angle θo inclined at a predetermined angle in the predetermined off direction Do with respect to the c-plane. That is, the bottom wall of the trench 26 preferably has the flat portion extending in the off direction Do. As a matter of course, the bottom wall may be curved in an arc shape toward the lower end side of the semiconductor layer 7.

The insulating film 27 covers the wall surfaces of the trench 26. The insulating film 27 may include at least one of a silicon oxide film, a silicon nitride film, and a silicon oxynitride film. In this embodiment, the insulating film 27 has a single layer structure constituted of the silicon oxide film. The insulating film 27 particularly preferably includes the silicon oxide film constituted of an oxide of the chip 2.

The embedded electrode 28 is embedded in the trench 26 and opposes the channel Ch across the insulating film 27. In this embodiment, the embedded electrode 28 opposes the impurity region 15 and the body region 20 across the insulating film 27. The embedded electrode 28 may include a conductive polysilicon of the p-type or the n-type.

The SiC semiconductor device 1 includes a plurality of inversion columns 30 of the n-type formed at intervals in the horizontal direction in the semiconductor layer 7. The inversion column 30 may be referred to as a “first column region,” an “inversion column region,” a “drift region,” an “inversion drift region,” etc. The inversion column 30 has an n-type impurity concentration higher than the p-type impurity concentration of the impurity region 15 and inverts the conductivity type of the impurity region 15 from the p-type to the n-type.

That is, the inversion column 30 includes a pentavalent element in addition to the trivalent element establishing the conductivity type of the impurity region 15. The inversion column 30 may have an n-type impurity concentration of not less than 1×10¹⁵ cm⁻³ and not more than 1×10¹⁸ cm⁻³ as a peak value. The n-type impurity concentration of the inversion column 30 is preferably adjusted by at least one type of pentavalent element. For example, the n-type impurity concentration of the inversion column 30 may be adjusted by at least one type among nitrogen, phosphorus, arsenic, antimony, and bismuth.

The inversion column 30 preferably includes a pentavalent element other than nitrogen and phosphorus. The n-type impurity concentration of the inversion column 30 is preferably adjusted by at least one type among arsenic, antimony, and bismuth. In view of easy availability, the n-type impurity concentration of the inversion column 30 is preferably adjusted by arsenic or antimony.

The plurality of inversion columns 30 are formed in the lower region 7a in the semiconductor layer 7. That is, the plurality of inversion columns 30 are formed in a thickness range between the lower end of the semiconductor layer 7 and the bottom walls of the plurality of trench structures 25. Specifically, the plurality of inversion columns 30 are arrayed at intervals in the first direction X in the lower region 7a and are each formed as a band extending in the second direction Y.

That is, the plurality of inversion columns 30 are arrayed at intervals in the m-axis direction and extend in the a-axis direction of the SiC monocrystal. Also, the plurality of inversion columns 30 are formed as stripes extending in the a-axis direction (the second direction Y), and an extension direction of the plurality of inversion columns 30 is matched with the off direction Do of the semiconductor layer 7.

The plurality of inversion columns 30 overlap the plurality of trench structures 25 in the lamination direction. Specifically, the plurality of inversion columns 30 overlap the plurality of trench structures 25 in the lamination direction in a one-to-one correspondence relationship. The plurality of inversion columns 30 are formed at intervals inward from the peripheral edges (the first to fourth connecting surfaces 12A to 12D) of the active surface 10 in the active region 8.

With regard to the second direction Y, both end portions of the plurality of inversion columns 30 may be positioned on an inner side of the active region 8 with respect to both end portions of the plurality of trench structures 25. With regard to the second direction Y, both the end portions of the plurality of inversion columns 30 may be positioned on the peripheral edge side of the active region 8 with respect to both the end portions of the plurality of trench structures 25.

In a case where the peripheral edge portions of the impurity region 15 are positioned in the active region 8, both the end portions of the plurality of inversion columns 30 may be positioned on the inner side of the active region 8 with respect to the peripheral edge portions (both end portions) of the impurity region 15. As a matter of course, both the end portions of the plurality of inversion columns 30 may be positioned on the peripheral edge side of the active region 8 with respect to the peripheral edge portions (both the end portions) of the impurity region 15.

Each of the plurality of inversion columns 30 has an upper end portion positioned on the bottom wall side of the trench structure 25 and a lower end portion positioned on the lower end side of the semiconductor layer 7. In this embodiment, the upper end portion of each of the plurality of inversion columns 30 is positioned in a region on the bottom wall side of the trench structure 25 with respect to a thickness range intermediate portion of the lower region 7a, and the lower end portion of each of the plurality of inversion columns 30 is positioned in a region on the lower end side of the semiconductor layer 7 with respect to the thickness range intermediate portion of the lower region 7a.

The upper end portions of the plurality of inversion columns 30 are formed at intervals on the lower end side of the semiconductor layer 7 with respect to the depth position of the outer surface 11. The upper end portions of the plurality of inversion columns 30 are formed at intervals from the bottom walls of the plurality of trench structures 25 toward the lower end side of the semiconductor layer 7 and oppose the plurality of trench structures 25 across a part of the impurity region 15. That is, the upper end portions of the plurality of inversion columns 30 are electrically connected to the impurity region 15 having a relatively high concentration. As a matter of course, the upper end portions of the plurality of inversion columns 30 may be connected to the bottom walls of the plurality of trench structures 25.

An intermediate distance between the bottom walls of the plurality of trench structures 25 and the upper end portions of the plurality of inversion columns 30 may be not less than 0 μm and not more than 1 μm. The intermediate distance may have a value falling within any one of ranges of not less than 0 μm and not more than 0.25 μm, not less than 0.25 μm and not more than 0.5 μm, not less than 0.5 μm and not more than 0.75 μm, and not less than 0.75 μm and not more than 1 μm.

The lower end portions of the plurality of inversion columns 30 cross the bottom portion of the impurity region 15 and are led out to a lower layer portion of the semiconductor layer 7. That is, each of the plurality of inversion columns 30 includes a portion positioned in a region between the bottom portion of the impurity region 15 and the bottom wall of each of the plurality of trench structures 25, and a portion positioned in a region between the lower end of the semiconductor layer 7 and the bottom portion of the impurity region 15. The lower end portions of the plurality of inversion columns 30 are electrically connected to the lower layer portion of the semiconductor layer 7. That is, the plurality of inversion columns 30 are electrically connected to the base layer 6 through a part of the semiconductor layer 7.

A cross-sectional area of a portion of each of the plurality of inversion columns 30 which is positioned in the impurity region 15 is preferably larger than a cross-sectional area of a portion of each of the plurality of inversion columns 30 which is positioned in the semiconductor layer 7. As a matter of course, the cross-sectional area of the portion of each of the plurality of inversion columns 30 which is positioned in the impurity region 15 may be smaller than the cross-sectional area of a portion of each of the plurality of inversion columns 30 which is positioned in the semiconductor layer 7.

In this embodiment, the lower end portions of the plurality of inversion columns 30 are formed at intervals from the lower end of the semiconductor layer 7 toward the bottom portion side of the impurity region 15 and oppose the base layer 6 across a part of the semiconductor layer 7. As a matter of course, the lower end portions of the plurality of inversion columns 30 may cross the boundary portion between the base layer 6 and the semiconductor layer 7 and may be positioned in the base layer 6. In a case where the lower end portion of the impurity region 15 is positioned in the base layer 6, the lower end portions of the plurality of inversion columns 30 may cross the bottom portion of the impurity region 15 in the base layer 6.

A lower end distance between the lower end of the semiconductor layer 7 and the lower end portion of each of the plurality of inversion columns 30 may be not less than 0 μm and not more than 2 μm. The lower end distance may have a value falling within any one of ranges of not less than 0 μm and not more than 0.5 μm, not less than 0.5 μm and not more than 1 μm, not less than 1 μm and not more than 1.5 μm, and not less than 1.5 μm and not more than 2 μm.

The plurality of inversion columns 30 are constituted of channeling regions extending along the second axis channel C2 in cross-sectional view. That is, the inversion column 30 is an impurity region introduced parallel to or substantially parallel to the regions (the second axis channel C2) surrounded by atomic rows along the low-index crystal axis in the semiconductor layer 7 and inclinedly extends with respect to the first main surface 3.

Therefore, the plurality of inversion columns 30 have the off direction Do and the off angle θo that are substantially matched with the off direction Do and the off angle θo of the second axis channel C2. In other words, the plurality of inversion columns 30 are inclined by the off angle θo from the vertical axis toward the off direction Do. That is, the plurality of inversion columns 30 are each constituted of a single impurity region having a thickness (a depth) that crosses the intermediate portion of the lower region 7a along the second axis channel C2.

Each of the plurality of inversion columns 30 has a column width WC in the array direction. The column width WC may be substantially equal to the trench width WT. The column width WC may be larger than the trench width WT. The column width WC may be less than the trench width WT. The column width WC may be less than the trench depth DT. The column width WC may be larger than the trench depth DT. The column width WC is preferably less than the second thickness T2 of the semiconductor layer 7. The column width WC is preferably less than the thickness of the impurity region 15.

The column width WC may be not less than 0.1 μm and not more than 5 μm. The column width WC may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

Each of the plurality of inversion columns 30 has a column thickness TC (a region depth). The column thickness TC is preferably less than the second thickness T2 of the semiconductor layer 7. The column thickness TC is preferably less than the thickness of the impurity region 15. The column thickness TC is particularly preferably not less than the trench depth DT. The column thickness TC is preferably larger than the trench width WT. The column thickness TC is particularly preferably larger than the trench depth DT. As a matter of course, the column thickness TC may be less than the trench depth DT.

The column thickness TC may be not less than one time and not more than five times the trench depth DT. A ratio TC/DT of the column thickness TC to the trench depth DT may have a value falling within any one of ranges of not less than 1 and not more than 1.5, not less than 1.5 and not more than 2, not less than 2 and not more than 2.5, not less than 2.5 and not more than 3, not less than 3 and not more than 3.5, not less than 3.5 and not more than 4, not less than 4 and not more than 4.5, and not less than 4.5 and not more than 5.

The column thickness TC is preferably larger than the column width WC. That is, each of the plurality of inversion columns 30 preferably has an aspect ratio TC/WC extending in a vertically long columnar shape along the second axis channel C2. The aspect ratio TC/WC is a ratio of the column thickness TC to the column width WC. The column thickness TC is preferably not less than 1 μm and not more than 5 μm.

The column thickness TC may have a value falling within any one of ranges of not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The plurality of inversion columns 30 is formed at an interval of a column pitch PC in the array direction. The column pitch PC may be substantially equal to the trench pitch PT. The column pitch PC may be larger than the trench pitch PT. The column pitch PC may be less than the trench pitch PT.

The column pitch PC is preferably less than the column thickness TC. The column pitch PC is preferably less than the trench depth DT. The column pitch PC is preferably less than the second thickness T2 of the semiconductor layer 7. The column pitch PC is preferably less than the thickness of the impurity region 15. The column pitch PC may be not less than 0.1 μm and not more than 5 μm.

The column pitch PC may have a value falling within any one of ranges of not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The column pitch PC is preferably not less than 0.5 μm and not more than 1.5 μm.

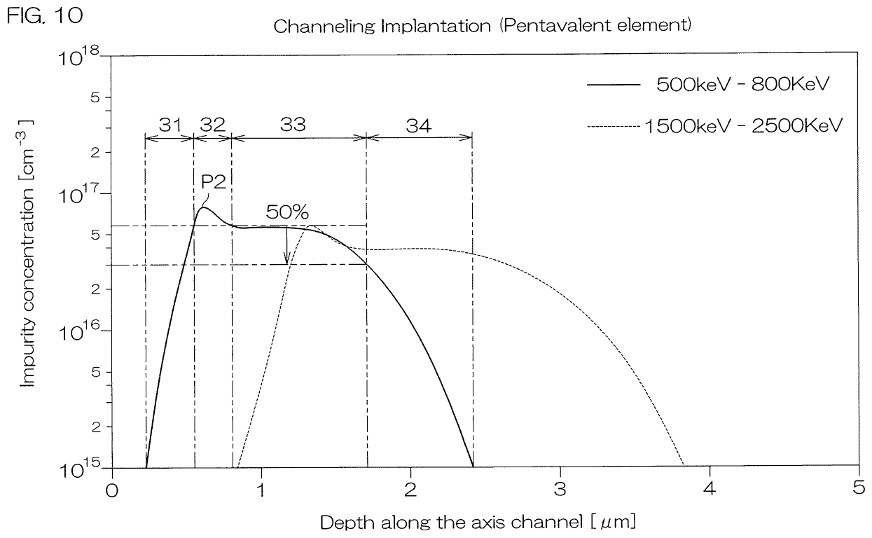

Hereinafter, an n-type concentration gradient of the inversion column 30 will be specifically described. FIG. 10 is a graph showing an example of the n-type concentration gradient of the inversion column 30. In FIG. 10, the ordinate axis represents the n-type impurity concentration of the inversion column 30, and the abscissa represents a depth along the second axis channel C2 on the basis of the bottom wall of the trench structure 25 (a zero point).

In FIG. 10, a region having an n-type impurity concentration of not less than 1×10¹⁵ cm⁻³ is defined as the inversion column 30 and is shown as a graph. Numerical values of an impurity concentration, a thickness, etc., provided hereinafter are an example for describing a basic configuration of the inversion column 30 based on the concentration gradient and are not provided with an intention of uniquely limiting the configuration of the inversion column 30. The impurity concentration, the thickness, etc., are adjusted to various values in accordance with an implantation condition (a dose amount, an implantation temperature, implantation energy, etc.), etc., of a pentavalent element.

FIG. 10 is a graph in a case where the inversion column 30 is formed by a channeling implantation method. FIG. 10 illustrates a concentration gradient of the inversion column 30 when a predetermined pentavalent element (arsenic in this case) is introduced, into the lower region 7a, parallel to or substantially parallel to the second axis channel C2 by an implantation energy of not less than 500 KeV and not more than 800 KeV.

The dose amount of the pentavalent element is 1×10¹³ cm⁻². The trench depth DT is approximately 1 μm, and the thickness of the lower region 7a is approximately 4 μm. In FIG. 10, the concentration gradient in the case where the inversion column 30 is formed with an implantation energy of not less than 1500 KeV and not more than 2500 KeV is represented by a broken line.

With reference to FIG. 10, the inversion column 30 has a thickness of not less than 2.1 μm and not more than 2.4 μm and has the upper end portion separated from the bottom wall of the trench structure 25 toward the bottom portion side of the impurity region 15 and the lower end portion separated from the bottom portion of the impurity region 15 toward the bottom wall side of the trench structure 25. The inversion column 30 has a concentration gradient that gradually decreases from the upper end portion side toward the lower end portion side.

Specifically, the n-type impurity concentration of the inversion column 30 has a concentration gradient including a second gradual increase portion 31, a second peak portion 32, a second gentle gradient portion 33, and a second gradual decrease portion 34 from the upper end portion side toward the lower end portion side. The second gradual increase portion 31 is a portion forming the upper end portion of the inversion column 30 and has an n-type impurity concentration gradually increasing from the upper end portion toward the lower end portion side up to the second peak portion 32 at a relatively steep increase rate. In this embodiment, the second gradual increase portion 31 is positioned in the impurity region 15 and is electrically connected to the impurity region 15.

The second peak portion 32 is a portion having a second peak value P2 (a maximum value) of the n-type impurity concentration. The second peak portion 32 may also be a main concentration transition portion having a projecting shape which includes a series of concentration changes (inflection points) in which the n-type impurity concentration turns from an increase (an increasing tendency) to a decrease (a decreasing tendency). The second peak portion 32 is electrically connected to the impurity region 15. In this embodiment, the second peak value P2 is positioned closer to the bottom portion of the impurity region 15 than the first peak value P1 of the impurity region 15.

The second gentle gradient portion 33 is formed in a region closer to the lower end portion than the second peak portion 32 and is a portion where the impurity concentration gently decreases at a relatively gentle decrease rate. That is, the second gentle gradient portion 33 is a portion, where a constant n-type impurity concentration is maintained in a constant depth range, and forms a main body portion of the inversion column 30. The n-type impurity concentration of the second gentle gradient portion 33 gently decreases in a concentration range less than the n-type impurity concentration of the second peak portion 32.

The second gentle gradient portion 33 is defined by a portion having a concentration decrease rate of not more than 50% in a thickness range of at least 0.5 μm. In the example in FIG. 10, the second gentle gradient portion 33 has a thickness of not less than 0.8 μm and not more than 1.1 μm and has the concentration decrease rate of not more than 50% in this thickness range. The second gentle gradient portion 33 is positioned in the impurity region 15 and is electrically connected to the impurity region 15. The second gentle gradient portion 33 may have a portion positioned in a thickness range between the lower end of the semiconductor layer 7 and the bottom portion of the impurity region 15 and may be electrically connected to the semiconductor layer 7.

The second gentle gradient portion 33 accounts for a thickness range of not less than 1/4 of the inversion column 30. Specifically, a ratio of the second gentle gradient portion 33 to the inversion column 30 is not less than 1/3. The ratio of the second gentle gradient portion 33 to the inversion column 30 is typically not more than 1/2 (less than 1/2). As a matter of course, the ratio of the second gentle gradient portion 33 to the inversion column 30 may be not less than 1/2.

The second gradual decrease portion 34 is a portion forming the lower end portion of the inversion column 30. The second gradual decrease portion 34 has a concentration decrease rate larger than the concentration decrease rate in the second gentle gradient portion 33 and is a portion where the n-type impurity concentration gradually decreases from the second gentle gradient portion 33 toward the lower end portion. The concentration decrease rate per unit thickness of the second gradual decrease portion 34 is larger than the concentration decrease rate per unit thickness of the second gentle gradient portion 33. The second gradual decrease portion 34 may be positioned in a thickness range between the lower end of the semiconductor layer 7 and the lower end portion of the impurity region 15 and may be electrically connected to the semiconductor layer 7.

In the case of the channeling implantation method, the thickness (the depth) of the inversion column 30 increases as the implantation energy increases. A depth position of the upper end portion of the inversion column 30 with respect to the bottom wall of the trench structure 25 increases as the implantation energy increases. A thickness of the second gradual increase portion 31, a thickness of the second peak portion 32, the thickness of the second gentle gradient portion 33, and a thickness of the second gradual decrease portion 34 all increase as the implantation energy increases. Meanwhile, the second peak value P2 of the inversion column 30 decreases as the implantation energy increases. This is because the pentavalent element is introduced into a deeper region as the implantation energy increases, and the n-type impurity concentration of this deeper region increases.

Oppositely, the depth position of the upper end portion of the inversion column 30 with respect to the bottom wall of the trench structure 25 decreases as the implantation energy decreases. The thickness of the second gradual increase portion 31, the thickness of the second peak portion 32, the thickness of the second gentle gradient portion 33, and the thickness of the second gradual decrease portion 34 all decrease as the implantation energy decreases. Meanwhile, the second peak value P2 of the inversion column 30 increases as the implantation energy decreases. This is because the introduction of the pentavalent element is inhibited in a shallow region as the implantation energy decreases.

In the case of the inversion column 30, since the pentavalent element is introduced into the semiconductor layer 7 instead of a trivalent element, it should be noted that even if identical process conditions to process conditions of the impurity region 15 are set, a concentration profile or a thickness (a depth) of the inversion column 30 is different from a concentration profile or a thickness (a depth) of the impurity region 15. Therefore, in order to achieve an appropriate charge balance, the process conditions of the inversion column 30 and the process conditions of the impurity region 15 are preferably set independently of each other.

The SiC semiconductor device 1 includes a plurality of non-inversion columns 35 of the p-type formed in the semiconductor layer 7. The non-inversion column 35 may be referred to as a “second column region,” a “non-inversion column region,” etc. The plurality of non-inversion columns 35 are respectively constituted of regions of the impurity region 15 which are defined by the plurality of inversion columns 30.

That is, the plurality of non-inversion columns 35 are each constituted of a channeling region of the p-type extending along the second axis channel C2. Also, the plurality of non-inversion columns 35 are arrayed at intervals in the first direction X (the m-axis direction) in the semiconductor layer 7 (the lower region 7a) and are each defined as a band extending in the second direction Y (the a-axis direction). Also, the plurality of non-inversion columns 35 overlap regions between the plurality of trench structures 25 in the lamination direction.

The plurality of non-inversion columns 35 form a plurality of pn-junction portions having charge balance together with the plurality of inversion columns 30. The state of having the charge balance means a state in which, with regard to the plurality of non-inversion columns 35 adjacent to each other, a depletion layer expanding from one pn-junction portion and a depletion layer expanding from the other pn-junction portion are connected in the plurality of inversion columns 30.

In this embodiment, the plurality of p-type non-inversion columns 35 subjected to concentration adjustment by the trivalent element (the impurity region 15) form the charge balance with the plurality of n-type inversion columns 30 subjected to concentration adjustment by the pentavalent element. The plurality of non-inversion columns 35 constitute a super junction structure with the plurality of inversion columns 30 in the lower region 7a.

The SiC semiconductor device 1 includes a plurality of intermediate regions 36 of the n-type formed in respective regions directly below the plurality of trench structures 25 in the semiconductor layer 7. In this embodiment, the single intermediate region 36 is interposed in a region between the bottom wall of the single trench structure 25 and the upper end portion of the single inversion column 30. Also, the plurality of intermediate regions 36 are arrayed at intervals in the first direction X (the m-axis direction) in the lower region 7a and are each formed as a band extending in the second direction Y (the a-axis direction).

With regard to one and the other trench structures 25, the intermediate region 36 on one side positioned directly below the one trench structure 25 is formed at an interval in the array direction (the first direction X) of the plurality of trench structures 25 from the intermediate region 36 on the other side positioned directly below the other trench structure 25. The plurality of intermediate regions 36 on one side oppose the plurality of intermediate regions 36 on the other side in the array direction (the first direction X) across a part of the impurity region 15.

Each of the intermediate regions 36 is connected to the bottom wall of the trench structure 25 and the upper end portion of the inversion column 30. Each of the intermediate regions 36 further has portions that protrude from a region directly below each of the trench structure 25 to both sides of the trench structure 25 and extend along side walls of the trench structure 25.

Each of the intermediate regions 36 is formed at an interval from the bottom portion of the body region 20 toward the bottom wall side of the trench structure 25 and opposes the body region 20 across a part of the impurity region 15. As a matter of course, each of the intermediate regions 36 may be connected to the bottom portion of the body region 20. Also, each of the intermediate regions 36 may be formed to be narrower than the bottom wall of the trench structure 25 and may be formed only along the bottom wall of the trench structure 25.

With regard to the second direction Y, both end portions of each of the intermediate regions 36 may be positioned on an inner side of the active region 8 with respect to both end portions of the corresponding trench structure 25. With regard to the second direction Y, both the end portions of the plurality of inversion columns 30 may be positioned on the peripheral edge side of the active region 8 with respect to both the end portions of the plurality of trench structures 25.

The plurality of intermediate regions 36 form a plurality of intermediate pn-junction portions having charge balance together with the plurality of non-inversion columns 35. That is, the plurality of intermediate regions 36 constitute a part of the super junction structure together with the plurality of non-inversion columns 35. The state of having the charge balance means a state in which, with regard to the plurality of intermediate regions 36 adjacent to each other, a depletion layer expanding from one intermediate pn-junction portion and a depletion layer expanding from the other intermediate pn-junction portion are connected in the plurality of non-inversion columns 35.

The plurality of intermediate regions 36 are each constituted of a random region introduced in a surface layer portion of each of the plurality of non-inversion columns 35 by the random implantation method with respect to the semiconductor layer 7. That is, the plurality of intermediate regions 36 have a thickness less than the thickness of the plurality of inversion columns 30 in the direction along the second axis channel C2. Also, the plurality of intermediate regions 36 do not have the second gentle gradient portion 33 having a thickness of not less than 0.5 μm in regard to the direction along the second axis channel C2.

The plurality of intermediate regions 36 may have an n-type impurity concentration of not less than 1×10¹⁵ cm⁻³ and not more than 1×10¹⁸ cm⁻³ as a peak value. The plurality of intermediate regions 36 may have the n-type impurity concentration (the peak value) higher than the n-type impurity concentration (the peak value) of the plurality of inversion columns 30. As a matter of course, the n-type impurity concentration (the peak value) of the plurality of intermediate regions 36 may be less than the n-type impurity concentration (the peak value) of the plurality of inversion columns 30.

The n-type impurity concentration of the intermediate region 36 is preferably adjusted by at least one type of pentavalent element. For example, the n-type impurity concentration of the intermediate region 36 may be adjusted by at least one type among nitrogen, phosphorus, arsenic, antimony, and bismuth. The intermediate region 36 preferably includes at least phosphorus.

The SiC semiconductor device 1 includes a plurality of source regions 37 formed on both sides of each of the plurality of trench structures 25 in the surface layer portion of the first main surface 3 (the active surface 10). The plurality of source regions 37 are formed in a surface layer portion of body region 20. The plurality of source regions 37 have an n-type impurity concentration (a peak value) higher than that of the semiconductor layer 7.

The n-type impurity concentration (the peak value) of the plurality of source regions 37 is preferably higher than the n-type impurity concentration (the peak value) of the inversion columns 30. The n-type impurity concentration (the peak value) of the plurality of source regions 37 is particularly preferably higher than the n-type impurity concentration (the peak value) of the intermediate regions 36. The plurality of source regions 37 may have an n-type impurity concentration of not less than 1×10¹⁸ cm⁻³ and not more than 1×10²¹ cm⁻³ as a peak value.

The plurality of source regions 37 extend as bands in the extension direction of the corresponding trench structures 25 in plan view. The plurality of source regions 37 are formed at intervals from the bottom portion of the body region 20 toward the active surface 10 side. The plurality of source regions 37 define, together with the intermediate regions 36 positioned directly below the source regions 37, the channels Ch as current paths extending along the wall surfaces of the corresponding trench structures 25. In this embodiment, the plurality of source regions 37 oppose a part of the impurity region 15 across a part of the body region 20 in the lamination direction. Therefore, the channel Ch is formed in a part of the impurity region 15 and a part of the body region 20.

The SiC semiconductor device 1 includes a plurality of contact regions 38 formed in regions between the plurality of trench structures 25 in the surface layer portion of the first main surface 3 (the active surface 10). The plurality of contact regions 38 are formed in the surface layer portion of the body region 20.

The plurality of contact regions 38 have a p-type impurity concentration (a peak value) higher than the p-type impurity concentration (the peak value) of the impurity region 15. The p-type impurity concentration (the peak value) of the plurality of contact regions 38 is higher than the p-type impurity concentration (the peak value) of the body region 20. The plurality of contact regions 38 may have a p-type impurity concentration of not less than 1×10¹⁸ cm⁻³ and not more than 1×10²¹ cm⁻³ as a peak value.

The plurality of contact regions 38 are interposed in regions between the plurality of source regions 37 adjacent to each other and each extend as a band in the extension direction of the plurality of trench structures 25. The plurality of contact regions 38 are formed at intervals from the bottom portion of the body region 20 toward the active surface 10 side and oppose the non-inversion columns 35 directly below the body region 20 across a part of the body region 20 in the lamination direction.

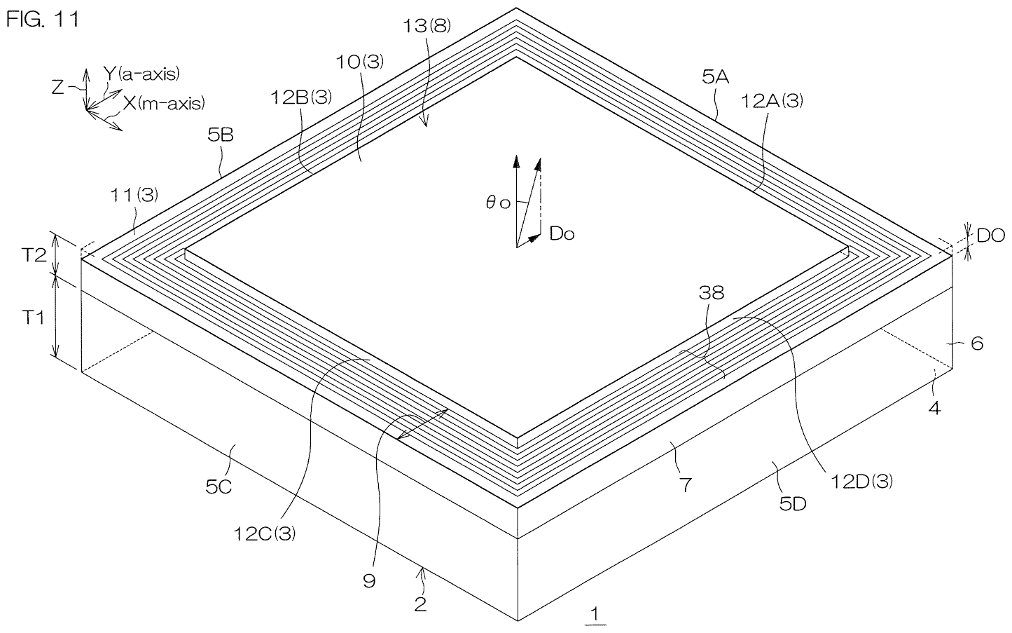

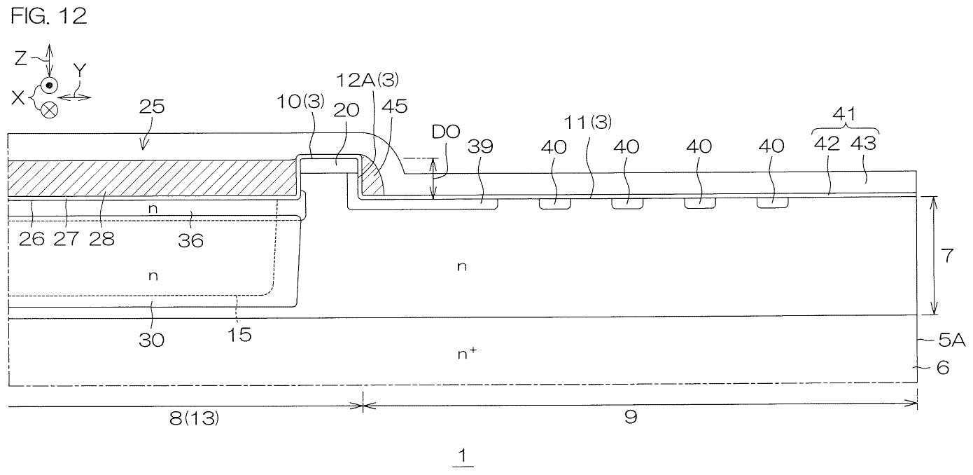

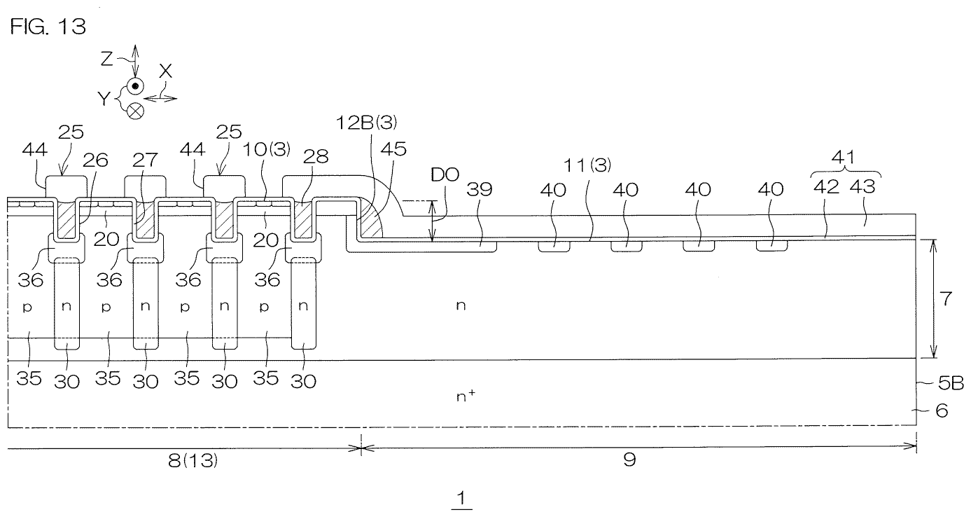

Hereinafter, a configuration on the outer peripheral region 9 side will be described. FIG. 11 is a perspective view showing a configuration of the outer peripheral region 9. FIG. 12 is a cross-sectional view showing a main portion of the outer peripheral region 9. FIG. 13 is a cross-sectional view showing the main portion of the outer peripheral region 9.

The SiC semiconductor device 1 includes a well region 39 of the p-type formed in a surface layer portion of the outer surface 11. The well region 39 is formed at intervals from the peripheral edges (the first to fourth side surfaces 5A to 5D) of the outer surface 11 toward the active surface 10 side and extends as a band along the active surface 10 in plan view. In this embodiment, the well region 39 is formed in a annular shape (specifically, a quadrangular annular shape) surrounding the active surface 10 in plan view.

The well region 39 is led out from the surface layer portion of the outer surface 11 toward the first to fourth connecting surfaces 12A to 12D side and extends along surface layer portions of the first to fourth connecting surfaces 12A to 12D. The well region 39 is electrically connected to the body region 20 in the surface layer portion of the active surface 10.

The well region 39 is formed at an interval from the lower end of the semiconductor layer 7 toward the outer surface 11 side and opposes the base layer 6 across a part of the semiconductor layer 7. Specifically, the well region 39 is formed at an interval from the bottom portion of the impurity region 15 toward the outer surface 11 side and is positioned closer to the bottom portion side of the impurity region 15 than the bottom wall of the trench structure 25. The well region 39 forms a pn-junction portion with the semiconductor layer 7 (the impurity region 15).

The well region 39 is constituted of a random region introduced in the surface layer portion of the semiconductor layer 7 by the random implantation method with respect to the semiconductor layer 7. The well region 39 has a thickness less than the thickness of the impurity region 15 in the direction along the second axis channel C2. Also, the thickness of the well region 39 is less than the thickness of the inversion column 30.

Unlike the inversion column 30, the well region 39 does not have a gentle gradient portion having a thickness of not less than 0.5 μm. The well region 39 may have a p-type impurity concentration of not less than 1×10¹⁵ cm⁻³ and not more than 1×10¹⁸ cm⁻³ as a peak value. The well region 39 has the p-type impurity concentration lower than the p-type impurity concentration of the contact regions 38. The p-type impurity concentration of the well region 39 may be higher than the p-type impurity concentration of the body region 20. As a matter of course, the p-type impurity concentration of the well region 39 may be lower than that of the body region 20.

The p-type impurity concentration of the well region 39 is preferably adjusted by at least one type of trivalent element. The trivalent element of the well region 39 may be the same type as the trivalent element of the impurity region 15, or may be a type different from the trivalent element of the impurity region 15. The trivalent element of the well region 39 may be at least one type among boron, aluminum, gallium, and indium.

The SiC semiconductor device 1 includes at least one field region 40 (preferably, not less than two and not more than twenty field regions 40) of the p-type formed in the surface layer portion of the outer surface 11 (the first main surface 3) in the outer peripheral region 9. The number of the plurality of field regions 40 is typically not less than four and not more than eight. The plurality of field regions 40 are formed in an electrically floating state and relax an electric field inside the chip 2 at a peripheral edge portion of the first main surface 3. The number, width, depth, p-type impurity concentration, etc., of the field regions 40 are arbitrary and can take on various values in accordance with the electric field to be relaxed.

In this embodiment, the plurality of field regions 40 are arrayed at intervals from the peripheral edges (the first to fourth connecting surfaces 12A to 12D) of the active surface 10 and the peripheral edges (the first to fourth side surfaces 5A to 5D) of the chip 2. Specifically, the plurality of field regions 40 are arrayed at intervals from the well region 39 toward the peripheral edge side of the outer surface 11.

The plurality of field regions 40 are each formed as a band extending along the active region 8 in plan view. Each of the plurality of field regions 40 has a portion extending as a band in the first direction X and a portion extending as a band in the second direction Y. In this embodiment, the plurality of field regions 40 are each formed in an annular shape (specifically, a quadrangular annular shape) surrounding the active region 8 (that is, the plurality of inversion columns 30) in plan view.

The plurality of field regions 40 are formed in the semiconductor layer 7 at intervals from the lower end of the semiconductor layer 7 toward the outer surface 11 side and respectively form pn-junction portions with the semiconductor layer 7. The plurality of field regions 40 preferably have bottom portions positioned on the outer surface 11 side with respect to the thickness range intermediate portion of the semiconductor layer 7.

In this embodiment, the plurality of field regions 40 are formed at intervals from the plurality of inversion columns 30 toward the peripheral edge side of the chip 2 and do not oppose the plurality of inversion columns 30 in the lamination direction. The plurality of field regions 40 are positioned closer to the bottom portion side of the semiconductor layer 7 (the impurity region 15) than the bottom walls of the trench structures 25.

Bottom portions of the plurality of field regions 40 may be positioned on the bottom portion side of the semiconductor layer 7 from a depth position of the upper end portions of the plurality of inversion columns 30. As a matter of course, the bottom portions of the plurality of field regions 40 may be positioned on the outer surface 11 side from the depth position of the upper end portions of the plurality of inversion columns 30.

The plurality of field regions 40 are each constituted of a random region introduced in the surface layer portion of the semiconductor layer 7 by the random implantation method with respect to the semiconductor layer 7. The plurality of field regions 40 have a thickness less than the thickness of the impurity region 15 in the direction along the second axis channel C2. Also, the thickness of the plurality of field regions 40 is less than the thickness of the inversion column 30.

Unlike the inversion column 30, etc., the plurality of field regions 40 do not have a gentle gradient portion having a thickness of not less than 0.5 μm. The plurality of field regions 40 may have a p-type impurity concentration of not less than 1×10¹⁵ cm⁻³ and not more than 1×10¹⁸ cm⁻³ as a peak value. The p-type impurity concentration of the field regions 40 may be less than the p-type impurity concentration of the contact regions 38.

The p-type impurity concentration of the field regions 40 may be substantially equal to the p-type impurity concentration of the body region 20. The p-type impurity concentration of the field regions 40 may be higher than the p-type impurity concentration of the body region 20. The p-type impurity concentration of the plurality of field regions 40 may be lower than the p-type impurity concentration of the plurality of body region 20.

The p-type impurity concentration of the plurality of field regions 40 is preferably adjusted by at least one type of trivalent element. The trivalent element of the field region 40 may be the same type as the trivalent element of the impurity region 15, or may be a type different from the trivalent element of the impurity region 15. The trivalent element of the field region 40 may be at least one type among boron, aluminum, gallium, and indium.

Each of the plurality of field regions 40 preferably has a width different from the column width WC of the inversion column 30. That is, electric field relaxation effects obtained by the plurality of field regions 40 are preferably adjusted separately from the plurality of inversion columns 30. The width of each of the plurality of field regions 40 is particularly preferably larger than the column width WC. As a matter of course, the width of each of the plurality of field regions 40 may be smaller than the column width WC. Also, a width of the plurality of field regions 40 may be substantially equal to the column width WC.

The plurality of field regions 40 are preferably formed at a pitch different from the column pitch PC of the inversion columns 30. The pitch of the plurality of field regions 40 is particularly preferably larger than the column pitch PC. The pitch of the plurality of field regions 40 may be smaller than the column pitch PC. The pitch of the plurality of field regions 40 may be substantially equal to the column pitch PC.

The SiC semiconductor device 1 includes an interlayer insulating film 41 that covers the first main surface 3. The interlayer insulating film 41 may be referred to as an “insulating film,” an “interlayer film,” an “intermediate insulating film,” etc. In this embodiment, the interlayer insulating film 41 has a laminated structure including a first insulating film 42 and a second insulating film 43. The first insulating film 42 may include at least one of a silicon oxide film, a silicon nitride film, and a silicon oxynitride film. The first insulating film 42 particularly preferably includes the silicon oxide film constituted of the oxide of the chip 2 (the semiconductor layer 7).

The first insulating film 42 selectively covers the first main surface 3 in the active region 8 and the outer peripheral region 9. Specifically, the first insulating film 42 selectively covers the active surface 10, the outer surface 11, and the first to fourth connecting surfaces 12A to 12D. The first insulating film 42 is connected to the insulating film 27 on the active surface 10 and exposes the embedded electrode 28.

On the outer surface 11, the first insulating film 42 covers the well region 39 and the plurality of field regions 40. In this embodiment, the first insulating film 42 is continuous to the first to fourth side surfaces 5A to 5D. As a matter of course, the first insulating film 42 may be formed at intervals inward from the peripheral edges of the outer surface 11 and may expose the semiconductor layer 7 from the peripheral edge portions of the outer surface 11. The first insulating film 42 covers, on the first to fourth connecting surfaces 12A to 12D, the body region 20 and the well region 39.

The second insulating film 43 is laminated on the first insulating film 42. The second insulating film 43 may include at least one of a silicon oxide film, a silicon nitride film, and a silicon oxynitride film. The interlayer insulating film 41 preferably includes the silicon oxide film. The second insulating film 43 covers the first main surface 3 across the first insulating film 42 in the active region 8 and the outer peripheral region 9. Specifically, the second insulating film 43 selectively covers the active surface 10, the outer surface 11, and the first to fourth connecting surfaces 12A to 12D across the first insulating film 42.

The second insulating film 43 covers the plurality of trench structures 25 (the embedded electrodes 28) in the active region 8. The second insulating film 43 covers, at peripheral edges of the outer peripheral region 9, the well region 39 and the plurality of field regions 40 across the first insulating film 42. In this embodiment, the second insulating film 43 is continuous to the first to fourth side surfaces 5A to 5D. As a matter of course, the second insulating film 43 may be formed at intervals inward from the peripheral edges of the outer surface 11 and may expose the peripheral edge portions of the first main surface 3 together with the first insulating film 42.

The SiC semiconductor device 1 includes a plurality of contact openings 44 formed in the interlayer insulating film 41. The plurality of contact openings 44 include a plurality of the contact openings 44 (not shown) that expose the plurality of trench structures 25 (the embedded electrodes 28) and a plurality of the contact openings 44 that expose the plurality of source regions 37. The plurality of contact openings 44 for the source regions 37 are formed in regions between the plurality of adjacent trench structures 25 and expose the plurality of source regions 37 and the plurality of contact regions 38.

The SiC semiconductor device 1 includes a side wall structure 45 which is arranged in the interlayer insulating film 41 such as to cover at least one of the first to fourth connecting surfaces 12A to 12D. The side wall structure 45 is arranged on the first insulating film 42 and is covered with the second insulating film 43. The side wall structure 45 moderates a level difference formed between the active surface 10 and the outer surface 11.

The side wall structure 45 is formed as a band extending along at least one of the first to fourth connecting surfaces 12A to 12D. In this embodiment, the side wall structure 45 is formed in a annular shape (specifically, a quadrangular annular shape) extending along the first to fourth connecting surfaces 12A to 12D such as to surround the active surface 10 in plan view.

The side wall structure 45 may have a portion extending in a film shape along the outer surface 11 and a portion extending in a film shape along the first to fourth connecting surfaces 12A to 12D. In this embodiment, the side wall structure 45 is formed at an interval from the innermost field region 40 toward the active surface 10 side and opposes the well region 39 across the first insulating film 42 in the horizontal direction and the lamination direction. The side wall structure 45 may oppose the body region 20 across the first insulating film 42.

With reference to FIG. 1, the SiC semiconductor device 1 includes a gate pad 50 which is arranged on the interlayer insulating film 41. The gate pad 50 is an electrode to which a gate potential is applied from an exterior. The gate pad 50 may be referred to as a “gate pad electrode,” a “first pad electrode,” etc. The gate pad 50 may have a laminated structure including a Ti-based metal film and an Al-based metal film laminated in that order from the interlayer insulating film 41 side.

In this embodiment, the gate pad 50 is arranged on a portion of the interlayer insulating film 41 that covers the active region 8. Specifically, the gate pad 50 is arranged on the active surface 10 at an interval from the outer surface 11 in plan view. The gate pad 50 is arranged in a region close to a central portion of one side (the second connecting surface 12B in this embodiment) of the active surface 10 in plan view.

As a matter of course, the gate pad 50 may be arranged in a region along any one of central portions of the first to fourth connecting surfaces 12A to 12D. As a matter of course, the gate pad 50 may be arranged at an arbitrary corner portion of the active surface 10 in plan view. Also, the gate pad 50 may be arranged at a central portion of the active surface 10 in plan view. In this embodiment, the gate pad 50 is formed in a quadrangular shape in plan view.

The SiC semiconductor device 1 includes at least one gate wiring 51 (in this embodiment, a plurality of gate wirings 51) which is led out on the interlayer insulating film 41 from the gate pad 50. The gate wiring 51 may be referred to as a “wiring,” a “wiring electrode,” etc. In this embodiment, the plurality of gate wirings 51 are arranged on the active surface 10 at intervals from the outer surface 11 in plan view.

The plurality of gate wirings 51 may have a laminated structure including a Ti-based metal film and an Al-based metal film laminated in that order from the interlayer insulating film 41 side. In this embodiment, each of the plurality of gate wirings 51 includes a first gate wiring 51A and a second gate wiring 51B.

The first gate wiring 51A is led out from the gate pad 50 toward the first connecting surface 12A side and extends in a line shape along the peripheral edges of the active surface 10 such as to intersect (specifically, to be orthogonal to) a part (specifically, one end portion) of each of the plurality of trench structures 25. The first gate wiring 51A penetrates the interlayer insulating film 41 through the plurality of contact openings 44 and is electrically connected to the one end portion of each of the plurality of trench structures 25.

The second gate wiring 51B is led out from the gate pad 50 toward the third connecting surface 12C side and extends in a line shape along the peripheral edges of the active surface 10 such as to intersect (specifically, to be orthogonal to) a part (specifically, the other end portion) of each of the plurality of trench structures 25. The second gate wiring 51B penetrates the interlayer insulating film 41 through the plurality of contact openings 44 and is electrically connected to the other end portion of each of the plurality of trench structures 25.

The SiC semiconductor device 1 includes a source pad 52 arranged on the interlayer insulating film 41 at intervals from the gate pad 50 and the gate wirings 51. The source pad 52 is an electrode to which a source potential is applied from the exterior. The source pad 52 may be referred to as a “source pad electrode,” a “second pad electrode,” etc. The source pad 52 may have a laminated structure including a Ti-based metal film and an Al-based metal film laminated in that order from the interlayer insulating film 41 side.

In this embodiment, the source pad 52 is arranged on the active surface 10 at an interval from the outer surface 11 in plan view. In this embodiment, the source pad 52 is formed in a polygonal shape having a recess portion that is recessed along the gate pad 50 in plan view. As a matter of course, the source pad 52 may be formed in a quadrangular shape in plan view.

The source pad 52 penetrates the interlayer insulating film 41 through the plurality of contact openings 44 and is electrically connected to the body region 20, the plurality of source regions 37, and the plurality of contact regions 38. That is, the source pad 52 is electrically connected to the plurality of non-inversion columns 35 (the impurity region 15) through the body region 20.

The SiC semiconductor device 1 includes a drain pad 53 that covers the second main surface 4. The drain pad 53 is an electrode to which a drain potential is applied from the exterior. The drain pad 53 may be referred to as a “drain pad electrode,” a “third pad electrode,” etc. The drain pad 53 forms an ohmic contact with the base layer 6 exposed from the second main surface 4.

That is, the drain pad 53 is electrically connected to the plurality of inversion columns 30 (the intermediate regions 36) through the base layer 6. The drain pad 53 may cover the entire region of the second main surface 4 such as to be continuous with the peripheral edges (the first to fourth side surfaces 5A to 5D) of the chip 2. The drain pad 53 may cover the second main surface 4 at intervals inward from the peripheral edges of the chip 2 such as to expose the peripheral edge portions of the chip 2.

A breakdown voltage that can be applied between the source pad 52 and the drain pad 53 (between the first main surface 3 and the second main surface 4) may be not less than 500 V and not more than 3000 V. The breakdown voltage may have a value falling within any one of ranges of not less than 500 V and not more than 1000 V, not less than 1000 V and not more than 1500 V, not less than 1500 V and not more than 2000 V, not less than 2000 V and not more than 2500 V, and not less than 2500 V and not more than 3000 V.

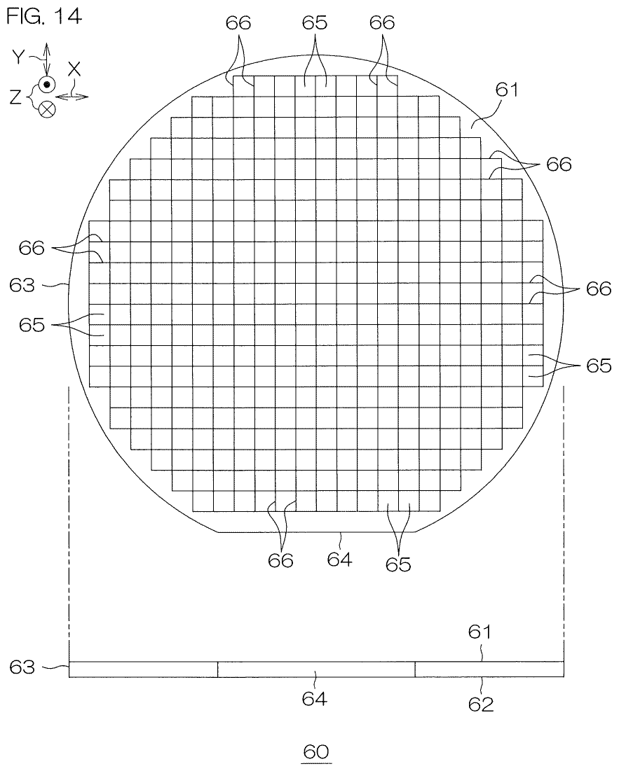

FIG. 14 is a schematic view showing a wafer 60 used in manufacturing the SiC semiconductor device 1. The wafer 60 is a base material of the base layer 6 and includes the SiC monocrystal. The wafer 60 is formed in a flat disk shape. As a matter of course, the wafer 60 may be formed in a flat rectangular parallelepiped shape. The wafer 60 has a first wafer main surface 61 on one side, a second wafer main surface 62 on the other side, and a wafer side surface 63 connecting the first wafer main surface 61 and the second wafer main surface 62.

The first wafer main surface 61 corresponds to the upper end of the base layer 6, and the second wafer main surface 62 corresponds to a lower end of the base layer 6. The first wafer main surface 61 and the second wafer main surface 62 are formed of c-planes of the SiC monocrystal. The first wafer main surface 61 is formed of a silicon plane of the SiC monocrystal, and the second wafer main surface 62 is formed of a carbon plane of the SiC monocrystal. The wafer 60 (the first wafer main surface 61 and the second wafer main surface 62) has the off direction Do and the off angle θo described above.

The wafer 60 has a mark 64 that indicates a crystal orientation of the SiC monocrystal at the wafer side surface 63. The mark 64 may include one or both of an orientation flat and an orientation notch. The orientation flat is constituted of a notched portion linearly cut in plan view. The orientation notch is constituted of a notched portion cut in a concave shape (for example, a tapered shape) toward a central portion of the first wafer main surface 61 in plan view.

The mark 64 may include one or both of a first orientation flat extending in the m-axis direction and a second orientation flat extending in the a-axis direction. The mark 64 may include one or both of an orientation notch recessed in the m-axis direction and an orientation notch recessed in the a-axis direction. FIG. 14 shows an orientation flat extending in the m-axis direction (the first direction X) in plan view.

For example, a plurality of device regions 65 and a plurality of intended cutting lines 66 are set in the wafer 60 by an alignment mark, etc. The device regions 65 are each a region corresponding to the SiC semiconductor device 1. The plurality of device regions 65 are each set in a quadrangular shape in plan view.

In this embodiment, the plurality of device regions 65 are set in a matrix along the first direction X and the second direction Y in plan view. The plurality of device regions 65 are each set at an interval inward from a peripheral edge of the first wafer main surface 61 in plan view. The plurality of intended cutting lines 66 are set in a lattice that extends along the first direction X and the second direction Y such as to define the plurality of device regions 65.

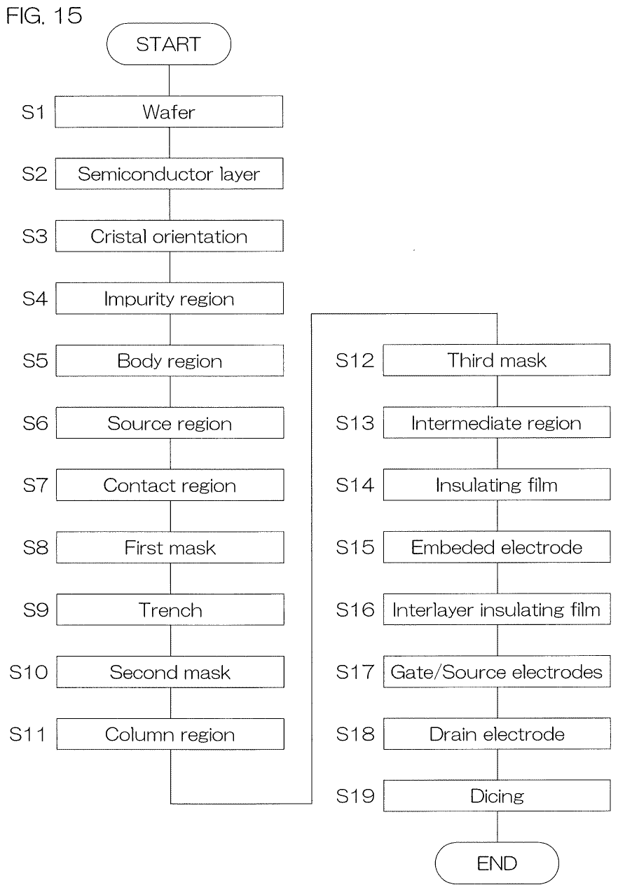

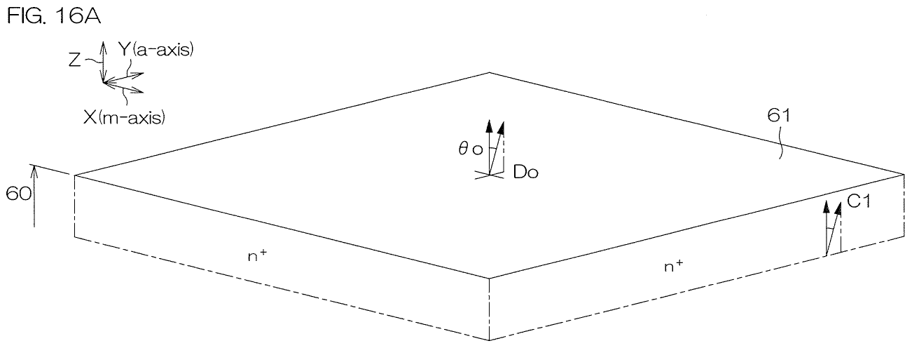

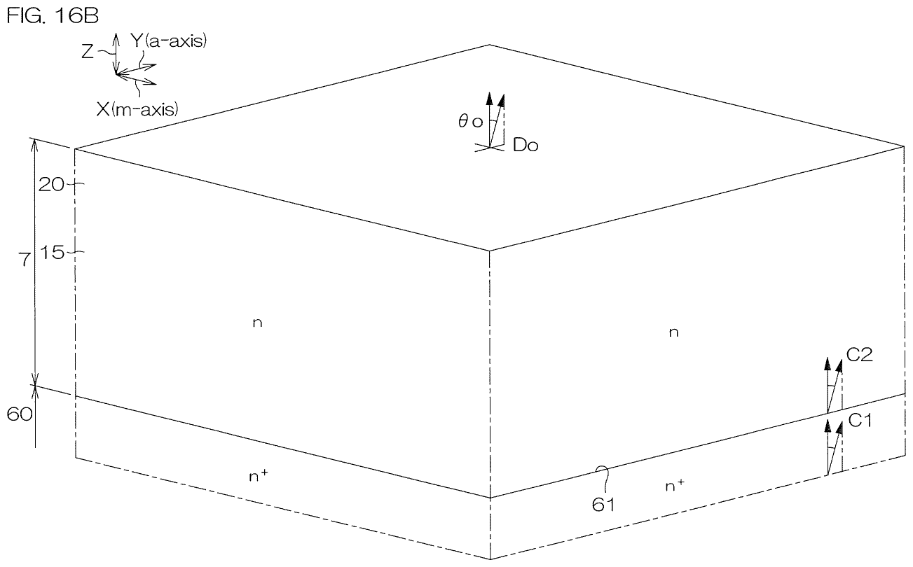

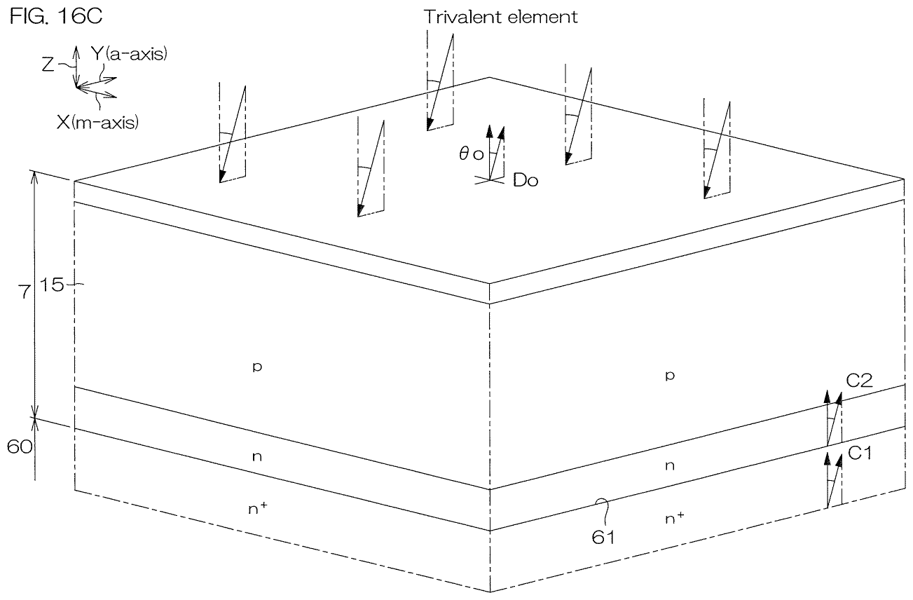

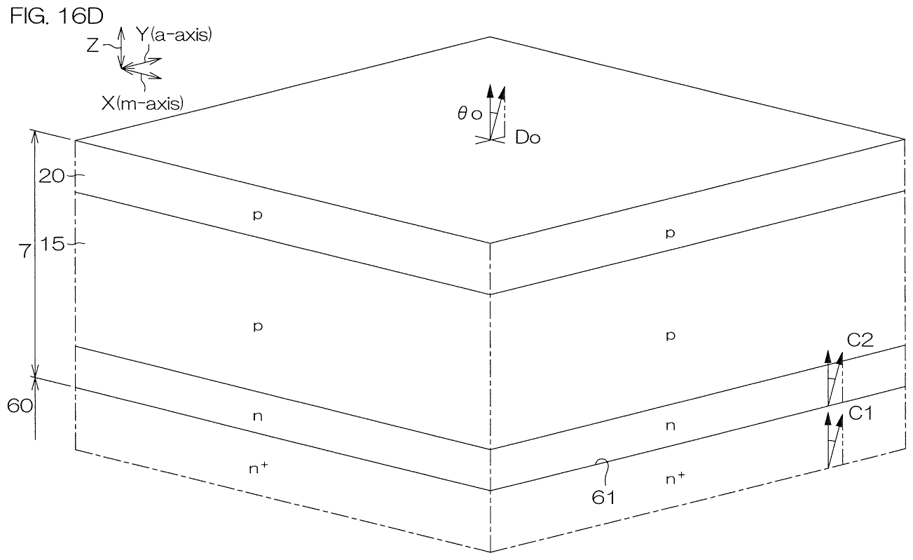

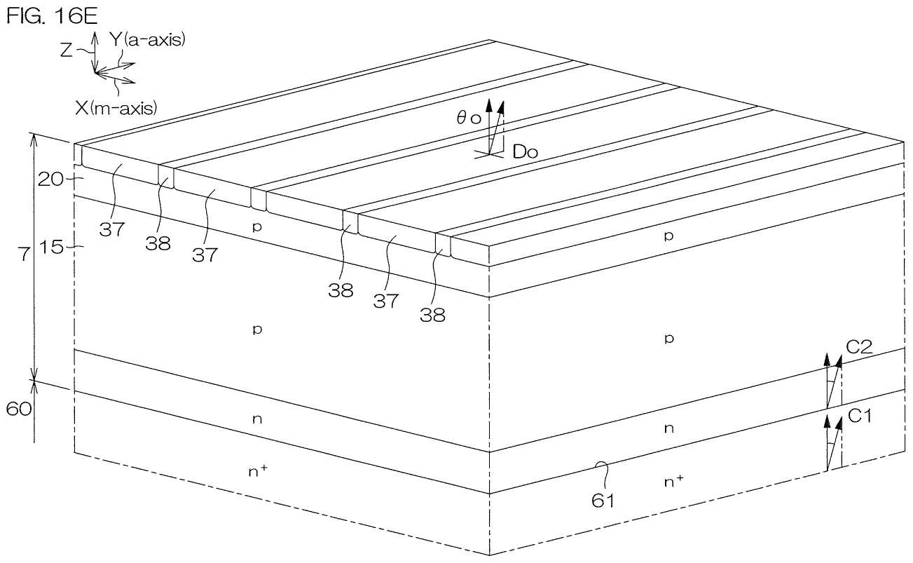

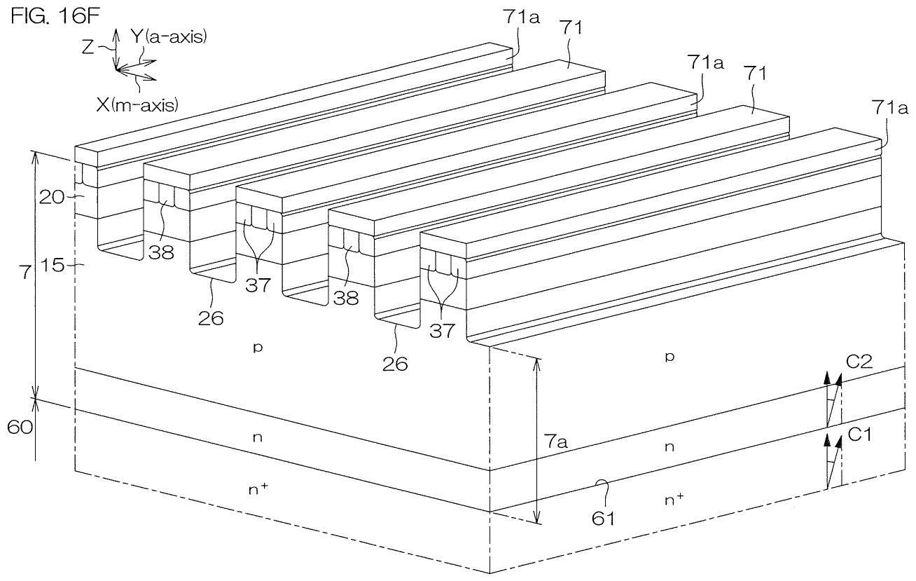

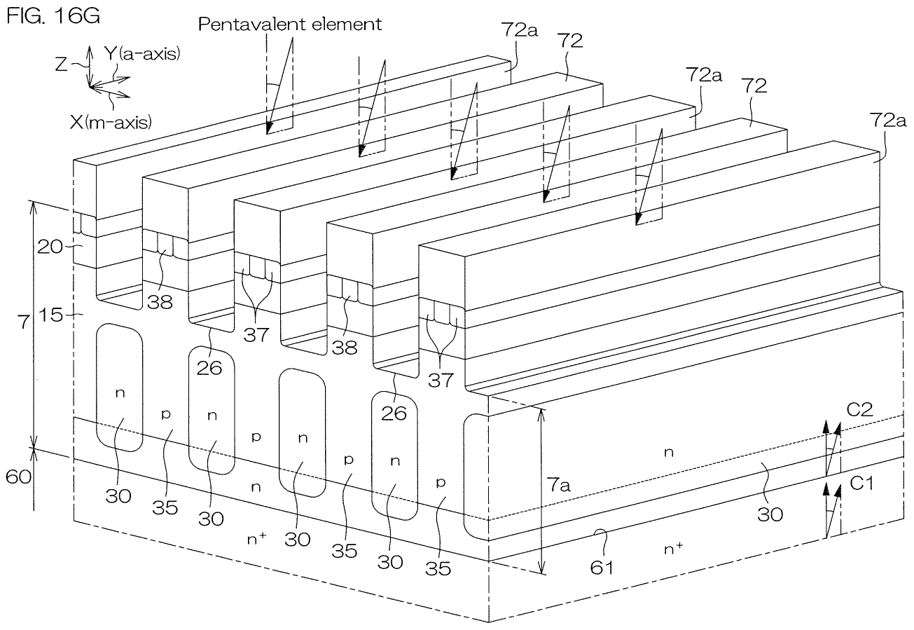

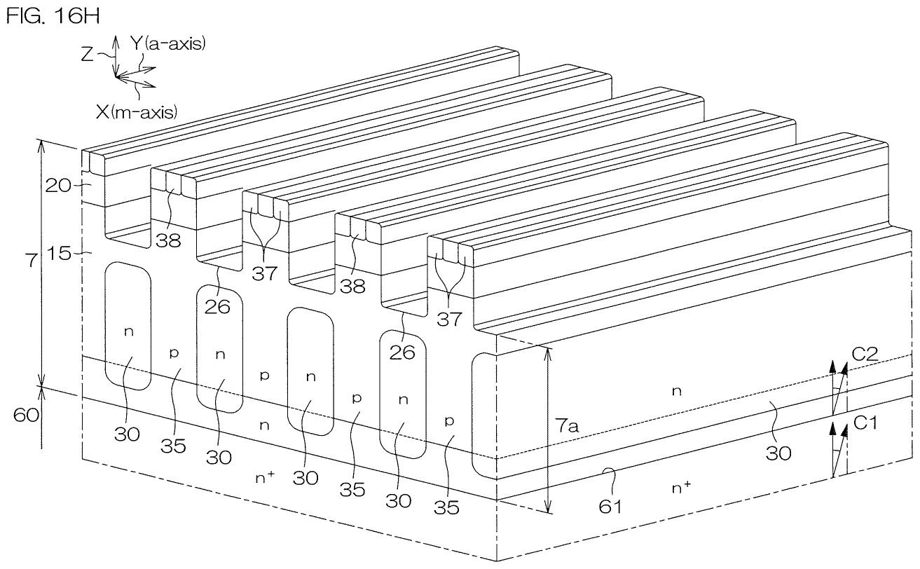

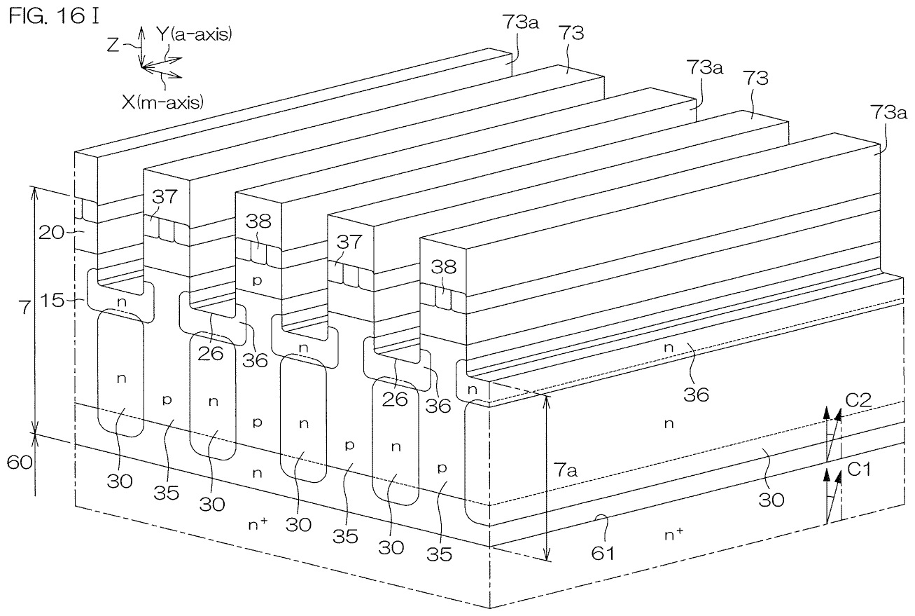

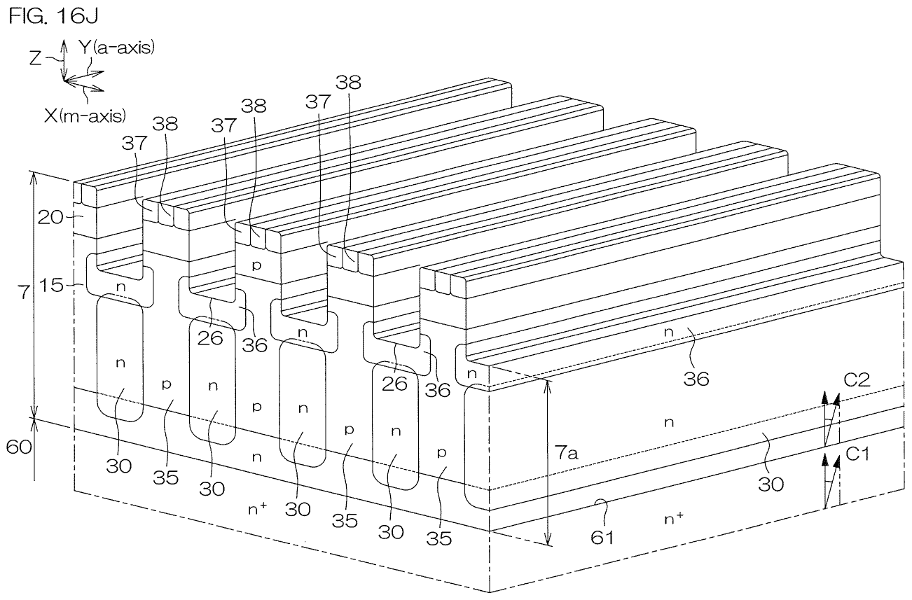

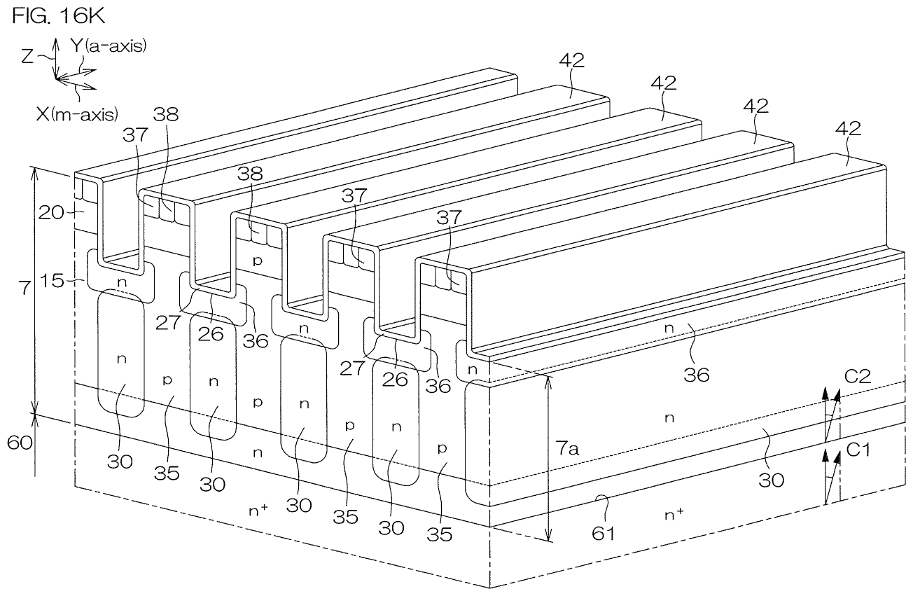

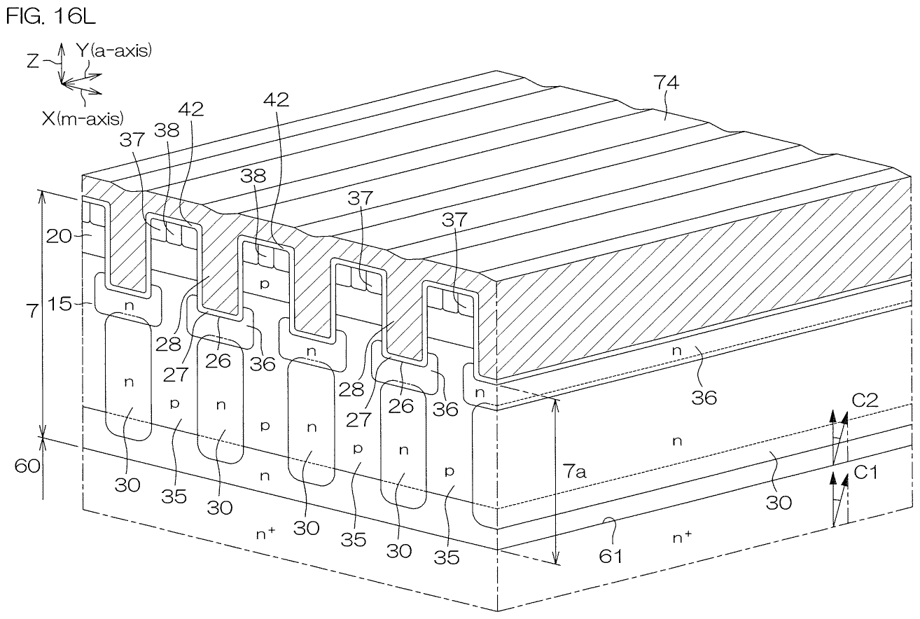

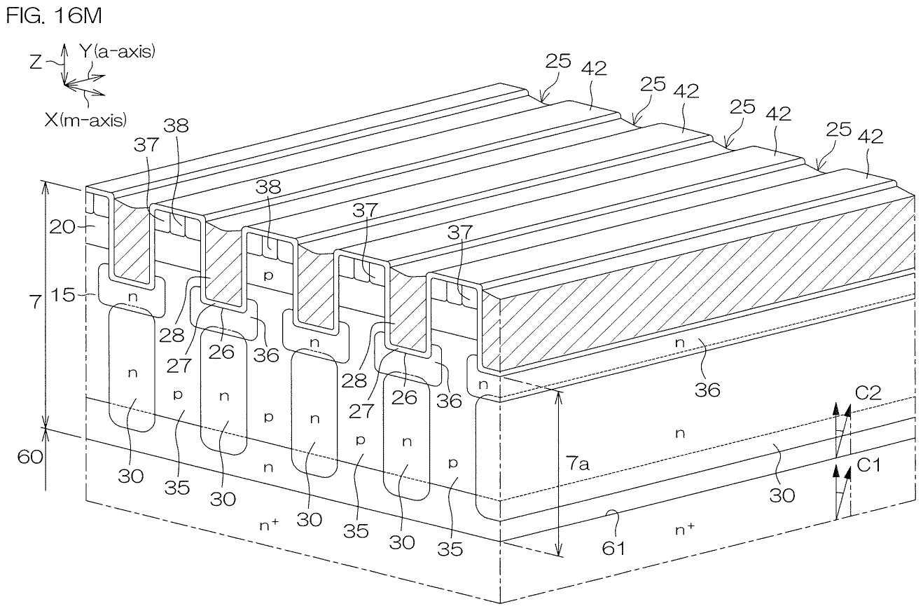

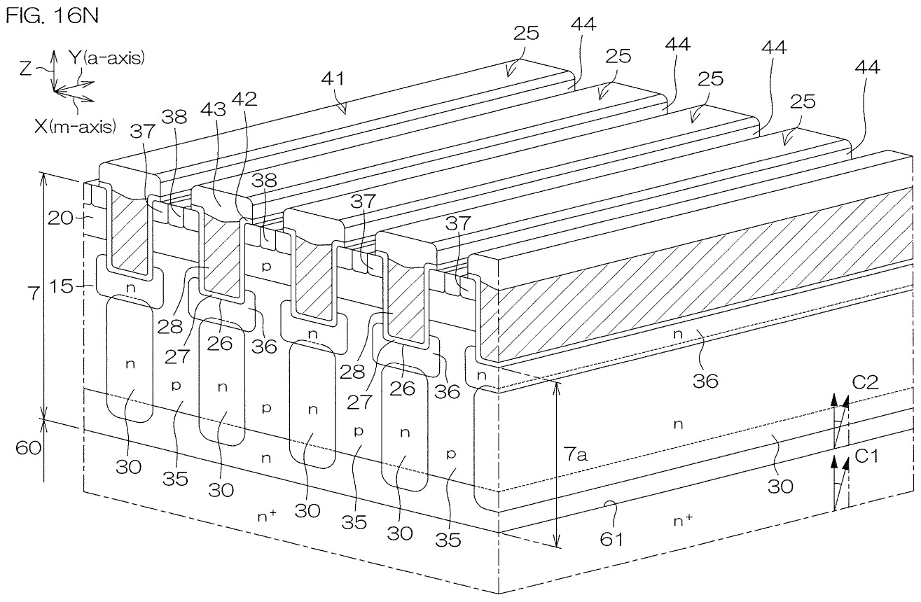

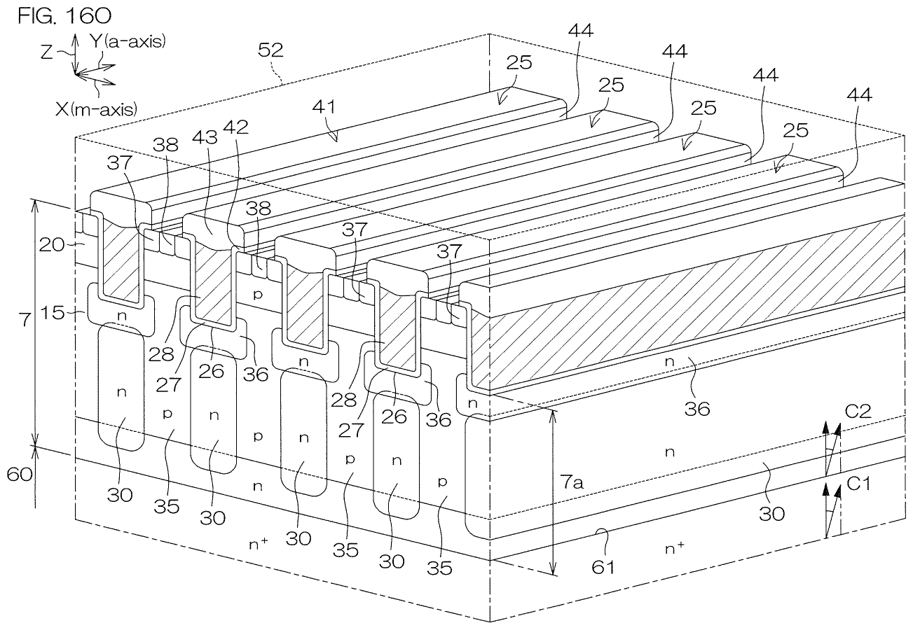

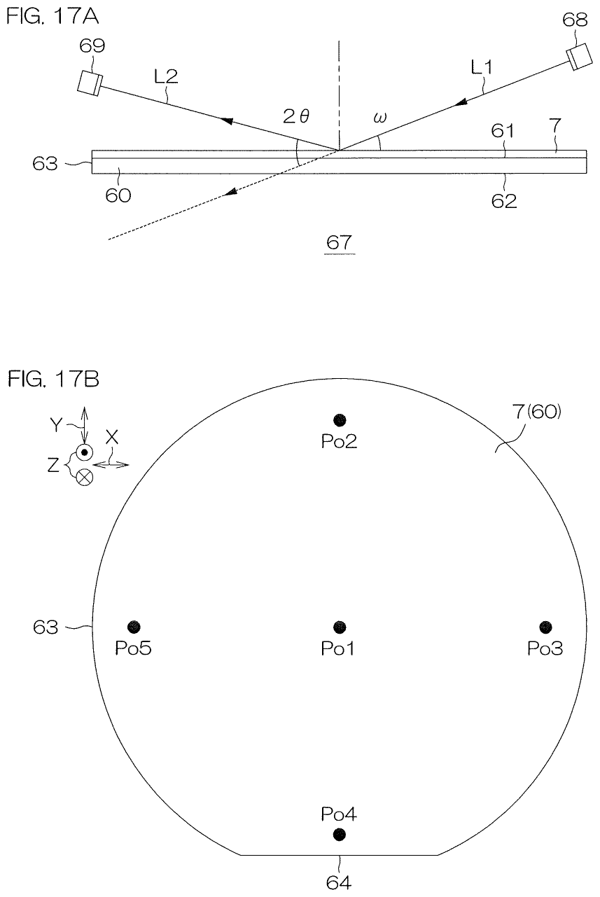

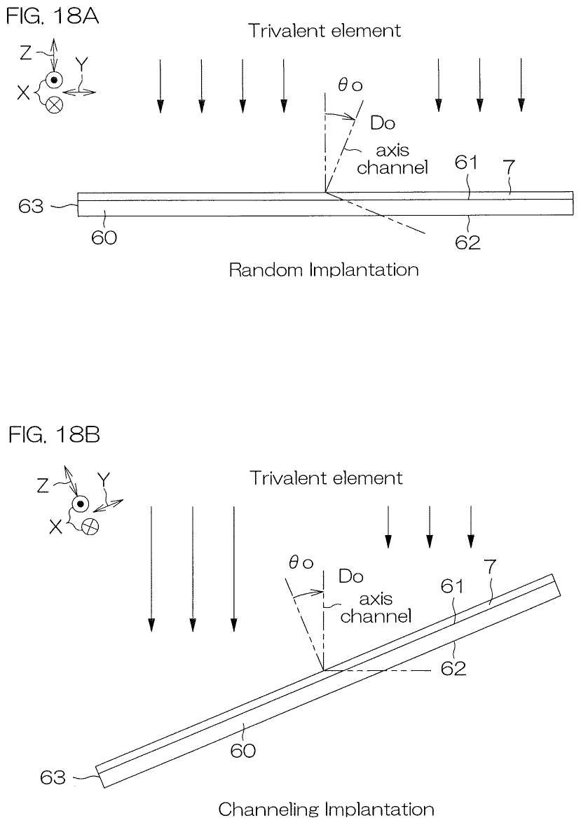

FIG. 15 is a flowchart showing a manufacturing method example of the SiC semiconductor device 1. FIGS. 16A to 16O are cross-sectional perspective views showing the manufacturing method example of the SiC semiconductor device 1. FIGS. 17A and 17B are schematic views for illustrating a measurement step of a crystal orientation. FIGS. 18A and 18B are schematic views for illustrating an ion implantation step. FIGS. 16A to 16O show cross-sectional perspective views of a portion of the active region 8 of the single device region 65.

First, with reference to FIG. 16A, a preparation step of the wafer 60 described above is performed (step S1 in FIG. 15). Next, with reference to FIG. 16B, a forming step of the semiconductor layer 7 is performed (step S2 in FIG. 15). The semiconductor layer 7 is formed with the first wafer main surface 61 (the wafer 60) as a starting point by the epitaxial growth method.

Next, a measurement step of a crystal orientation of the semiconductor layer 7 is performed (step S3 in FIG. 15). The crystal orientation of the semiconductor layer 7 is obtained by including a step of measuring the off angle θo of the semiconductor layer 7. That is, this step includes a step of measuring a crystal orientation of the second axis channel C2 of the semiconductor layer 7.

The wafer 60 is cut out from an ingot (an SiC ingot) which is a crystalline lump, but there is a risk that an error occurs in the off angle θo due to a process error. In a case where an error occurs in the off angle θo of the wafer 60, a process error also occurs in the off angle θo of the semiconductor layer 7, and this becomes an obstacle at the time of a channeling implantation step. Therefore, it is preferable that data (information) of the off angle θo is acquired before the channeling implantation step, and the channeling implantation step is performed based on the data (information) of this off angle θo.

With reference to FIG. 17A, in this step, the crystal orientation of the semiconductor layer 7 is measured by an X-ray diffraction method (a so-called ω-2θ measurement method) using an X-ray diffractometer 67. The X-ray diffractometer 67 may be referred to as an “XRD (X-ray diffraction) device.”

The X-ray diffractometer 67 includes an irradiation portion 68 and a detection portion 69 and performs a rocking curve measurement method. The irradiation portion 68 irradiates the upper end of the semiconductor layer 7 (the first wafer main surface 61 of the wafer 60) with an incident X-ray L1 having a predetermined incident angle ω. The incident angle ω is defined by an angle between the incident X-ray L1 and the upper end of the semiconductor layer 7 (the first wafer main surface 61 of the wafer 60).

The detection portion 69 is arranged at an angular position of a diffraction angle 2θ (θ is a Bragg angle) with respect to an irradiation position on the wafer 60 with the incident X-ray L1 and detects a diffracted X-ray L2. The diffraction angle 2θ is an angle between an incident direction of the incident X-ray L1 and a diffraction direction of the diffracted X-ray L2.

In the rocking curve measurement method, the incident angle ω is shifted in a minute angle range in a state in which the diffraction angle 2θ is fixed, and a rocking curve representing the intensity of the diffracted X-ray L2 (an intensity profile of the diffracted X-ray L2) is measured. The rocking curve has the intensity of the diffracted X-ray L2 on the ordinate and the incident angle ω on the abscissa. The incident angle ω is obtained at an angular position at which the intensity of the diffracted X-ray L2 takes on a peak value.

In this step, the rocking curve measurement method is performed only for one location (for example, the central portion) of the upper end of the semiconductor layer 7 (the first wafer main surface 61 of the wafer 60). In the case where an in-plane variation in the off angle θo is assumed, the rocking curve measurement method may be performed at a plurality of locations (for example, the central portion and a peripheral edge portion) of the upper end of the semiconductor layer 7 (the first wafer main surface 61 of the wafer 60).

FIG. 17B shows measuring locations in a case where the rocking curve measurement method is performed at a plurality of (here, five) locations of the upper end of the semiconductor layer 7. Here, the off angle θo of the semiconductor layer 7 is set to approximately 4°. In FIG. 17B, first to fifth measuring points Po1 to Po5 are shown.

The first measuring point Po1 is set at the central portion of the semiconductor layer 7. The second measuring point Po2 is set on the peripheral edge portion of the semiconductor layer 7 on one side (a side opposite to the mark 64) in the second direction Y at an interval from the first measuring point Po1. The third measuring point Po3 is set on the peripheral edge portion of the semiconductor layer 7 on one side (the right side with respect to the mark 64) in the first direction X at an interval from the first measuring point Po1.

The fourth measuring point Po4 is set on the peripheral edge portion of the semiconductor layer 7 on the other side (the mark 64 side) in the second direction Y at an interval from the first measuring point Po1. The fifth measuring point Po5 is set on the peripheral edge portion of the semiconductor layer 7 on the other side (the left side with respect to the mark 64) in the first direction X at an interval from the first measuring point Po1.

Measurement results of the incident angles ω, the diffraction angles 2θ, and the off angles θo at the first to fifth measuring points Po1 to Po5 are as shown in Table 1 below. The off angle θo is obtained by a calculation formula of “ω−(2θ×½)” using the incident angle ω and the diffraction angle 2θ.

TABLE 1

| Measuring point | ω (°) | 2θ (°) | θoff (°) |
|---|---|---|---|
| Po1 | 21.836 | 35.606 | 4.033 |
| Po2 | 21.830 | 35.609 | 4.025 |
| Po3 | 21.841 | 35.611 | 4.035 |
| Po4 | 21.837 | 35.609 | 4.033 |
| Po5 | 21.856 | 35.606 | 4.053 |
| Average | | | 4.036 |
| Standard deviation | | | 0.009 |

As shown in Table 1, an average value of the off angles θo of the first to fifth measuring points Po1 to Po5 was 4.036°, and the standard deviation of these off angles θo was 0.009° (±0.01°). This leads to an understanding that the in-plane variation in the off angle θo occurring at the upper end of the semiconductor layer 7 (the first wafer main surface 61 of the wafer 60) is very small and has a magnitude that does not interfere with the channeling implantation step.

Therefore, it is understood that there is no problem to set at least one location as a measuring location with respect to the upper end of the semiconductor layer 7 (the first wafer main surface 61). For example, the measuring location may be any one or the plurality of (all of) first to fifth measuring points Po1 to Po5. For example, the measuring location may be only the first measuring point Po1. By reducing measuring locations (the number of measurements), the number of manufacturing processes (manufacturing costs) is reduced.

As a matter of course, the off angle θo may be measured at a plurality of locations of the upper end of the semiconductor layer 7 (the first wafer main surface 61), and an implantation angle according to the in-plane variation in the off angle θo may be set in the channeling implantation step. In this case, although the number of manufacturing processes (manufacturing costs) increases, an in-plane error of the impurity region 15 and the plurality of inversion columns 30 formed in the semiconductor layer 7 is appropriately prevented.

The off angle θo of the semiconductor layer 7 is substantially matched with the off angle θo of the wafer 60. Therefore, the measurement step of the crystal orientation may be performed on the wafer 60 before the forming step of the semiconductor layer 7. However, from the viewpoint of ensuring accuracy, the measurement step of the crystal orientation is preferably performed on the semiconductor layer 7.

Next, with reference to FIG. 16C, a forming step of the impurity region 15 is performed (step S4 in FIG. 15). The forming step of the impurity region 15 includes a channeling implantation step of a trivalent element (p-type impurity) into the semiconductor layer 7. In this step, the trivalent element is introduced into the entire region of the semiconductor layer 7 through a mask (not illustrated) having a predetermined layout.

The mask (not illustrated) is arranged on the upper end of the semiconductor layer 7, exposes a region in which the impurity region 15 is to be formed in the active region, and covers regions other than this. As a matter of course, in a case where the trivalent element is introduced into the entire region of the semiconductor layer 7, the mask (not illustrated) may be omitted. The semiconductor layer 7 (the wafer 60) has the off angle θo inclined at a predetermined angle in the predetermined off direction Do with respect to the first wafer main surface 61. The channeling implantation step is performed based on the data (information) of the off angle θo.

With reference to FIG. 18A, in the random implantation method, a trivalent element is introduced into the semiconductor layer 7 with a predetermined implantation energy in the direction intersecting the second axis channel C2 (the off angle θo) (see also FIG. 9). For example, in the random implantation method, the trivalent element is implanted in the vertical direction Z perpendicular to the upper end of the semiconductor layer 7 (the first wafer main surface 61).

In the case of the random implantation method, since the trivalent element is introduced in a direction in which relatively dense atomic rows are present in plan view, the trivalent element collides with the atomic rows at a relatively shallow depth position. Hence, the atomic rows inhibit the trivalent element from being introduced into a relatively deep depth position of the semiconductor layer 7. As a result, the impurity region 15 not having first gentle gradient portion 18 is formed.

Meanwhile, with reference to FIG. 18B, in the channeling implantation method, an implantation angle of the trivalent element with respect to the semiconductor layer 7 is controlled, and the trivalent element is introduced into the semiconductor layer 7 with the predetermined implantation energy along the second axis channel C2 (the c-axis of the SiC monocrystal in this embodiment) (see also FIG. 8). In this case, one or both of the implantation angle of the trivalent element with respect to the semiconductor layer 7 and an inclination angle of the semiconductor layer 7 with respect to the implantation angle of the trivalent element are adjusted.

For example, the wafer 60 may be horizontally supported, and the trivalent element may be introduced into the semiconductor layer 7 along the second axis channel C2. As a matter of course, the wafer 60 may be supported in a state of being inclined by the off angle θo with respect to the horizontal, and the trivalent element may be introduced into the semiconductor layer 7 along the second axis channel C2. The impurity region 15 having a predetermined thickness is formed at a predetermined depth position by an arbitrary combination of implantation energies of the trivalent element and implantation temperatures of the trivalent element (temperatures of the wafer 60).

The implantation energy of the trivalent element may be not less than 100 KeV and not more than 2000 KeV. The implantation energy may have a value falling within any one of ranges of not less than 100 KeV and not more than 250 KeV, not less than 250 KeV and not more than 500 KeV, not less than 500 KeV and not more than 750 KeV, not less than 750 KeV and not more than 1000 KeV, not less than 1000 KeV and not more than 1250 KeV, not less than 1250 KeV and not more than 1500 KeV, not less than 1500 KeV and not more than 1750 KeV, and not less than 1750 KeV and not more than 2000 KeV.

The implantation temperature of the trivalent element may be adjusted in a range of 0° C. or higher and 1500° C. or lower. The implantation temperature may have a value falling within any one of ranges of 0° C. or higher and 25° C. or lower, 25° C. or higher and 50° C. or lower, 50° C. or higher and 100° C. or lower, 100° C. or higher and 250° C. or lower, 250° C. or higher and 500° C. or lower, 500° C. or higher and 750° C. or lower, 750° C. or higher and 1000° C. or lower, 1000° C. or higher and 1250° C. or lower, and 1250° C. or higher and 1500° C. or lower.

The implantation angle of the trivalent element is preferably set within a range of ±2° on the basis of an axis along the second axis channel C2 (the c-axis of the SiC monocrystal in this embodiment) (0°). The implantation angle of the trivalent element is particularly preferably set within a range of ±1° on the basis of the axis along the second axis channel C2 (the c-axis of the SiC monocrystal in this embodiment) (0°).

In the case of the channeling implantation method, the trivalent element is introduced along the second axis channel C2 in which atomic rows are relatively sparse in plan view. The trivalent element travels in the second axis channel C2 while repeating small-angle scattering due to a channeling effect and reaches a relatively deep depth position of the semiconductor layer 7. That is, in the case of the channeling implantation method, a collision probability of the trivalent element with respect to the atomic rows of the SiC monocrystal is reduced.

In this case, a trivalent element belonging to heavy elements heavier than carbon is preferably introduced into the semiconductor layer 7. That is, the trivalent element is preferably a trivalent element (at least one type among aluminum, gallium, and indium) other than boron. In this embodiment, the trivalent element is aluminum.

After the implantation step of the trivalent element, by an annealing method, lattice defects, etc., that formed in the semiconductor layer 7 may be repaired at the same time as the trivalent element is electrically activated. An annealing temperature for the semiconductor layer 7 may be not less than 500° C. and not more than 2000° C.

Next, with reference to FIG. 16D, a forming step of the body region 20 is performed (step S5 in FIG. 15). The forming step of the body region 20 includes a random implantation step of a trivalent element (p-type impurity) into the surface layer portion of the semiconductor layer 7. In this step, the trivalent element is introduced into the entire region of the semiconductor layer 7. For example, in the random implantation method, the trivalent element is implanted in the vertical direction Z perpendicular to the upper end of the semiconductor layer 7 (the first wafer main surface 61). Consequently, the body region 20 is formed over the entire region of the surface layer portion of the semiconductor layer 7.

Next, with reference to FIG. 16E, a forming step of the plurality of source regions 37 is performed (step S6 in FIG. 15). The plurality of source regions 37 are formed by introducing a pentavalent element into the surface layer portion of the semiconductor layer 7 by the random implantation method through the mask (not illustrated) having the predetermined layout.

Also, a forming step of the plurality of contact regions 38 is performed (step S7 in FIG. 15). The plurality of contact regions 38 are formed by introducing a trivalent element into the surface layer portion of the semiconductor layer 7 by the random implantation method through the mask (not illustrated) having the predetermined layout. The forming step of the contact region 38 may be performed before the forming step of the source region 37.

Next, with reference to FIG. 16F, a forming step of a first mask 71 having a predetermined pattern is performed (step S8 in FIG. 15). The first mask 71 is preferably an organic mask (a hard mask). The first mask 71 is arranged on the upper end of the semiconductor layer 7 and has a plurality of first openings 71a that expose regions in which the plurality of trenches 26 are to be formed.

The plurality of first openings 71a are formed at intervals in the first direction X and are each defined as a band extending in the second direction Y. That is, the plurality of first openings 71a have an extension direction extending along the off direction Do in plan view. Also, the first mask 71 has first openings 71a (not illustrated) that exposes regions in which the outer surface 11 is to be formed. The first openings 71a for the outer surface 11 are formed in a lattice along the plurality of intended cutting lines 66.

Next, a forming step of the plurality of trenches 26 is performed (step S9 in FIG. 15). In the forming step of the trenches 26, unnecessary portions of the semiconductor layer 7 are removed by an etching method through the first mask 71. The etching method may be one or both of a wet etching method and a dry etching method.

The etching method is preferably an RIE (reactive ion etching method. Consequently, the plurality of trenches 26 are formed at the upper end of the semiconductor layer 7. Also, the active surface 10, the outer surface 11, and the first to fourth connecting surfaces 12A to 12D are formed at the upper end of the semiconductor layer 7. After the forming step of the plurality of trenches 26, the first mask 71 is removed.

Next, with reference to FIG. 16G, a forming step of a second mask 72 having a predetermined pattern is performed (step S10 in FIG. 15). The second mask 72 is preferably an organic mask (a resist mask). The second mask 72 is arranged on the upper end of the semiconductor layer 7 and has a plurality of second openings 72a that expose the plurality of trenches 26 in a one-to-one correspondence relationship. The plurality of second openings 72a are formed at intervals in the first direction X and are each defined as a band extending in the second direction Y. That is, the plurality of second openings 72a have an extension direction extending along the off direction Do in plan view.

Next, a forming step of the plurality of inversion columns 30 is performed (step S11 in FIG. 15). The forming step of the plurality of inversion columns 30 includes a channeling implantation step of a pentavalent element (n-type impurity) into the semiconductor layer 7. The pentavalent element is introduced into the lower region 7a of the semiconductor layer 7 from the plurality of second openings 72a of the second mask 72 through the bottom walls of the plurality of trenches 26. The channeling implantation step is performed based on the data (information) of the off angle θo described above.

In the channeling implantation method, an implantation angle of the pentavalent element with respect to the semiconductor layer 7 is controlled, and the pentavalent element is introduced into the semiconductor layer 7 with a predetermined implantation energy along the second axis channel C2 (the c-axis of the SiC monocrystal in this embodiment). In this case, one or both of an implantation angle of the pentavalent element with respect to the semiconductor layer 7 and an inclination angle of the semiconductor layer 7 with respect to the implantation angle of the pentavalent element are adjusted.

For example, the wafer 60 may be horizontally supported, and the pentavalent element may be introduced into the semiconductor layer 7 along the second axis channel C2. As a matter of course, the wafer 60 may be supported in a state of being inclined by the off angle θo with respect to the horizontal, and the pentavalent element may be introduced into the semiconductor layer 7 along the second axis channel C2. The plurality of inversion columns 30 having a predetermined thickness are formed at a predetermined depth position by an arbitrary combination of implantation energies of the pentavalent element and implantation temperatures of the pentavalent element.

The implantation energy of the pentavalent element may be not less than 100 KeV and not more than 2000 KeV. The implantation energy may have a value falling within any one of ranges of not less than 100 KeV and not more than 250 KeV, not less than 250 KeV and not more than 500 KeV, not less than 500 KeV and not more than 750 KeV, not less than 750 KeV and not more than 1000 KeV, not less than 1000 KeV and not more than 1250 KeV, not less than 1250 KeV and not more than 1500 KeV, not less than 1500 KeV and not more than 1750 KeV, and not less than 1750 KeV and not more than 2000 KeV.

The implantation energy related to the inversion columns 30 may be substantially equal to the implantation energy related to the impurity region 15 or may be different from the implantation energy related to the impurity region 15. The implantation energy related to the inversion columns 30 may be not less than the implantation energy related to the impurity region 15. The implantation energy related to the inversion columns 30 may be less than the implantation energy related to the impurity region 15.

The implantation temperature of the pentavalent element may be adjusted in a range of 0° C. or higher and 1500° C. or lower. The implantation temperature may have a value falling within any one of ranges of 0° C. or higher and 25° C. or lower, 25° C. or higher and 50° C. or lower, 50° C. or higher and 100° C. or lower, 100° C. or higher and 250° C. or lower, 250° C. or higher and 500° C. or lower, 500° C. or higher and 750° C. or lower, 750° C. or higher and 1000° C. or lower, 1000° C. or higher and 1250° C. or lower, and 1250° C. or higher and 1500° C. or lower.

An implantation temperature related to the inversion columns 30 may be substantially equal to an implantation temperature related to the impurity region 15 or may be different from the implantation temperature related to the impurity region 15. The implantation temperature related to the inversion columns 30 may be not less than the implantation temperature related to the impurity region 15. The implantation temperature related to the inversion columns 30 may be less than the implantation temperature related to the impurity region 15.

The implantation angle of the pentavalent element is preferably set within a range of ±2° on the basis of the axis along the second axis channel C2 (the c-axis of the SiC monocrystal in this embodiment) (0°). The implantation angle of the pentavalent element is particularly preferably set within a range of ±1° on the basis of the axis along the second axis channel C2 (the c-axis of the SiC monocrystal in this embodiment) (0°).

In the case of the channeling implantation method, the pentavalent element is introduced along the second axis channel C2 in which atomic rows are relatively sparse in plan view. The pentavalent element travels in the second axis channel C2 while repeating small-angle scattering due to a channeling effect and reaches a relatively deep depth position of the semiconductor layer 7. That is, in the case of the channeling implantation method, a collision probability of the pentavalent element with respect to the atomic rows of the SiC monocrystal is reduced. The pentavalent element is preferably arsenic or antimony.

The plurality of second openings 72a have the extension direction extending along the off direction Do, and the implantation angle of the pentavalent element is inclined in the off direction Do. Therefore, the pentavalent element is introduced into the semiconductor layer 7 substantially perpendicularly to the bottom walls of the trenches 26 through the plurality of second openings 72a in cross-sectional view orthogonal to the extension direction.

Consequently, the plurality of inversion columns 30 are prevented from being formed in an inclined posture in the semiconductor layer 7. Also, wall surfaces of the plurality of second openings 72a are prevented from becoming blocking objects with respect to an incident path of the pentavalent element. Consequently, a process error of the plurality of inversion columns 30 due to shadowing of the wall surfaces of the plurality of second openings 72a is prevented. Therefore, the accuracy of the charge balance is improved.

After the implantation step of the pentavalent element, by the annealing method, lattice defects, etc., that formed in the semiconductor layer 7 may be repaired at the same time as the pentavalent element is electrically activated. An annealing temperature for the semiconductor layer 7 may be not less than 500° C. and not more than 2000° C. Consequently, the plurality of inversion columns 30 and the plurality of non-inversion columns 35 are formed, and at the same time, the super junction structure is formed.

An annealing method related to the inversion columns 30 may also serve as an annealing method related to the impurity region 15. In this case, the annealing method related to the impurity region 15 before the forming step of the inversion columns 30 may be omitted. With reference to FIG. 16H, after the forming step of the plurality of inversion columns 30, the second mask 72 is removed.

Next, with reference to FIG. 16I, a forming step of a third mask 73 having a predetermined pattern is performed (step S12 in FIG. 15). The third mask 73 is preferably an organic mask (a resist mask). The third mask 73 is arranged on the upper end of the semiconductor layer 7 and has a plurality of third openings 73a that selectively expose the plurality of trenches 26. The plurality of third openings 73a respectively expose some of the plurality of trenches 26 at intervals in the first direction X and the second direction Y.

Next, a forming step of the plurality of intermediate regions 36 is performed (step S13 in FIG. 15). The forming step of the plurality of intermediate regions 36 includes a step of introducing the pentavalent element into the semiconductor layer 7 with a predetermined implantation energy in a direction intersecting the second axis channel C2 (the off angle θo) by the random implantation method through the third mask 73. The pentavalent element is introduced from the plurality of third openings 73a through the wall surfaces (the side walls and the bottom wall) of the plurality of trenches 26 into the semiconductor layer 7 (the impurity region 15). The pentavalent element may be introduced into the semiconductor layer 7 once or a plurality of times.

In the case where the pentavalent element is introduced a plurality of times, the pentavalent element may be introduced to different depth positions of the semiconductor layer 7 in multiple stages with a plurality of implantation energies. The pentavalent element may be introduced into the semiconductor layer 7 (the impurity region 15) through the wall surfaces (the side walls and the bottom wall) of the plurality of trenches 26 by an oblique ion implantation method. With reference to FIG. 16J, after the forming step of the plurality of intermediate regions 36, the third mask 73 is removed.

Although not specifically shown, a forming step of the well region 39 is performed before the forming step of the intermediate region 36 or after the forming step of the intermediate region 36. The well region 39 is formed by introducing a trivalent element into the semiconductor layer 7 by the random implantation method through the mask (not illustrated) that selectively exposes the outer surface 11 and the first to fourth connecting surfaces 12A to 12D.

Although not specifically shown, a forming step of the plurality of field regions 40 is performed before the forming step of the intermediate region 36 or after the forming step of the intermediate region 36. The plurality of field regions 40 are formed by introducing a trivalent element into the surface layer portion of the semiconductor layer 7 by the random implantation method through the mask (not illustrated) that selectively exposes the outer surface 11.

Next, with reference to FIG. 16K, a forming step of the insulating film 27 is performed (step S14 in FIG. 15). The forming step of the insulating film 27 also serves as a forming step of the first insulating film 42. The insulating film 27 may be formed by one or both of a CVD (chemical vapor deposition) method and an oxidation treatment method. The insulating film 27 and the first insulating film 42 are typically formed by a thermal oxidation treatment method. The insulating film 27 is formed in a film shape on the wall surfaces of the plurality of trenches 26, and the first insulating film 42 is formed in a film shape in a region of the upper end of the semiconductor layer 7 other than the plurality of trenches 26.

Next, with reference to FIG. 16L, a forming step of the embedded electrodes 28 is performed (step S15 in FIG. 15). This step includes a step of forming a base electrode film 74 on the insulating film 27. In this embodiment, the base electrode film 74 includes a conductive polysilicon. The base electrode film 74 backfills the plurality of trenches 26 and covers the upper end of the semiconductor layer 7. The base electrode film 74 may be formed by the CVD method.

Next, with reference to FIG. 16M, unnecessary portions of the embedded electrodes 28 are removed by the etching method. The unnecessary portions of the embedded electrodes 28 are removed until the insulating film 27 is exposed. The etching method may be one or both of a wet etching method and a dry etching method. Consequently, the plurality of embedded electrodes 28 are embedded in the plurality of trenches 26, and the plurality of trench structures 25 are formed.

Next, with reference to FIG. 16N, a forming step of the interlayer insulating film 41 (the second insulating film 43) is performed (step S16 in FIG. 15). The interlayer insulating film 41 may be formed by the CVD method. In the interlayer insulating film 41, the plurality of contact openings 44 having a predetermined layout is formed by an etching method through a mask (not illustrated) having a predetermined layout.

Next, with reference to FIG. 16O, a forming step of the gate pad 50, the gate wiring 51, and the source pad 52 is performed (step S17 in FIG. 15). The gate pad 50, the gate wiring 51, and the source pad 52 are formed by depositing a metal film on the interlayer insulating film 41 by a sputtering method, and then forming the metal film into a predetermined layout by an etching method through a mask (not illustrated) having a predetermined layout.

Next, a forming step of the drain pad 53 is performed (step S18 in FIG. 15). The drain pad 53 is formed by depositing a metal film on the second wafer main surface 62 by a sputtering method. Then, the wafer 60 is cut along the plurality of intended cutting lines 66 (step S19 in FIG. 15). A plurality of SiC semiconductor devices 1 are manufactured from the single wafer 60 through steps including the above-described steps.

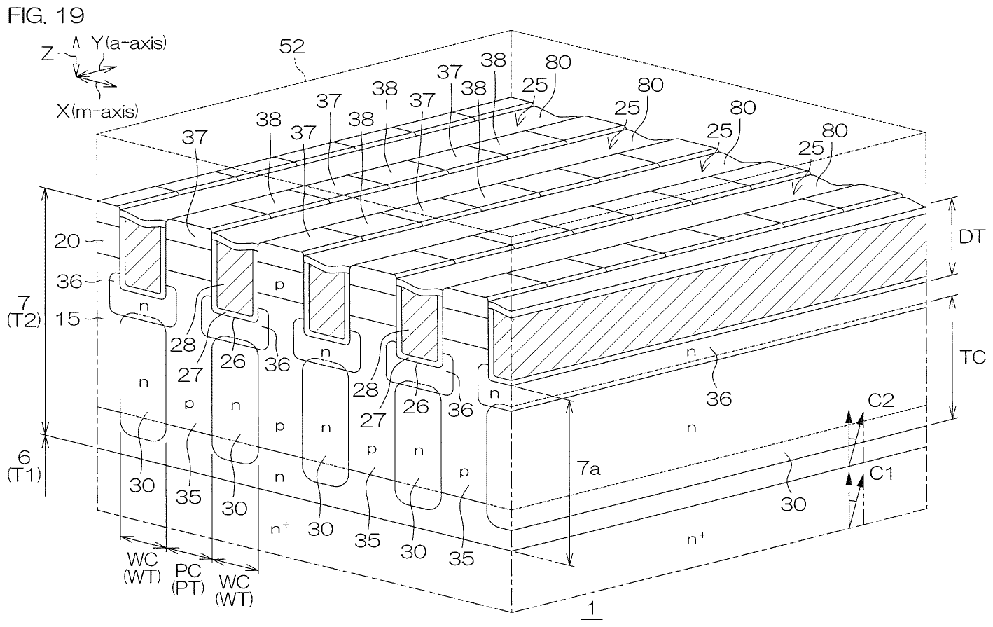

Hereinafter, other configuration examples of the trench structures 25 will be described. FIG. 19 is a cross-sectional perspective view showing the trench structures 25 according to a second configuration example. With reference to FIG. 19, the plurality of trench structures 25 according to the second configuration example respectively have configurations contributing to pitch reduction. The plurality of trench structures 25 according to the second configuration example are particularly effective in achieving pitch reduction in the plurality of inversion columns 30.

Each of the plurality of trench structures 25 includes the trench 26, the insulating film 27, the embedded electrode 28, and an embedded insulator 80. The trench 26 has a configuration as in the case of the first configuration example. In this embodiment, the insulating film 27 is formed at an interval from the first main surface 3 (the active surface 10) toward the bottom wall side of the trench 26 and exposes the surface layer portion of the first main surface 3 (the active surface 10) at an opening end of the trench 26. An upper end portion of the insulating film 27 is preferably positioned on the first main surface 3 side with respect to a depth range intermediate portion of the trench 26.

In this embodiment, the embedded electrode 28 is embedded in the trench 26 at an interval from the first main surface 3 (the active surface 10) toward the bottom wall side of the trench 26 and defines an opening recess recessed toward the bottom wall of the trench 26 at the opening end of the trench 26. The embedded electrode 28 exposes the surface layer portion of the first main surface 3 (the active surface 10) and the upper end portion of the insulating film 27 at the opening end of the trench 26. The upper end portion of the embedded electrode 28 is preferably positioned on the first main surface 3 side with respect to the depth range intermediate portion of the trench 26.

The embedded insulator 80 is embedded in the trench 26 (the opening recess) such as to expose the first main surface 3 (the active surface 10) and covers the insulating film 27 and the embedded electrode 28 in the trench 26. The embedded insulator 80 is embedded in the trench 26 at an interval from the first main surface 3 (the active surface 10) toward the embedded electrode 28 side and exposes the surface layer portion of the first main surface 3 (the active surface 10) at the opening end of the trench 26.

An upper end portion of the embedded insulator 80 is preferably positioned on the first main surface 3 side with respect to the depth range intermediate portion of the trench 26. The embedded insulator 80 may include at least one of a silicon oxide film, a silicon nitride film, and a silicon oxynitride film. The embedded insulator 80 preferably includes the silicon oxide film.

In this embodiment, the plurality of source regions 37 described above are respectively formed in regions between the plurality of trench structures 25 adjacent to each other in the surface layer portion of the first main surface 3 (the active surface 10). The plurality of source regions 37 are arrayed at intervals along the plurality of trench structures 25 such as to be connected to the plurality of trench structures 25 positioned on both sides of each of the source regions 37.

Specifically, the plurality of source regions 37 on one side arrayed along the side wall of the trench structure 25 on one side oppose the plurality of source regions 37 on the other side arrayed along the side wall of the trench structure 25 on the other side in a one-to-one correspondence relationship. That is, the plurality of source regions 37 are arrayed in a matrix in plan view.

As a matter of course, the plurality of source regions 37 on one side may oppose regions between the plurality of source regions 37 on the other side in a one-to-one correspondence relationship. That is, the plurality of source regions 37 may be arrayed in a staggered arrangement in plan view. Each of the plurality of source regions 37 has a portion exposed from the side wall of the trench 26 at the opening end of the trench 26 and opposes the embedded electrode 28 and the embedded insulator 80 across the insulating film 27.

In this embodiment, the plurality of contact regions 38 described above are respectively formed in regions between the plurality of trench structures 25 adjacent to each other in the surface layer portion of the first main surface 3 (the active surface 10). The plurality of contact regions 38 are arrayed at intervals along the plurality of trench structures 25 such as to be connected to the plurality of trench structures 25 positioned on both sides of each of the contact regions 38.

Specifically, the plurality of contact regions 38 and the plurality of source regions 37 are alternately arrayed along the plurality of trench structures 25. More specifically, the plurality of contact regions 38 on one side arrayed along a side wall of the trench structure 25 on one side oppose the plurality of contact regions 38 on the other side arrayed along a side wall of the trench structure 25 on the other side in a one-to-one correspondence relationship. Also, the plurality of contact regions 38 are arrayed in a matrix in plan view.

As a matter of course, the plurality of contact regions 38 on one side may oppose regions (that is, the plurality of source regions 37) between the plurality of source regions 37 on the other side in a one-to-one correspondence relationship. That is, the plurality of contact regions 38 may be arrayed in a staggered arrangement in plan view. Each of the plurality of contact regions 38 has a portion exposed from the side wall of the trench 26 at the opening end of the trench 26 and opposes the embedded electrode 28 and the embedded insulator 80 across the insulating film 27.

Although not specifically shown, the interlayer insulating film 41 described above has the laminated structure including the first insulating film 42 and the second insulating film 43. As in the case according to the first configuration example, the first insulating film 42 selectively covers the active surface 10, the outer surface 11, and the first to fourth connecting surfaces 12A to 12D.

In this embodiment, the first insulating film 42 covers the peripheral edge portions of the active surface 10 and collectively exposes the plurality of trench structures 25 in an inner portion of the active surface 10. Specifically, the first insulating film 42 is connected to the insulating film 27 at both end portions of each of the plurality of trench structures 25 and exposes the embedded electrode 28. Also, the first insulating film 42 covers the outer surface 11 and the first to fourth connecting surfaces 12A to 12D in the same mode as in the case of the first configuration example.

As in the case according to the first configuration example, the second insulating film 43 selectively covers the active surface 10, the outer surface 11, and the first to fourth connecting surfaces 12A to 12D across the first insulating film 42. In this embodiment, the second insulating film 43 covers the peripheral edge portions of the active surface 10 and collectively exposes the plurality of trench structures 25 in the inner portion of the active surface 10. Specifically, the second insulating film 43 enters into the trench 26 from above the first main surface 3 (the active surface 10) at both end portions of each of the plurality of trench structures 25 and is connected to the embedded insulator 80 in the trench 26.

In this embodiment, the interlayer insulating film 41 includes the plurality of contact openings 44 (not shown) that expose both end portions (the embedded electrodes 28) of each of the plurality of trench structures 25 and the single contact opening 44 that collectively exposes inner portions (the embedded insulators 80) of the plurality of trench structures 25, the plurality of source regions 37, and the plurality of contact regions 38.

The gate pad 50 described above, the plurality of gate wirings 51 described above, and the drain pad 53 described above have configurations as in the case of the first configuration example. The source pad 52 described above enters into the single contact opening 44 from above the interlayer insulating film 41 and collectively covers the inner portions (the embedded insulators 80) of the plurality of trench structures 25, the plurality of source regions 37, and the plurality of contact regions 38 in the single contact opening 44.

The source pad 52 is electrically insulated from the plurality of trench structures 25 (the embedded electrodes 28) by the embedded insulator 80 and is electrically connected to the plurality of source regions 37 and the plurality of contact regions 38 on the first main surface 3 (the active surface 10). In this embodiment, the source pad 52 is also electrically connected to exposed portions of the plurality of intermediate regions 36 on the first main surface 3.

The source pad 52 has an embedded portion embedded in the trench 26. The embedded portion of the source pad 52 opposes the embedded electrodes 28 across the embedded insulator 80 in the trenches 26 and is electrically connected to the plurality of source regions 37 and the plurality of contact regions 38 at the opening end of the trench 26.

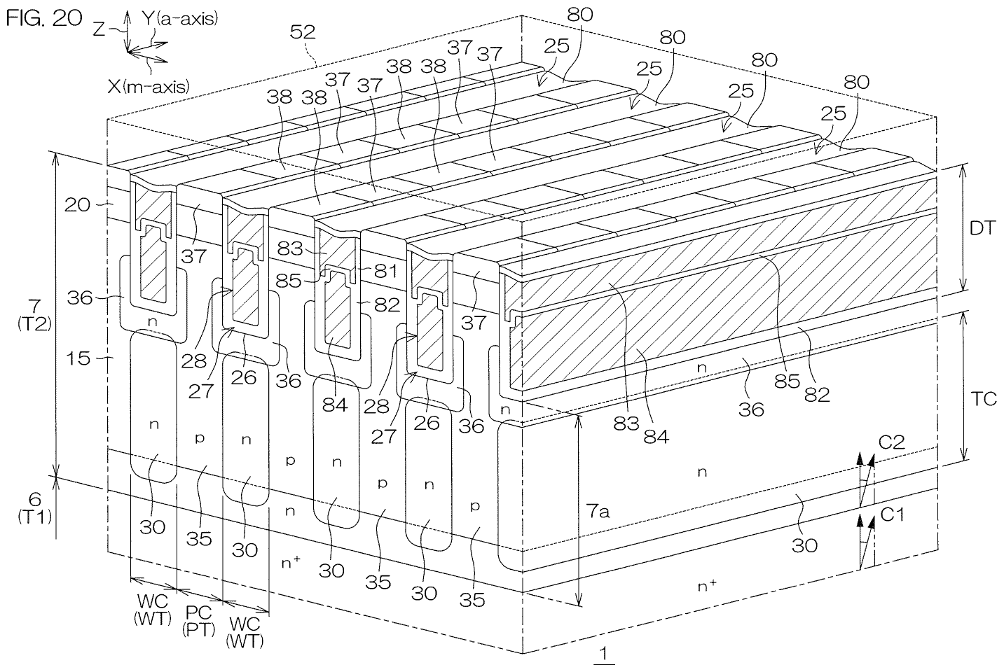

FIG. 20 is a cross-sectional perspective view showing the trench structures 25 according to a third configuration example. With reference to FIG. 20, the plurality of trench structures 25 according to the third configuration example respectively have configurations obtained by modifying the plurality of trench structures 25 according to the second configuration example.

Each of the plurality of trench structures 25 includes the trench 26, the insulating film 27, the embedded electrode 28, and an embedded insulator 80. The trench 26 has a configuration as in the case of the first configuration example. In this embodiment, the insulating film 27 includes an upper insulating film 81 and a lower insulating film 82.

The upper insulating film 81 is formed as the insulating film 27 for controlling the channels Ch and covers the wall surfaces of the trenches 26 on the opening side with respect to the bottom portion of the body region 20. The upper insulating film 81 has a portion that crosses the bottom portion of the body region 20 and covers the impurity region 15 (the non-inversion column 35). In this case, a covering area of the upper insulating film 81 with respect to the body region 20 is preferably larger than a covering area of the upper insulating film 81 with respect to the impurity region 15 (the non-inversion column 35).

The upper insulating film 81 may include a silicon oxide film. The upper insulating film 81 preferably includes the silicon oxide film constituted of the oxide of the chip 2. The upper insulating film 81 may have a thickness of not less than 1 nm and not more than 100 nm. The thickness of the upper insulating film 81 may have a value falling within any one of ranges of not less than 1 nm and not more than 25 nm, not less than 25 nm and not more than 50 nm, not less than 50 nm and not more than 75 nm, and not less than 75 nm and not more than 100 nm.

The lower insulating film 82 covers the wall surface of the trench 26 on the bottom wall side with respect to the bottom portion of the body region 20. The lower insulating film 82 covers the impurity region 15 (the non-inversion column 35). A covering area of the lower insulating film 82 with respect to the impurity region 15 (the non-inversion column 35) is larger than a covering area of the upper insulating film 81 with respect to the body region 20.

The lower insulating film 82 may include a silicon oxide film. The lower insulating film 82 may include a silicon oxide film constituted of the oxide of the chip 2 or may include a silicon oxide film formed by a CVD method. The lower insulating film 82 has a thickness larger than the thickness of the upper insulating film 81. The thickness of the lower insulating film 82 is preferably not less than ten times and not more than fifty times the thickness of the upper insulating film 81.

The lower insulating film 82 may have a thickness of not less than 100 nm and not more than 500 nm. The thickness of the lower insulating film 82 may have a value falling within any one of ranges of not less than 100 nm and not more than 150 nm, not less than 150 nm and not more than 200 nm, not less than 200 nm and not more than 250 nm, not less than 250 nm and not more than 300 nm, not less than 300 nm and not more than 350 nm, not less than 350 nm and not more than 400 nm, not less than 400 nm and not more than 450 nm, and not less than 450 nm and not more than 500 nm.

In this embodiment, the embedded electrode 28 has a multi-electrode structure (a double-electrode structure) including an upper electrode 83, a lower electrode 84, and an intermediate insulating film 85. The upper electrode 83 is embedded on the opening side of the trench 26 across the insulating film 27. Specifically, the upper electrode 83 is embedded on the opening side of the trench 26 across the upper insulating film 81 and opposes the body region 20 across the upper insulating film 81.

An opposing area of the upper electrode 83 with respect to the body region 20 is larger than an opposing area of the upper electrode 83 with respect to the impurity region 15 (the non-inversion column 35). In this embodiment, the upper electrode 83 is embedded in the trench 26 at an interval from the first main surface 3 (the active surface 10) toward the bottom wall side of the trench 26 and defines an opening recess recessed toward the bottom wall of the trench 26 at the opening end of the trench 26. The upper electrode 83 exposes the surface layer portion of the first main surface 3 (the active surface 10) and the upper end portion of the upper insulating film 81 at the opening end of the trench 26.

The gate potential as a control potential is applied to the upper electrode 83. The upper electrode 83 controls inversion and non-inversion of the channels Ch (the current paths) in the body region 20 in response to a gate potential. The upper electrode 83 may include p-type or n-type conductive polysilicon.

The lower electrode 84 is embedded on the bottom wall side of the trench 26 across the insulating film 27. Specifically, the lower electrode 84 is embedded on the bottom wall side of the trench 26 across the lower insulating film 82 and opposes the impurity region 15 (the non-inversion column 35) across the lower insulating film 82. That is, the lower electrode 84 is embedded on the bottom wall side of the trench 26 with respect to the bottom portion of the body region 20. Although not specifically shown, the lower electrode 84 is led out to the opening side of the trench 26 in a part (both end portions in this embodiment) of the trench 26.

An opposing area of the lower electrode 84 with respect to the impurity region 15 (the non-inversion column 35) is larger than an opposing area of the upper electrode 83 with respect to the body region 20. The lower electrode 84 extends in a wall shape along a depth direction of the trench 26. The lower electrode 84 has an upper end portion projecting from the lower insulating film 82 toward the upper electrode 83 side and engages with a lower end portion of the upper electrode 83. The upper end portion of the lower electrode 84 opposes the upper insulating film 81 (the body region 20) across the lower end portion of the upper electrode 83 in the horizontal direction.

A gate potential or a source potential may be applied to lower electrode 84. In the case where the gate potential is applied to lower electrode 84, the lower electrode 84 has a potential equal to that of the upper electrode 83. Therefore, a voltage drop between the upper electrode 83 and the lower electrode 84 is prevented. Consequently, electric field concentration with respect to the trench structure 25 is prevented.

Meanwhile, in the case where the source potential is applied to the lower electrode 84, the lower electrode 84 can function as a field electrode. Therefore, parasitic capacitance between the lower electrode 84 (the field electrode) and the impurity region 15 (the non-inversion column 35) is reduced. Consequently, a decrease in the switching speed caused by the parasitic capacitance is prevented. The lower electrode 84 may include p-type or n-type conductive polysilicon.

The intermediate insulating film 85 is interposed between the upper electrode 83 and the lower electrode 84 and electrically insulates the upper electrode 83 and the lower electrode 84 in the trench 26. The intermediate insulating film 85 is continuous with the upper insulating film 81 and the lower insulating film 82. The intermediate insulating film 85 has a thickness smaller than the thickness of the lower insulating film 82. The thickness of the intermediate insulating film 85 is preferably larger than the thickness of the upper insulating film 81. The intermediate insulating film 85 may include a silicon oxide film. The intermediate insulating film 85 preferably includes the silicon oxide film constituted of an oxide of the lower electrode 84.

The embedded insulator 80 is embedded in the trench 26 (the opening recess) such as to expose the first main surface 3 (the active surface 10) and covers the upper insulating film 81 and the upper electrode 83 in the recess. The embedded insulator 80 is embedded in the trench 26 at an interval from the first main surface 3 (the active surface 10) toward the upper electrode 83 side and exposes the surface layer portion of the first main surface 3 (the active surface 10) at the opening end of the trench 26.

The inversion column 30 described above and the intermediate region 36 described above are formed in the same mode as in the cases of the modes described above. In this embodiment, each of the intermediate region 36 opposes the lower electrode 84 across the lower insulating film 82 in a portion along the bottom wall of the trench 26 and opposes the lower electrode 84 across the lower insulating film 82 in a portion along the side wall of the trench 26.

A portion of each of the intermediate regions 36 along the side wall of each of the trenches 26 is formed at an interval from the bottom portion of the body region 20 toward the bottom wall side of each of the trench structures 25 and opposes the body region 20 across a part of the impurity region 15. As a matter of course, each of the intermediate regions 36 may be connected to the body region 20. In this case, each of the intermediate regions 36 may oppose the upper electrode 83 across the upper insulating film 81.

In this embodiment, each of the plurality of source regions 37 described above has a portion exposed from the side wall of the trench 26 at the opening end of the trench 26 and opposes the upper electrode 83 and the embedded insulator 80 across the upper insulating film 81. In this embodiment, each of the plurality of contact regions 38 described above has a portion exposed from the side wall of the trench 26 at the opening end of the trench 26 and opposes the upper electrode 83 and the embedded insulator 80 across the upper insulating film 81.

In this embodiment, the plurality of gate wirings 51 described above penetrate the interlayer insulating film 41 through the plurality of contact openings 44 and are electrically connected to the plurality of upper electrodes 83. In the case where the gate potential is applied to the lower electrode 84, the plurality of gate wirings 51 penetrate the interlayer insulating film 41 through the plurality of contact openings 44 and are electrically connected to the plurality of upper electrodes 83 and the plurality of lower electrodes 84.

In the case where the source potential is applied to the lower electrodes 84, the source pad 52 is electrically connected to the plurality of lower electrodes 84. In this case, the SiC semiconductor device 1 may include a source wiring led out from the source pad 52 onto the interlayer insulating film 41. In this case, the source wiring is formed in a line shape extending along the peripheral edges of the active surface 10 such as to intersect (specifically, to be orthogonal to) a part (one end portion or both end portions) of each of the plurality of trench structures 25 in a region outside the plurality of gate wirings 51. The source wiring penetrates the interlayer insulating film 41 through the plurality of contact openings 44 and is electrically connected to the plurality of lower electrodes 84.

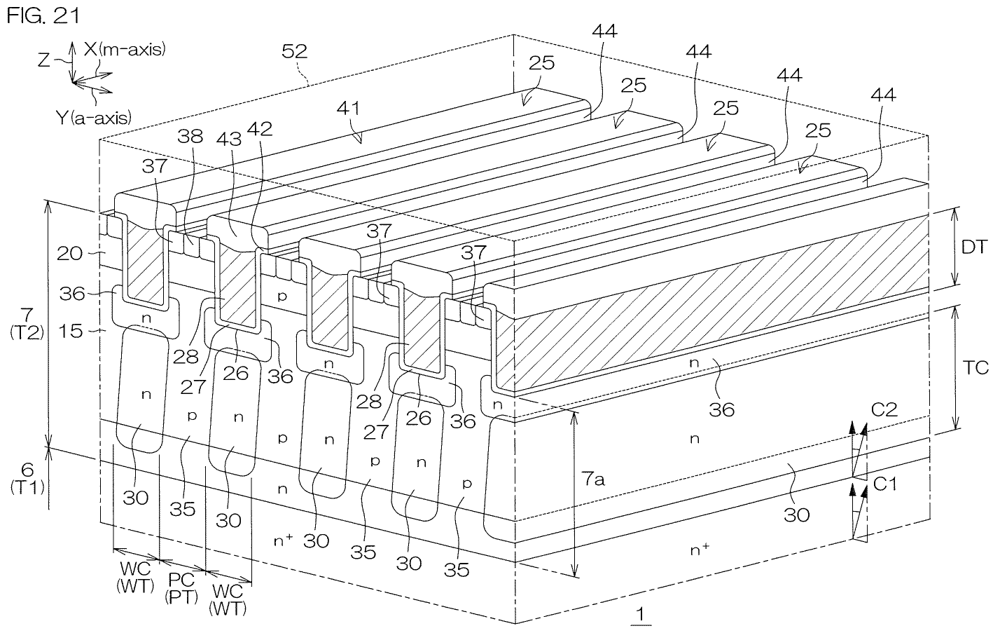

FIG. 21 is a cross-sectional perspective view showing the trench structure 25 according to the fourth configuration example. The plurality of trench structures 25 according to the first configuration example are arrayed at intervals in the first direction X (the m-axis direction) and are each formed as a band extending in the second direction Y (the a-axis direction). However, the plurality of trench structures 25 may each be formed as a band extending in the first direction X (the m-axis direction) and may be arrayed at intervals in the second direction Y (the a-axis direction).

The plurality of inversion columns 30 are each formed as a band extending in the first direction X (the m-axis direction) in accordance with the layout of the plurality of trench structures 25 and are arrayed at intervals in the second direction Y (the a-axis direction). In this case, since the extension direction of the plurality of inversion columns 30 intersects (specifically, is orthogonal to) the off direction Do of the SiC monocrystal, the plurality of inversion columns 30 are inclined by substantially the off angle θo from the vertical axis toward the off direction Do in cross-sectional view from the m-plane of the SiC monocrystal. Therefore, in view of the accuracy of the charge balance, it is preferable that the plurality of inversion columns 30 extend in the off direction Do.

As a matter of course, the array direction of the plurality of trench structures 25 may be a direction other than the a-axis direction and the m-axis direction, and the extension direction of the plurality of trench structures 25 may be a direction other than the a-axis direction and the m-axis direction. That is, the plurality of trench structures 25 may extend in a direction intersecting both the a-axis direction and the m-axis direction. In this case, the array direction of the plurality of inversion columns 30 becomes a direction other than the a-axis direction and the m-axis direction, and the extension direction of the plurality of inversion columns 30 becomes a direction other than the a-axis direction and the m-axis direction. That is, the plurality of inversion columns 30 extend in a direction intersecting both the a-axis direction and the m-axis direction.

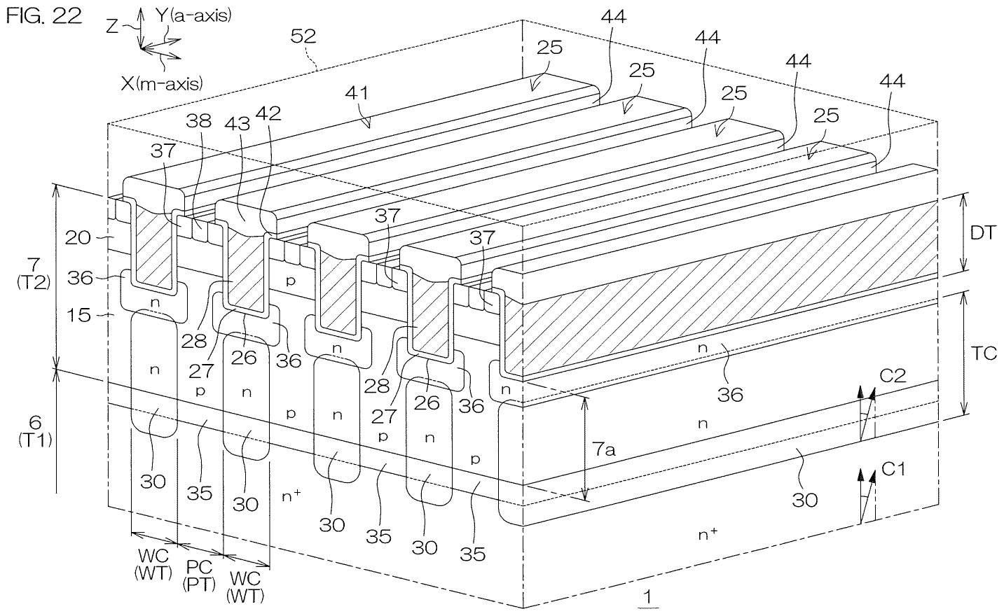

Hereinafter, modification examples of the SiC semiconductor device 1 will be described. Configurations according to the modification examples can be applied to the first to fourth configuration examples described above. FIG. 22 is a cross-sectional perspective view showing the SiC semiconductor device 1 according to a first modification example. In the embodiments described above, the impurity region 15 is formed at an interval from the lower end of the semiconductor layer 7 toward the first main surface 3 side.

On the other hand, the impurity region 15 according to the first modification example has a bottom portion that crosses the boundary portion between the base layer 6 and the semiconductor layer 7 and is positioned in the base layer 6. The bottom portion of the impurity region 15 is positioned in a surface layer portion of the base layer 6. Since the second axis channel C2 is substantially matched with the first axis channel C1, the bottom portion of the impurity region 15 is formed along the first axis channel C1 in the base layer 6.

Meanwhile, the inversion column 30 described above has a lower end portion that crosses the bottom portion of the impurity region 15 in the base layer 6 and is electrically connected to the base layer 6. The lower end portion of the inversion column 30 is positioned in the surface layer portion of the base layer 6. Since the second axis channel C2 is substantially matched with the first axis channel C1, the lower end portion of the inversion column 30 is formed along the first axis channel C1 in the base layer 6.

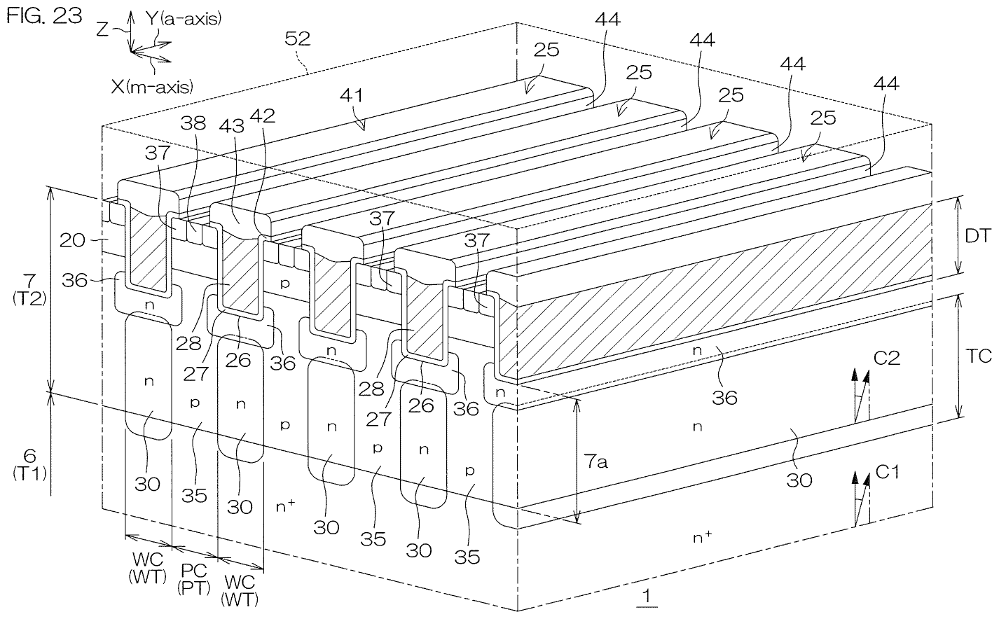

FIG. 23 is a cross-sectional perspective view showing the SiC semiconductor device 1 according to a second modification example. In the embodiments described above, the impurity region 15 is formed in the semiconductor layer 7. On the other hand, in the SiC semiconductor device 1 according to the second modification example, the semiconductor layer 7 of the p-type (the epitaxial layer of the p-type) is formed, and the p-type impurity region 15 is omitted. The p-type semiconductor layer 7 is distinguished from the impurity region 15 in that the p-type semiconductor layer 7 does not have the first gradual increase portion 16, the first peak portion 17, the first gentle gradient portion 18, and the first gradual decrease portion 19.

A p-type impurity concentration of the semiconductor layer 7 is preferably less than the n-type impurity concentration of the base layer 6. The semiconductor layer 7 may have a p-type impurity concentration of not less than 1×10¹⁵ cm⁻³ and not more than 1×10¹⁸ cm⁻³ as a peak value. The p-type impurity concentration of the semiconductor layer 7 may be substantially constant in the thickness direction. As a matter of course, the p-type impurity concentration of the semiconductor layer 7 may have a concentration gradient that gradually increases and/or gradually decreases in the lamination direction (the crystal growth direction).

The p-type impurity concentration of the semiconductor layer 7 may be adjusted by at least one type of trivalent element. The trivalent element of the semiconductor layer 7 may be at least one type among boron, aluminum, gallium, and indium. The trivalent element of the semiconductor layer 7 is typically boron or aluminum.

The body region 20 described above does not necessarily have to be formed. For example, in a case where a part (the surface layer portion) of the semiconductor layer 7 can function as a part of the body region 20, the part (the surface layer portion) of the semiconductor layer 7 may be formed as the body region 20, and the body region 20 may be omitted. In other words, the surface layer portion of the semiconductor layer 7 may also serve as the body region 20, and the body region 20 may be formed using the surface layer portion of the semiconductor layer 7.

The plurality of inversion columns 30 (the intermediate regions 36) described above are formed in the lower region 7a such as to invert the conductivity type of the p-type semiconductor layer 7 and define the plurality of non-inversion columns 35 each constituted of a part of the p-type semiconductor layer 7. The conductivity type of the well region 39 described above is replaced from the p-type to the n-type. Also, the conductivity type of the field region 40 described above is replaced from the p-type to the n-type.

As a matter of course, even in a case where the p-type semiconductor layer 7 is formed, a configuration may be employed in which the p-type impurity region 15 is included. In this case, the p-type impurity concentration of the p-type semiconductor layer 7 is corrected (adjusted) by the p-type impurity region 15.

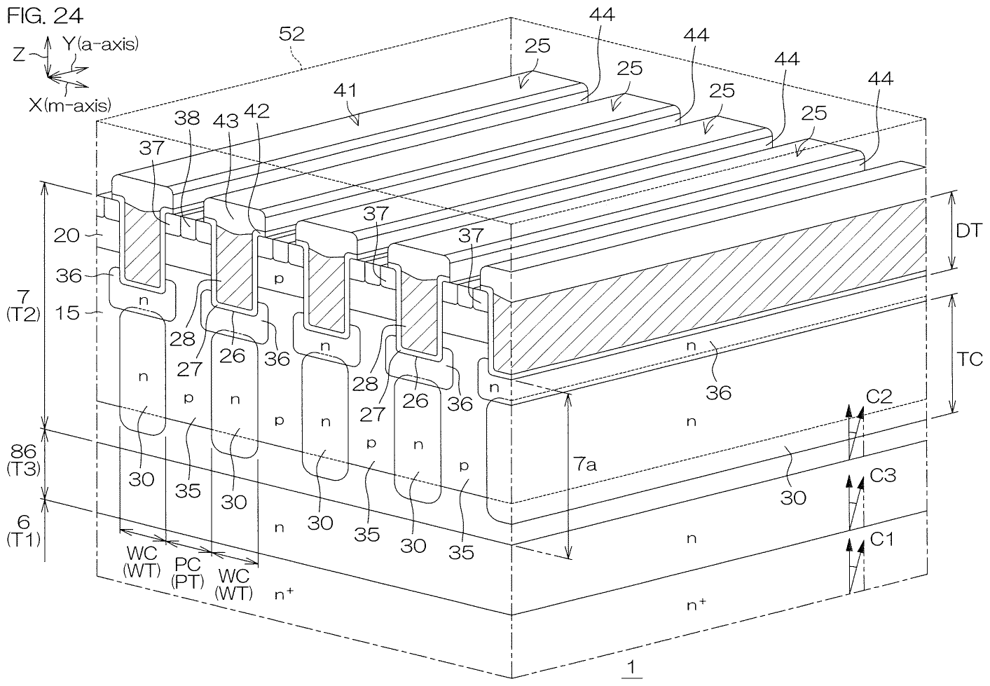

FIG. 24 is a cross-sectional perspective view showing the SiC semiconductor device 1 according to a third modification example. The SiC semiconductor device 1 according to the third modification example further includes a buffer layer 86 of the n-type made of the SiC monocrystal laminated on the base layer 6. The buffer layer 86 is also a component of the chip 2. The buffer layer 86 may be referred to as a “buffer SiC layer,” a “buffer region,” etc.

The buffer layer 86 extends in a layer shape in the horizontal direction and forms an intermediate portion of the chip 2 and a part of each of the first to fourth side surfaces 5A to 5D. The buffer layer 86 is constituted of an epitaxial layer (that is, an SiC epitaxial layer) that is crystal-grown with the base layer 6 as a starting point.

The buffer layer 86 has a lower end and an upper end. The lower end of the buffer layer 86 is a crystal growth starting point, and the upper end of the buffer layer 86 is a crystal growth end point. Since the buffer layer 86 is continuously crystal-grown from the base layer 6, the lower end of the buffer layer 86 is matched with an upper end of the base layer 6. A boundary portion between the base layer 6 and the buffer layer 86 is not necessarily visible and can be indirectly evaluated and/or determined from other configurations or elements. The buffer layer 86 has the off direction Do and the off angle θo that are substantially matched with the off direction Do and the off angle θo of the base layer 6.

The buffer layer 86 has a third axis channel C3 oriented along the lamination direction. The third axis channel C3 is constituted of regions (channels) that are of comparatively wide interatomic distance (atomic interval) in the SiC monocrystal constituting the buffer layer 86 and are surrounded by atomic rows constituting a crystal axis extending in the lamination direction (crystal growth direction).

That is, the third axis channel C3 is a region where a region with sparse atomic rows extends in the lamination direction and the atomic rows (the interatomic distance/atomic density) in the horizontal direction are sparse in plan view. The third axis channel C3 is preferably constituted of the regions surrounded by atomic rows oriented along a low index crystal axis among crystal axes.

In this embodiment, the third axis channel C3 is constituted of the regions surrounded by atomic rows along the c-axis of the SiC monocrystal. That is, the third axis channel C3 extends along the c-axis and has the off direction Do and the off angle θo. In other words, the third axis channel C3 is inclined by the off angle θo from the vertical axis toward the off direction Do.

An n-type impurity concentration of the buffer layer 86 is preferably less than the n-type impurity concentration of the base layer 6. The buffer layer 86 may have an n-type impurity concentration of not less than 1×10¹⁵ cm⁻³ and not more than 1×10¹⁸ cm⁻³ as a peak value. The n-type impurity concentration of the buffer layer 86 may be substantially constant in the thickness direction. As a matter of course, the n-type impurity concentration of the buffer layer 86 may have a concentration gradient that gradually increases and/or gradually decreases in the lamination direction (the crystal growth direction).

The buffer layer 86 has an n-type impurity concentration adjusted by at least one type of pentavalent element. For example, the n-type impurity concentration of the buffer layer 86 may be adjusted by at least one type among nitrogen, phosphorus, arsenic, antimony, and bismuth. The buffer layer 86 preferably includes a pentavalent element other than phosphorus.

The n-type impurity concentration of the buffer layer 86 is preferably adjusted by at least nitrogen. In a case where the buffer layer 86 includes two or more types of pentavalent elements, the buffer layer 86 preferably includes nitrogen and a pentavalent element other than nitrogen. In this case, the buffer layer 86 preferably includes one or both of arsenic and antimony as a pentavalent element other than phosphorus and nitrogen.

The buffer layer 86 has a third thickness T3. The third thickness T3 is preferably less than the first thickness T1 of the base layer 6. The third thickness T3 is preferably not less than 1 μm. The third thickness T3 is preferably not more than 5 μm. The third thickness T3 may have a value falling within any one of ranges of not less than 1 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm.

The semiconductor layer 7 is laminated on the buffer layer 86. The semiconductor layer 7 is constituted of an epitaxial layer (that is, an SiC epitaxial layer) that is crystal-grown with the buffer layer 86 as a starting point. Therefore, the semiconductor layer 7 has the off direction Do and the off angle θo that are substantially matched with the off direction Do and the off angle θo of the buffer layer 86. Also, the second axis channel C2 is substantially matched with the third axis channel C3.

The second thickness T2 of the semiconductor layer 7 is preferably larger than the third thickness T3. As a matter of course, the second thickness T2 may be less than the third thickness T3. Also, the second thickness T2 may be substantially equal to the third thickness T3.

The impurity region 15 described above may have a bottom portion positioned in the semiconductor layer 7, and the inversion column 30 described above may have a lower end portion positioned in the base layer 6, the semiconductor layer 7, or the buffer layer 86. As a matter of course, the impurity region 15 may have a bottom portion positioned in the buffer layer 86, and the inversion column 30 may have a lower end portion positioned in the base layer 6 or the buffer layer 86.

The embodiments described above can be implemented in yet other embodiments. For example, in the embodiments described above, the base layer 6, the semiconductor layer 7, and the buffer layer 86 each including the SiC monocrystal are employed. However, at least one or all of the base layer 6, the semiconductor layer 7, and the buffer layer 86 may include a monocrystal of a wide bandgap semiconductor other than the SiC monocrystal.

The wide bandgap semiconductor is a semiconductor that has a bandgap wider than the bandgap of silicon. Examples of the monocrystal of the wide bandgap semiconductor include silicon carbide (SiC), gallium nitride (GaN), diamond (C), and gallium oxide (Ga₂O₃). The base layer 6, the semiconductor layer 7, and the buffer layer 86 may be constituted of a monocrystal of the same type or may be constituted of monocrystals of different types.

The channeling implantation step (the step of implanting impurities into a region where atomic rows are sparse) described above is also applicable to a monocrystal constituting a cubical crystal. Therefore, the monocrystal of the wide bandgap semiconductor may be a cubical crystal or a hexagonal crystal. In a case where a cubical monocrystal is applied to at least one or all of the base layer 6, the semiconductor layer 7, and the buffer layer 86, these axis channels are formed by a region surrounded by atomic rows along a low-index crystal axis of cubical crystal axes.

The low-index crystal axis related to the cubical crystal is a crystal axis whose absolute values of “h,” “k,” and “l” are all represented by not more than 2 (preferably not more than 1) with respect to Miller indices (h, k, and l). As a matter of course, at least one or all of the base layer 6, the semiconductor layer 7, and the buffer layer 86 may include a silicon monocrystal.

In the embodiments described above, the n-type base layer 6 was described. However, the base layer 6 of the p-type may be employed. In this case, an IGBT (insulated gate bipolar transistor) structure is formed instead of the MISFET structure. In this case, in the above description, the “source” of the MISFET structure is replaced with an “emitter” of the IGBT structure, and the “drain” of the MISFET structure is replaced with a “collector” of the IGBT structure. The p-type base layer 6 may be a p-type region that includes a trivalent element introduced into the surface layer portion of the second main surface 4 of the chip 2 by an ion implantation method.

Hereinafter, examples of features extracted from this Description and the accompanying drawings will be described. Hereinafter, the alphanumeric characters, etc., in parentheses represent the corresponding components, etc., in the embodiments described above, but are not intended to limit the scope of clauses to the embodiments. A “semiconductor device” in the following clauses may be replaced with an “SiC semiconductor device,” a “wide bandgap semiconductor device,” a “semiconductor switching device,” a “MISFET device,” an “IGBT device, etc., as necessary.

[A1] A semiconductor device (1) comprising: a semiconductor layer (7) that includes a main surface (3) and has an axis channel (C2) in a lamination direction (Z); an impurity region (15) of a p-type formed in the semiconductor layer (7); a trench (26) that is formed shallower than the impurity region (15) in the main surface (3) and defines a lower region (7a) including a part of the impurity region (15) between a bottom portion of the semiconductor layer (7) and the trench (26); and an inversion column (30) of an n-type that is formed in the lower region (7a) such as to extend along the axis channel (C2) and that inverts a conductivity type of the impurity region (15).

[A2] The semiconductor device (1) according to A1, wherein the inversion column (30) crosses a thickness range intermediate portion of the lower region (7a) along the axis channel (C2).

[A3] The semiconductor device (1) according to A1 or A2, wherein the inversion column (30) has a thickness (TC) larger than a depth (DT) of the trench (26) with regard to a thickness direction of the semiconductor layer (7).

[A4] The semiconductor device (1) according to any one of A1 to A3, wherein the inversion column (30) is constituted of a single region.

[A5] The semiconductor device (1) according to any one of A1 to A4, wherein the inversion column (30) has an upper end portion on the trench (26) side and a lower end portion on the bottom portion side of the semiconductor layer (7) and has a concentration gradient gradually decreasing from the upper end portion toward the lower end portion.

[A6] The semiconductor device (1) according to A5, wherein the concentration gradient includes a peak value (P2) on the upper end portion side and a gentle gradient portion (33) where an impurity concentration gradually decreases at a gentle decrease rate in a region closer to the lower end portion than the peak value (P2).

[A7] The semiconductor device (1) according to A6, wherein the gentle gradient portion (33) accounts for a thickness range of not less than 1/4 of the inversion column (30).

[A8] The semiconductor device (1) according to any one of A1 to A7, wherein the trench (26) extends as a band in plan view, and the inversion column (30) extends as a band along the trench (26) in plan view.

[A9] The semiconductor device (1) according to A8, wherein the trench (26) extends in an a-axis direction of the semiconductor layer (7) in plan view.

[A10] The semiconductor device (1) according to any one of A1 to A9, wherein the semiconductor layer (7) has an off angle (θo) inclined toward an off direction (Do) on a basis of a vertical axis (Z), and the axis channel (C2) has the off angle (θo) inclined toward the off direction (Do) on a basis of the vertical axis (Z).

[A11] The semiconductor device (1) according to A10, wherein the off direction (Do) is an a-axis direction of the semiconductor layer (7).

[A12] The semiconductor device (1) according to A10 or A11, wherein the off angle (θo) is not more than 10°.

[A13] The semiconductor device (1) according to any one of A1 to A12, wherein the semiconductor layer (7) is of the n-type, and the impurity region (15) inverts a conductivity type of the semiconductor layer (7).

[A14] The semiconductor device (1) according to any one of A1 to A13, wherein the impurity region (15) crosses a thickness range intermediate portion of the semiconductor layer (7) along the axis channel (C2).

[A15] The semiconductor device (1) according to any one of A1 to A14, wherein the inversion column (30) crosses the bottom portion of the impurity region (15).

[A16] The semiconductor device (1) according to any one of A1 to A15, wherein the impurity region (15) is formed at an interval from the bottom portion of the semiconductor layer (7) toward the main surface (3) side, and the inversion column (30) is electrically connected to a lower layer portion of the semiconductor layer (7).

[A17] The semiconductor device (1) according to any one of A1 to A16, wherein the inversion column (30) is formed at an interval from a bottom wall of the trench (26) toward the bottom portion side of the semiconductor layer (7).

[A18] The semiconductor device (1) according to A17, further comprising an intermediate region (36) of the n-type formed in a region in the semiconductor layer (7) between the bottom wall of the trench (26) and the inversion column (30).

[A19] The semiconductor device (1) according to A18, further comprising a source region (37) of the n-type that is formed on a lateral side of the trench (26) at an interval from the intermediate region (36) toward the main surface (3) side in a surface layer portion of the main surface (3) and defines a channel (Ch) as a current path leading to the inversion column (30) between the intermediate region (36) and the source region (37).

[A20] The semiconductor device (1) according to A19, wherein the source region (37) has an n-type impurity concentration higher than an n-type impurity concentration of the inversion column (30).

[A21] The semiconductor device (1) according to any one of A1 to A20, wherein the semiconductor layer (7) is an SiC layer (7) including an SiC monocrystal.

While the specific embodiments have been described in detail above, these are merely specific examples used to clarify the technical contents. The various technical ideas extracted from this Description can be combined as appropriate with each other without being limited by the order of description, the order of configuration examples, etc., in the Description.

What is claimed is:

1. An SiC semiconductor device comprising:
an SiC layer that includes a main surface and has an axis channel in a lamination direction;
an impurity region of a p-type formed in the SiC layer;
a trench that is formed shallower than the impurity region in the main surface and defines a lower region including a part of the impurity region between a bottom portion of the SiC layer and the trench; and
an inversion column of an n-type that is formed in the lower region such as to extend along the axis channel and that inverts a conductivity type of the impurity region.

2. The SiC semiconductor device according to claim 1,
wherein the inversion column crosses a thickness range intermediate portion of the lower region along the axis channel.

3. The SiC semiconductor device according to claim 1,
wherein the inversion column has a thickness larger than a depth of the trench with regard to a thickness direction of the SiC layer.

4. The SiC semiconductor device according to claim 1,
wherein the inversion column is constituted of a single region.

5. The SiC semiconductor device according to claim 1,
wherein the inversion column has an upper end portion on the trench side and a lower end portion on the bottom portion side of the SiC layer and has a concentration gradient gradually decreasing from the upper end portion toward the lower end portion.

6. The SiC semiconductor device according to claim 5,
wherein the concentration gradient includes a peak value on the upper end portion side and a gentle gradient portion where an impurity concentration gradually decreases at a gentle decrease rate in a region closer to the lower end portion than the peak value.

7. The SiC semiconductor device according to claim 6,
wherein the gentle gradient portion accounts for a thickness range of not less than 1/4 of the inversion column.

8. The SiC semiconductor device according to claim 1,
wherein the trench extends as a band in plan view, and
the inversion column extends as a band along the trench in plan view.

9. The SiC semiconductor device according to claim 8,
wherein the trench extends in an a-axis direction of an SiC monocrystal in plan view.

10. The SiC semiconductor device according to claim 1,
wherein the SiC layer has an off angle inclined toward an off direction on a basis of a vertical axis, and
the axis channel has the off angle inclined toward the off direction on a basis of the vertical axis.

11. The SiC semiconductor device according to claim 10,
wherein the off direction is an a-axis direction of an SiC monocrystal.

12. The SiC semiconductor device according to claim 11,
wherein the off angle is not more than 10°.

13. The SiC semiconductor device according to claim 1,
wherein the SiC layer is of the n-type, and
the impurity region inverts a conductivity type of the SiC layer.

14. The SiC semiconductor device according to claim 1,
wherein the impurity region crosses a thickness range intermediate portion of the SiC layer along the axis channel.

15. The SiC semiconductor device according to claim 1,
wherein the inversion column crosses the bottom portion of the impurity region.

16. The SiC semiconductor device according to claim 1,
wherein the impurity region is formed at an interval from the bottom portion of the SiC layer toward the main surface side, and
the inversion column is electrically connected to a lower layer portion of the SiC layer.

17. The SiC semiconductor device according to claim 1,
wherein the inversion column is formed at an interval from a bottom wall of the trench toward the bottom portion side of the SiC layer.

18. The SiC semiconductor device according to claim 17, further comprising:
an intermediate region of the n-type formed in a region in the SiC layer between the bottom wall of the trench and the inversion column.

19. The SiC semiconductor device according to claim 18, further comprising:
a source region of the n-type that is formed on a lateral side of the trench at an interval from the intermediate region toward the main surface side in a surface layer portion of the main surface and defines a channel as a current path leading to the inversion column between the intermediate region and the source region.

20. The SiC semiconductor device according to claim 19,
wherein the source region has an n-type impurity concentration higher than an n-type impurity concentration of the inversion column.
